(19) United States
(12) Patent Application Publication
(10) Pub. No.: US 2026/0016751 A1
(43) Pub. Date: Jan. 15, 2026

(54) LAMINATE, PREPARATION OF LAMINATE AND PATTERN FORMING PROCESS

(71) Applicant: Shin-Etsu Chemical Co., Ltd., Tokyo (JP)

(72) Inventors: Shun Kikuchi, Joetsu-shi (JP); Daisuke Kori, Joetsu-shi (JP); Ryunosuke Handa, Joetsu-shi (JP); Satoshi Kusama, Joetsu-shi (JP); Kousuke Ohyama, Joetsu-shi (JP); Masaki Ohashi, Joetsu-shi (JP)

(73) Assignee: Shin-Etsu Chemical Co., Ltd., Tokyo (JP)

(21) Appl. No.: 19/257,573

(22) Filed: Jul. 2, 2025

(30) Foreign Application Priority Data
Jul. 12, 2024 (JP) 2024-112836

(51) Int. Cl. G03F 7/09; C09J 161/14; G03F 7/039; G03F 7/075; G03F 7/11; G03F 7/16; G03F 7/32

(52) U.S. Cl. CPC G03F 7/094; G03F 7/039; G03F 7/0752; G03F 7/11; G03F 7/168; G03F 7/325; C09J 161/14

(57) ABSTRACT

A laminate includes a substrate, an adherent film formed thereon from a composition comprising a polymer and an organic solvent, and a resist film formed on the adherent film from a resist composition comprising a hypervalent iodine compound, a carboxy-containing compound and a solvent. When the laminate is processed by EB or EUV lithography, the resist film exhibits a high sensitivity and maximum resolution.

### CROSS-REFERENCE TO RELATED APPLICATION

This non-provisional application claims priority under 35 U.S.C. § 119(a) on Patent Application No. 2024-112836 filed in Japan on Jul. 12, 2024, the entire contents of which are hereby incorporated by reference.

### TECHNICAL FIELD

This invention relates to a laminate, a method for preparing the same, and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having a polymerizable olefin. With respect to the patterning of a resist film to a feature size of 16 nm et seq., it is believed impossible in the light of acid diffusion to form such a pattern from a chemically amplified resist composition. It would be desirable to have a non-chemically-amplified resist composition.

A typical non-chemically-amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of their application to the resist at a practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where the pattern feature size becomes smaller than ever. Particularly in the case of line-and-space patterns, chances of collapse and disconnection of patterns increase outstandingly as the pattern size becomes smaller. Minimizing such chances leads to an improvement in maximum resolution.

Patent Document 2 discloses a negative resist composition comprising a tin compound. Based on tin element having high EUV absorption, this resist composition is improved in stochastics and achieves a high sensitivity and high resolution. The so-called metal resist compositions, however, suffer from many problems including low solubility in resist solvents, poor shelf stability, and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2018-005224 (U.S. Pat. No. 10,323,113)
Patent Document 2: JP-A 2021-503482
Non-Patent Document 1: SPIE Vol. 5039 p1 (2003)
Non-Patent Document 2: SPIE Vol. 6520 p65203L-1 (2007)

### DISCLOSURE OF INVENTION

An object of the invention is to provide a laminate comprising a substrate, an adherent film thereon, and a resist film formed thereon from a non-chemically-amplified resist composition which exhibits a high sensitivity and maximum resolution, the laminate being applicable to photolithography using high-energy radiation, typically EB and EUV lithography, and a process for forming a pattern in the resist film of the laminate.

The inventors have found that a laminate is constructed by laying an adherent film on a substrate and forming a resist film on the adherent film from a resist composition comprising a hypervalent iodine compound and a carboxy-containing compound, that when the laminate is processed by photolithography, the resist film exhibits a high resolution, and that the laminate is quite useful in precise micropatterning.

In one aspect, the invention provides a laminate comprising a substrate, an adherent film on the substrate, and a resist film on the adherent film.

The adherent film is formed of an adherent film-forming composition comprising a polymer comprising repeat units having the formula (1) or (2) and an organic solvent,

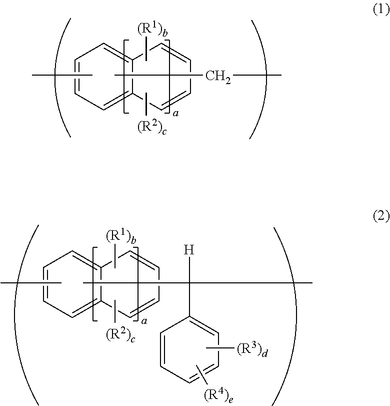

wherein a is 0, 1 or 2, b is an integer meeting 0≤b≤4a+2, c is an integer meeting 1≤c≤4a+2, and 1≤b+c≤4a+2, d is 0, 1, 2, 3, 4 or 5, e is 0, 1, 2, 3, 4 or 5, and 1≤d+e≤5,
R¹ is hydroxy or 2-propynyloxy,
R² is carboxy or carboxymethoxy,
R³ is hydroxy or 2-propynyloxy, and
R⁴ is carboxy or carboxymethoxy.

The resist film is formed of a resist composition comprising at least one hypervalent iodine compound selected from a hypervalent iodine compound having the formula (3), a hypervalent iodine compound having the formula (4), and a hypervalent iodine compound having the formula (5), a carboxy-containing compound, and a solvent,

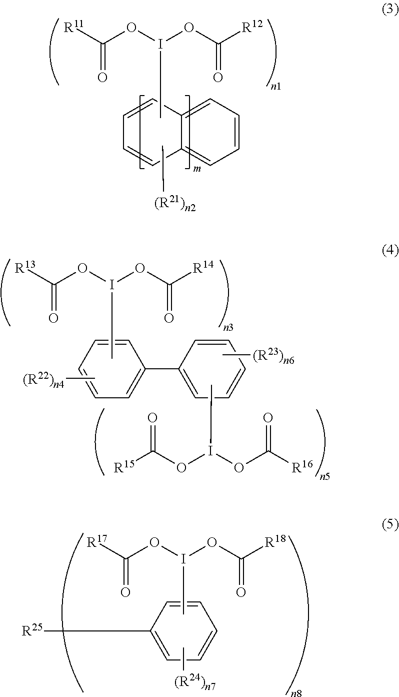

wherein m is 0, 1 or 2; when m=0, n1 is 1, 2 or 3, n2 is 0, 1, 2, 3, 4 or 5 and 1≤n1+n2≤6; when m=1, n1 is 1, 2 or 3, n2 is 0, 1, 2, 3, 4, 5, 6 or 7 and 1≤n1+n2≤8; when m=2, n1 is 1, 2 or 3, n2 is 0, 1, 2, 3, 4, 5, 6, 7, 8 or 9 and 1≤n1+n2≤10, n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
R¹¹ to R¹⁸ are each independently halogen or a C₁-C₁₀ hydrocarbyl group which may contain a heteroatom, R¹¹ and R¹², R¹³ and R¹⁴, R¹⁵ and R¹⁶, or R¹⁷ and R¹⁸ may bond together to form a ring with the carbon atoms to which they are attached and the intervenient atoms, and
R²¹ to R²⁴ are each independently halogen or a C₁-C₄₀ hydrocarbyl group which may contain a heteroatom; when n2 is 2 or more, a plurality of R²¹ may be identical or different and a plurality of R²¹ may bond together to form a ring with the carbon atoms on the aromatic ring to which they are attached; when n4 is 2 or more, a plurality of R²² may be identical or different and a plurality of R²² may bond together to form a ring with the carbon atoms on the aromatic ring to which they are attached; when n6 is 2 or more, a plurality of R²³ may be identical or different and a plurality of R²³ may bond together to form a ring with the carbon atoms on the aromatic ring to which they are attached; when n7 is 2 or more, a plurality of R²⁴ may be identical or different and a plurality of R²⁴ may bond together to form a ring with the carbon atoms on the aromatic ring to which they are attached;
R²⁵ is a C₁-C₄₀ (n8)-valent hydrocarbon group or C₂-C₄₀ (n8)-valent heterocyclic group; when n8=2, R²⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R²⁴ and R²⁵ may bond together to form a ring with the carbon atoms to which they are attached and the intervenient atoms.

In a preferred embodiment, the laminate further comprises a resist underlying film and a silicon-containing intermediate film between the substrate and the adherent film in the described order from the substrate side.

In a preferred embodiment, the polymer comprising repeat units having the formula (1) or (2) has a weight average molecular weight of 500 to 20,000.

The adherent film-forming composition may further comprise at least one additive selected from a surfactant, crosslinker and thermal acid generator.

In a preferred embodiment, the adherent film has a thickness of 2 to 50 nm.

In a preferred embodiment, the carboxy-containing compound is a polymer comprising repeat units having the formula (6) or a compound having the formula (7).

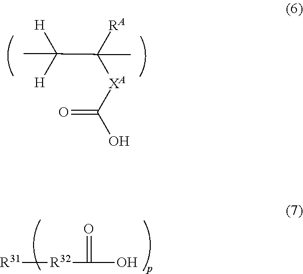

Herein R^{A} is hydrogen, halogen, methyl or trifluoromethyl,
X^{A} is a single bond, phenylene, naphthylene, or *—C(═O)—O—X^{A1}—, X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone,
p is 1, 2, 3 or 4,
R³¹ is a C₁-C₄₀ p-valent hydrocarbon group or C₂-C₄₀ p-valent heterocyclic group; when p=2, R³¹ may also be an ether bond, carbonyl group, azo group, thioether bond, carbonate bond, carbamate bond, sulfinyl group or sulfonyl group; some or all of the hydrogen atoms in the p-valent hydrocarbon group or p-valent heterocyclic group may be substituted by a heteroatom-containing moiety, some —CH₂— in the p-valent hydrocarbon group may be replaced by a heteroatom-containing moiety,
R³² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety; when p is 2, 3 or 4, a plurality of R³² may be identical or different.

In another aspect, the invention provides a method for preparing a laminate, comprising the steps of:
applying an adherent film-forming composition onto a substrate and heating to form an adherent film thereon, the adherent film-forming composition comprising a polymer comprising repeat units having the formula (1) or (2) and an organic solvent, and
applying a resist composition onto the adherent film and heating to form a resist film thereon, the resist composition comprising at least one hypervalent iodine compound selected from hypervalent iodine compounds having the formulae (3), (4), and (5), a carboxy-containing compound, and a solvent.

The invention also provides a method for preparing a laminate, comprising the steps of:
applying a resist underlying film-forming composition onto a substrate and heating to form a resist underlying film thereon,
forming a silicon-containing intermediate film on the resist underlying film,
applying an adherent film-forming composition onto the silicon-containing intermediate layer and heating to form an adherent film thereon, the adherent film-forming composition comprising a polymer comprising repeat units having the formula (1) or (2) and an organic solvent, and
applying a resist composition onto the adherent film and heating to form a resist film thereon, the resist composition comprising at least one hypervalent iodine compound selected from hypervalent iodine compounds having the formulae (3), (4), and (5), a carboxy-containing compound, and a solvent.

In a preferred embodiment, the step of forming a silicon-containing intermediate film includes applying a silicon-containing intermediate film material onto the resist underlying film and heating the material coating.

In a preferred embodiment, the silicon-containing intermediate film is an inorganic hard mask intermediate film selected from a silicon oxide film, silicon nitride film and silicon oxynitride film, which are formed by the CVD or ALD method.

In a preferred embodiment, the carboxy-containing compound is a polymer comprising repeat units having the formula (6) or a compound having the formula (7).

In a further aspect, the invention provides a pattern forming process comprising the steps of exposing the resist film in the laminate defined above to i-line, KrF excimer laser, ArF excimer laser, EB or EUV, and developing the exposed resist film in a developer. Typically, the developer is an organic solvent.

### Advantageous Effects of Invention

The laminate exhibits both high sensitivity and resolution when processed by photolithography using i-line, KrF excimer laser, ArF excimer laser, EB or EUV and is quite useful in micropatterning.

### DESCRIPTION OF EMBODIMENTS

The terms “a” and “an” herein do not denote a limitation of quantity, but rather denote the presence of at least one of the referenced item. As used herein, the notation (Cₙ-Cₘ) means a group containing from n to m carbon atoms per group. In chemical formulae, Me stands for methyl, Ac for acetyl. Both the broken line (---) and the asterisk (*) designate a point of attachment or valence bond.

The abbreviations and acronyms have the following meaning.
UV: ultraviolet radiation
EUV: extreme ultraviolet
EB: electron beam
Mw: weight average molecular weight
Mw/Mn: polydispersity index
GPC: gel permeation chromatography
PAB: post-apply bake
PEB: post-exposure bake
LWR: line width roughness
CDU: critical dimension uniformity

### Laminate

The laminate is quite useful in multilayer resist processes such as 2-layer resist process and 4-layer resist process using a resist underlying film and a silicon-containing intermediate film.

One embodiment of the invention is a laminate comprising a substrate, an adherent film, and a resist film disposed in the described order.

### Substrate

The substrate used herein is preferably a substrate for integrated circuit fabrication, e.g., Si, SiO₂, SiN, SiON, TiN, WSi, BPSG or SOG or a substrate for mask circuit fabrication, e.g., Cr, CrO, CrON, MoSi₂ or SiO₂.

### Adherent Film

The adherent film is formed on the substrate from an adherent film-forming composition comprising a polymer comprising repeat units having the formula (1) or (2) and an organic solvent.

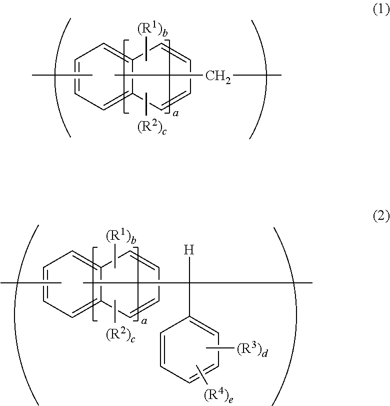

In formulae (1) and (2), a is 0, 1 or 2, b is an integer meeting 0 b 4a+2, c is an integer meeting 1≤c≤4a+2, and 1≤b+c≤4a+2, d is 0, 1, 2, 3, 4 or 5, e is 0, 1, 2, 3, 4 or 5, and 1≤d+e≤5.

In formulae (1) and (2), R¹ is hydroxy or 2-propynyloxy, R² is carboxy or carboxymethoxy, R³ is hydroxy or 2-propynyloxy, and R⁴ is carboxy or carboxymethoxy.

Examples of the repeat unit having formula (1) are shown below, but not limited thereto.

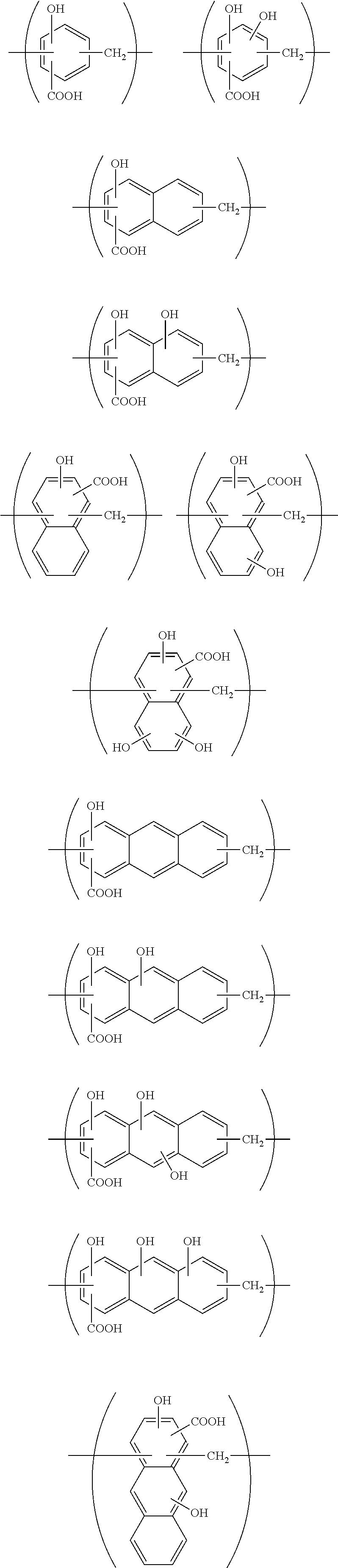

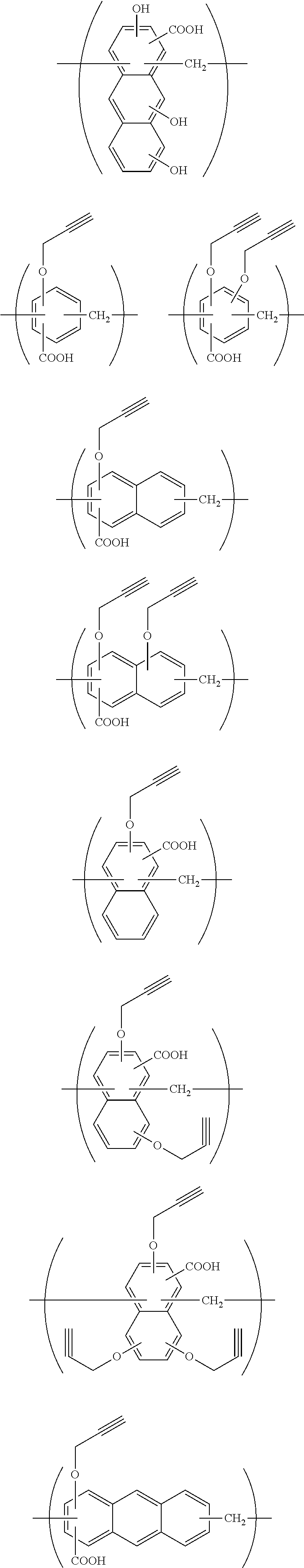

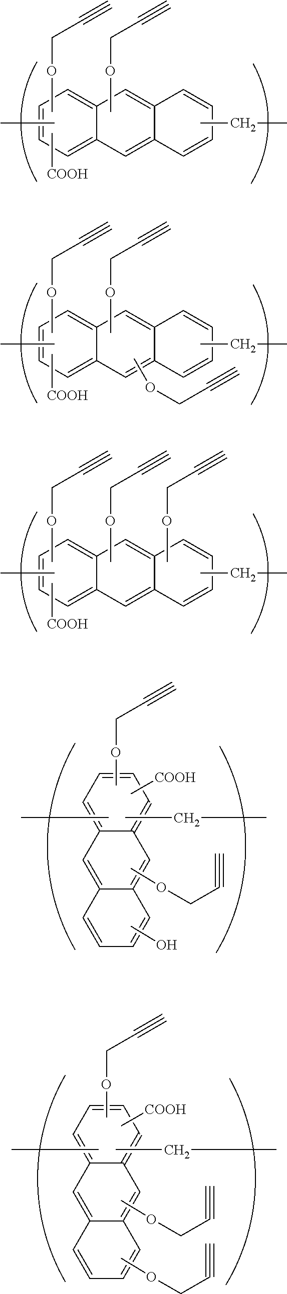

Examples of the repeat unit having formula (2) are shown below, but not limited thereto.

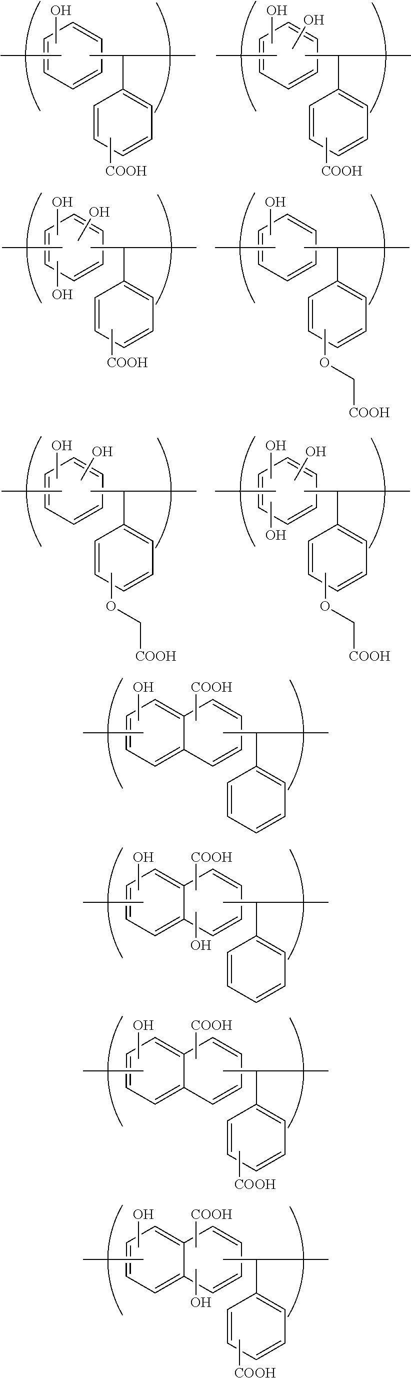

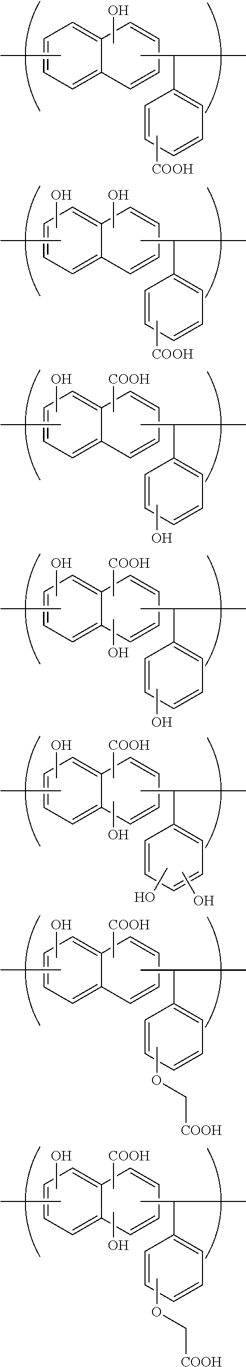

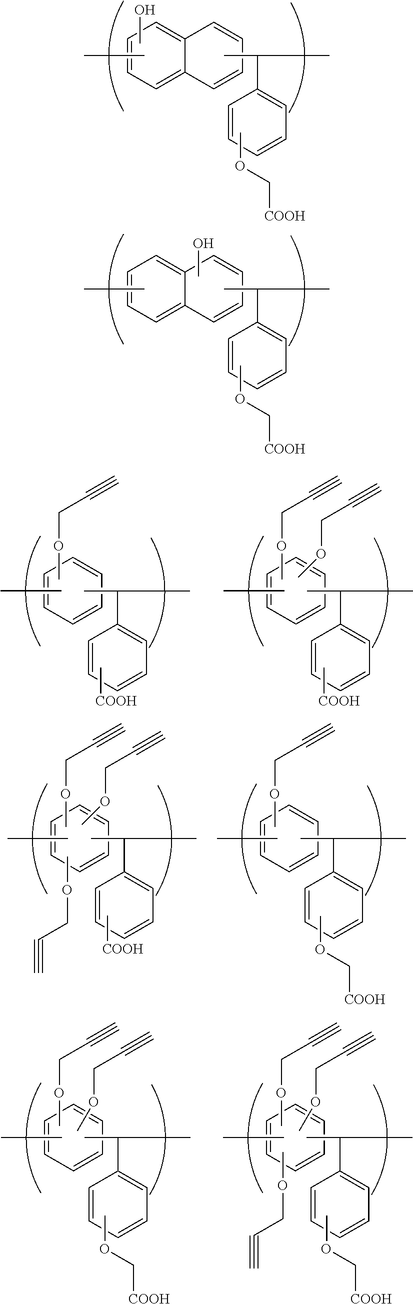

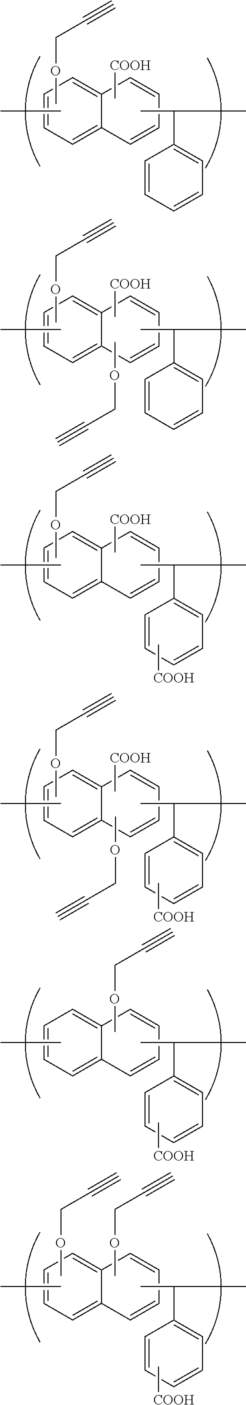

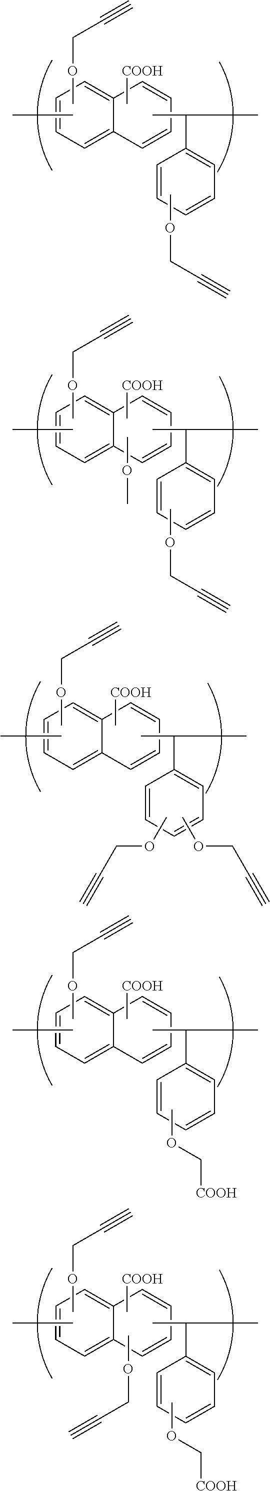

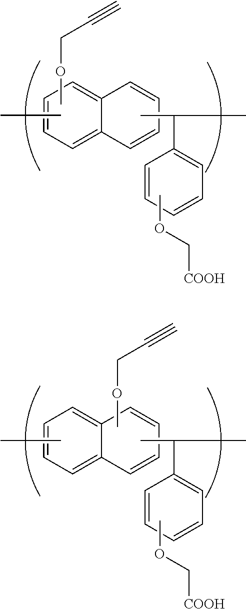

A polymer comprising repeat units having formula (1) or (2) wherein R¹ is hydroxy, referred to as polymer A, hereinafter, can be obtained from polycondensation reaction using a compound having the formula (a) and a compound having the formula (b) or (c).

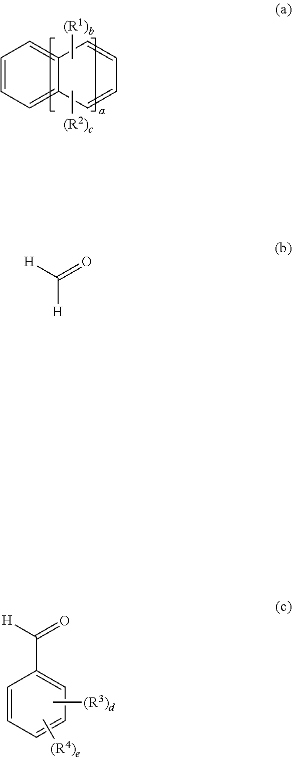

Herein, a to e and R¹ to R⁴ are as defined above.

The polycondensation reaction is generally carried out in a solventless system or in a solvent in the presence of an acid or base catalyst at room temperature or under cooling or heating if necessary. Examples of the solvent used herein include alcohols such as methanol, ethanol, isopropyl alcohol, butanol, ethylene glycol, propylene glycol, diethylene glycol, glycerol, methyl cellosolve, ethyl cellosolve, butyl cellosolve, and propylene glycol monomethyl ether; ethers such as diethyl ether, dibutyl ether, diethylene glycol diethyl ether, diethylene glycol dimethyl ether, tetrahydrofuran, and 1,4-dioxane; chlorine-based solvents such as methylene chloride, chloroform, dichloroethane and trichloroethylene; hydrocarbons such as hexane, heptane, benzene, toluene, xylene, and cumene; nitriles such as acetonitrile; ketones such as acetone, ethyl methyl ketone, and isobutyl methyl ketone; esters such as ethyl acetate, n-butyl acetate, and propylene glycol methyl ether acetate; lactones such as γ-butyrolactone; and aprotic polar solvents such as dimethyl sulfoxide, N,N-dimethylformamide, and hexamethyl phosphoric triamide. The solvent is preferably used in an amount of 0 to 2,000 parts by weight per 100 parts by weight of the starting compounds combined. The solvent may be used alone or in admixture.

Suitable acid catalysts include inorganic acids such as hydrochloric acid, hydrobromic acid, sulfuric acid, nitric acid, phosphoric acid, and heteropolyacids; organic acids such as oxalic acid, trifluoroacetic acid, methanesulfonic acid, benzenesulfonic acid, p-toluenesulfonic acid, and trifluoromethanesulfonic acid; and Lewis acids such as aluminum trichloride, aluminum ethoxide, aluminum isopropoxide, boron trifluoride, boron trichloride, boron tribromide, tin tetrachloride, tin tetrabromide, dibutyltin dichloride, dibutyltin dimethoxide, dibutyltin oxide, titanium tetrachloride, titanium tetrabromide, titanium(IV) methoxide, titanium(IV) ethoxide, titanium(IV) isopropoxide, and titanium(IV) oxide. Suitable base catalysts include inorganic bases such as sodium hydroxide, calcium hydroxide, barium hydroxide, sodium carbonate, sodium hydrogencarbonate, potassium carbonate, lithium hydride, sodium hydride, potassium hydride, and calcium hydride; alkyl metals such as methyl lithium, n-butyl lithium, magnesium methyl chloride, and magnesium ethyl bromide; alkoxides such as sodium methoxide, sodium ethoxide, and potassium t-butoxide; and organic bases such as triethylamine, diisopropylethylamine, N,N-dimethylaniline, pyridine, and 4-dimethylaminopyridine. The catalyst is preferably used in an amount of 0.001 to 100 parts by weight, more preferably 0.005 to 50 parts by weight per 100 parts by weight of the starting compounds.

For the polycondensation reaction, the temperature is preferably from −50° C. to nearly the boiling point of the solvent, more preferably from room temperature to about 100° C., and the time is preferably about 4 to 24 hours, more preferably about 4 to 10 hours.

The polycondensation reaction may be performed in various modes, for example, the mode of charging the starting compounds and the catalyst all at once, the mode of adding dropwise the starting compounds to the catalyst, and the mode of mixing the starting compounds and adding dropwise the catalyst to the mixture.

After the completion of polycondensation reaction, preferably unreacted compounds and catalyst are removed from the system. The removal method may be by elevating the temperature of the reactor at 130 to 230° C. and removing the volatiles at about 1 to 50 mmHg, by adding an adequate solvent or water to the system and fractionating the polymer, or by dissolving the polymer in a good solvent and re-precipitating in a poor solvent. A proper one may be selected from these methods depending on the properties of the reaction product.

A polymer comprising repeat units having formula (1) or (2) wherein R¹ is 2-propynyloxy can be prepared, for example, by reacting a polymer A with a propargyl halide. Examples of the propargyl halide include propargyl chloride, propargyl bromide, and propargyl iodide.

The reaction of polymer A with a propargyl halide may be carried out with reference to JP-A H01-503541, for example.

The resulting polymer should preferably have a weight average molecular weight (Mw) of 500 to 500,000, more preferably 1,000 to 100,000 versus polystyrene standards and a dispersity (Mw/Mn) of 1.2 to 2.0. By cutting off the monomer component, oligomer component and low molecular weight fractions having a Mw of up to 1,000, the amount of volatiles during bake is minimized. Then contamination around the bake cup is prevented and surface defects caused by volatile deposits dropping onto the wafer are eliminated.

The organic solvent used in the adherent film-forming composition is not particularly limited as long as the polymer and optional components are soluble therein. Suitable organic solvents include those described in U.S. Pat. No. 7,537,880 (JP-A 2008-111103, paragraphs [0144]-[0145]), specifically ketones such as cyclohexanone and methyl 2-n-amyl ketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone.

The amount of the organic solvent used in the adherent film-forming composition is preferably 3,000 to 30,000 parts by weight, more preferably 4,000 to 20,000 parts by weight per 100 parts by weight of the polymer comprising repeat units having formula (1) or (2). The organic solvent may be used alone or in admixture.

The adherent film-forming composition may contain an acid generator and a crosslinker for further promoting crosslinking reaction.

The acid generator may be either a thermal acid generator adapted to generate an acid through thermal decomposition or a photoacid generator adapted to generate an acid upon light exposure. Suitable acid generators include onium salts, diazomethane derivatives, glyoxime derivatives, bissulfone derivatives, sulfonic acid esters of N-hydroxyimide compounds, β-ketosulfonic acid derivatives, disulfone derivatives, nitrobenzyl sulfonate derivatives, sulfonic acid salts, and sulfonic acid ester derivatives. Specifically, those compounds described in JP-A 2008-065303, paragraphs [0081]-[0111] are included. When the adherent film-forming composition contains the acid generator, its amount is preferably 0.01 to 100 parts by weight, more preferably 0.01 to 10 parts by weight per 100 parts by weight of the polymer comprising repeat units having formula (1) or (2). The acid generator may be used alone or in admixture.

Examples of the crosslinker include melamine compounds, guanamine compounds, glycoluril compounds, or urea compounds which are substituted with at least one of methylol, alkoxymethyl and acyloxymethyl groups, epoxy compounds, thioepoxy compounds, isocyanate compounds, azide compounds, and compounds containing a double bond such as alkenyl ether. Specifically, those compounds described in JP-A 2008-065303, paragraphs [0074]-[0080] are included. When the adherent film-forming composition contains the crosslinker, its amount is preferably 0.1 to 100 parts by weight, more preferably 0.1 to 30 parts by weight per 100 parts by weight of the polymer comprising repeat units having formula (1) or (2). The crosslinker may be used alone or in admixture.

The adherent film-forming composition may contain a surfactant for facilitating spin coating. Suitable surfactants include nonionic surfactants such as polyoxyethylene alkyl ethers, polyoxyethylene alkyl allyl ethers, polyoxyethylene polyoxypropylene block copolymers, sorbitan fatty acid esters, and polyoxyethylene sorbitan fatty acid esters as well as fluorochemical surfactants and partially fluorinated oxetane ring-opening polymerization products. Specifically, those compounds described in JP-A 2009-269953, paragraphs [0142]-[0147] are included. When the adherent film-forming composition contains the surfactant, its amount is preferably 0.001 to 1 part by weight, more preferably 0.001 to 0.5 part by weight per 100 parts by weight of the polymer comprising repeat units having formula (1) or (2). The surfactant may be used alone or in admixture.

The adherent film-forming composition may contain a basic compound for improving storage stability. The basic compound plays the role of a quencher (or acid quenching agent) for preventing a minor amount of an acid generated by the acid generator from forwarding crosslinking reaction. Suitable basic compounds include primary, secondary and tertiary aliphatic amines, mixed amines, aromatic amines, heterocyclic amines, nitrogen-containing compounds having carboxy group, nitrogen-containing compounds having sulfonyl group, nitrogen-containing compounds having hydroxy group, nitrogen-containing compounds having hydroxyphenyl group, alcoholic nitrogen-containing compounds, amide derivatives, and imide derivatives. Specifically, those compounds described in JP-A 2008-065303, paragraphs [0112]-[0119] are included. When the adherent film-forming composition contains the basic compound, its amount is preferably 0.01 to 30 parts by weight, more preferably 0.01 to 10 parts by weight per 100 parts by weight of the polymer comprising repeat units having formula (1) or (2). The basic compound may be used alone or in admixture.

The adherent film has a thickness of preferably 2 nm to less than 100 nm, more preferably 2 nm to 50 nm.

In the manufacture of semiconductor devices wherein small-size patterns are formed by the multilayer resist process, the adherent film is effective for preventing a line-and-space pattern from collapsing or for forming a contact hole pattern with improved CDU.

The tight adhesion between the adherent film and the resist film is attributable to the inclusion of carboxy groups in the adherent film. When the resist composition to be described later is coated and baked on the adherent film, the hypervalent iodine compound functions to form a crosslink between a carboxy group on the adherent film surface and a carboxy group of the carboxy-containing compound in the resist composition. Since the relevant resist composition is of positive tone, the crosslinking between the pattern of unexposed region and the surface of the adherent film provides resistance against the stress during development, prevents the line-and-space pattern from collapsing, and is useful in forming a resist pattern with a high aspect ratio. When a contact hole pattern is formed, on the other hand, the tight adhesion between the resist film and the adherent film prevents the developer from entering between the resist film and the resist underlying film to cause swelling. Then a contact hole pattern with improved CDU is formed.

### Resist Underlying Film and Silicon-Containing Intermediate Film

In a preferred embodiment, the laminate of the invention further comprises a resist underlying film and a silicon-containing intermediate film disposed between the substrate and the adherent film in the order from the substrate side.

The resist underlying film may be any of well-known underlying films used in the micropatterning method based on the multilayer resist process. Typical of the resist underlying film is spin-on carbon ODL-301 (Shin-Etsu Chemical Co., Ltd., carbon content 88 wt %).

The resist underlying film has a thickness of preferably 40 to 500 nm, more preferably 100 to 300 nm.

The silicon-containing intermediate film is preferably a silicon-containing resist intermediate film which is formed from a silicon-containing resist intermediate film-forming solution or an inorganic hard mask intermediate film which is formed by the CVD or atomic layer deposition (ALD) method.

As the silicon-containing resist intermediate film for the four-layer resist process, an intermediate film based on polysilsesquioxane is preferably used. By providing the silicon-containing resist intermediate film with an antireflective effect, reflection is suppressed. Particularly in the case of exposure at wavelength 193 nm, when a material containing much aromatic groups and having high resistance to substrate etching is used as the resist underlying film, the value of k increases and the substrate reflection becomes high. By providing the silicon-containing resist intermediate film for suppressing reflection, the substrate reflection can be reduced to 0.5% or below. For the silicon-containing resist intermediate film having the antireflective effect, a film based on anthracene is preferred for exposure at wavelength 248 nm or 157 nm, and a film based on polysilsesquioxane having a phenyl group or photo-absorptive group bearing a silicon-silicon bond as a pendant and adapted to crosslink with the aid of acid or heat is preferred for exposure at wavelength 193 nm.

The silicon-containing resist intermediate film has a thickness of preferably 10 to 70 nm, more preferably 20 to 50 nm.

The inorganic hard mask intermediate film is preferably selected from a silicon oxide film, silicon nitride film and silicon oxynitride film. Inter alia, the SiON film is most preferred because it has a high antireflective effect.

The inorganic hard mask intermediate film has a thickness of preferably 5 to 200 nm, more preferably 10 to 100 nm.

### Resist Film

The resist film is formed from a resist composition comprising a hypervalent iodine compound, a carboxy-containing compound, and a solvent.

The hypervalent iodine compound is a three-coordinate hypervalent iodine compound having the formula (3), (4) or (5).

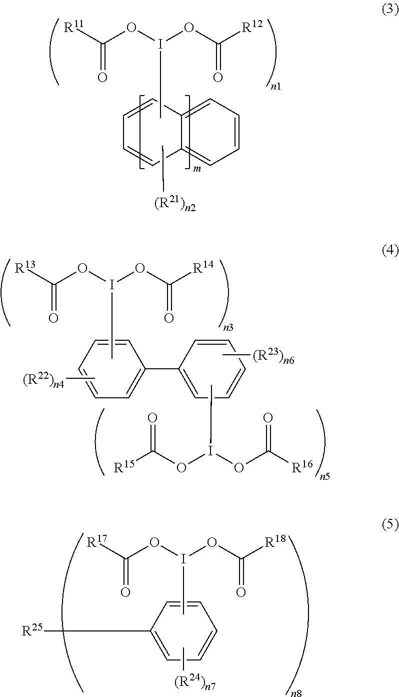

In formulae (3) to (5), m is 0, 1 or 2. When m=0, n1 is 1, 2 or 3, n2 is 0, 1, 2, 3, 4 or 5 and 1≤n1+n2≤6. When m=1, n1 is 1, 2 or 3, n2 is 0, 1, 2, 3, 4, 5, 6 or 7 and 1≤n1+n2≤8. When m=2, n1 is 1, 2 or 3, n2 is 0, 1, 2, 3, 4, 5, 6, 7, 8 or 9 and 1≤n1+n2≤10. The subscript n3 is 1 or 2, n4 is 0, 1, 2, 3 or 4, 1≤n3+n4≤5, n5 is 1 or 2, n6 is 0, 1, 2, 3 or 4, and 1≤n5+n6≤5. The subscript n7 is 0, 1, 2, 3 or 4, and n8 is 1, 2, 3 or 4.

In formulae (3) to (5), R¹¹ to R¹⁸ are each independently halogen or a C₁-C₁₀ hydrocarbyl group which may contain a heteroatom. R¹¹ and R¹², R¹³ and R¹⁴, R¹⁵ and R¹⁶, or R¹⁷ and R¹⁸ may bond together to form a ring with the carbon atoms to which they are attached and the intervenient atoms.

Suitable halogen atoms represented by R¹¹ to R¹⁸ include fluorine, chlorine, bromine and iodine. The C₁-C₁₀ hydrocarbyl group represented by R¹¹ to R¹⁸ may be saturated or unsaturated and straight, branched or cyclic. Examples thereof include C₁-C₁₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₂-C₁₀ alkenyl groups such as vinyl and allyl; C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹¹ to R¹⁸ are preferably C₁-C₄ hydrocarbyl groups.

In formulae (3) to (5), R²¹ to R²⁴ are each independently halogen or a C₁-C₄₀ hydrocarbyl group which may contain a heteroatom. When n2 is 2 or more, a plurality of R²¹ may be identical or different and a plurality of R²¹ may bond together to form a ring with the carbon atoms on the aromatic ring to which they are attached. When n4 is 2 or more, a plurality of R²² may be identical or different and a plurality of R²² may bond together to form a ring with the carbon atoms on the aromatic ring to which they are attached. When n6 is 2 or more, a plurality of R²³ may be identical or different and a plurality of R²³ may bond together to form a ring with the carbon atoms on the aromatic ring to which they are attached. When n7 is 2 or more, a plurality of R²⁴ may be identical or different and a plurality of R²⁴ may bond together to form a ring with the carbon atoms on the aromatic ring to which they are attached.

Suitable halogen atoms represented by R²¹ to R²⁴ include fluorine, chlorine, bromine and iodine. The C₁-C₄₀ hydrocarbyl group represented by R²¹ to R²⁴ may be saturated or unsaturated and straight, branched or cyclic. Examples thereof include C₁-C₄₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl, and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

In formula (5), R²⁵ is a C₁-C₄₀ (n8)-valent hydrocarbon group or C₂-C₄₀ (n8)-valent heterocyclic group. When n8=2, R²⁵ may also be an ether bond, carbonyl group, azo group, thioether bond, carbonate bond, carbamate bond, sulfinyl group, sulfonyl group or thioketone bond. Some or all of the hydrogen atoms in the (n8)-valent hydrocarbon group or (n8)-valent heterocyclic group may be substituted by a heteroatom-containing moiety, and some —CH₂— in the (n8)-valent hydrocarbon group may be replaced by a heteroatom-containing moiety. R²⁴ and R²¹ may bond together to form a ring with the carbon atoms to which they are attached and the intervenient atoms.

The (n8)-valent hydrocarbon group represented by R²¹ may be saturated or unsaturated and straight, branched or cyclic. The (n8)-valent hydrocarbon group is obtained by eliminating “n8” number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Examples of the C₁-C₄₀ alkane include methane, ethane, propane, butane, pentane, hexane, heptane, octane, nonane, decane, and structural isomers thereof.

Examples of the C₂-C₄₀ alkene include ethylene, propylene, butene, pentene, hexene, heptene, octene, nonene, decene, and structural isomers thereof.

Examples of the C₂-C₄₀ alkyne include acetylene, propyne, butyne, pentyne, hexyne, heptyne, octyne, nonyne, decyne, and structural isomers thereof.

Examples of the C₃-C₄₀ cyclic saturated hydrocarbon include cyclopropane, cyclobutane, cyclohexane, cycloheptane, cyclooctane, adamantane, and norbornane.

Examples of the C₃-C₄₀ cyclic unsaturated hydrocarbon include cyclopropene, cyclobutene, cyclopentene, cyclohexene, cycloheptene, cyclooctene, and norbornene.

Examples of the C₆-C₄₀ aromatic hydrocarbon include benzene, naphthalene and biphenyl.

The (n8)-valent heterocyclic group represented by R²⁵ is obtained by eliminating “n8” number of hydrogen atoms from a heterocyclic compound. Suitable heterocyclic compounds include furane, pyridine, pyrazole, and thiazolidine.

Also included are the (n8)-valent hydrocarbon groups or (n8)-valent heterocyclic groups in which some or all of the hydrogen atoms are substituted by a moiety containing a heteroatom such as oxygen, sulfur, nitrogen or halogen so that the group may contain a hydroxy moiety, cyano moiety, fluorine, chlorine, bromine, or iodine; and the (n8)-valent hydrocarbon group in which some —CH₂— is replaced by a moiety containing a heteroatom such as oxygen, sulfur or nitrogen so that the group may contain a carbonyl moiety, ether bond, thioether bond, ester bond, sulfonate ester bond, carbonate bond, carbamate bond, lactone ring, sultone ring, or carboxylic anhydride (—C(═O)—O—C(═O)—).

Examples of the hypervalent iodine compound having formula (3) are shown below, but not limited thereto.

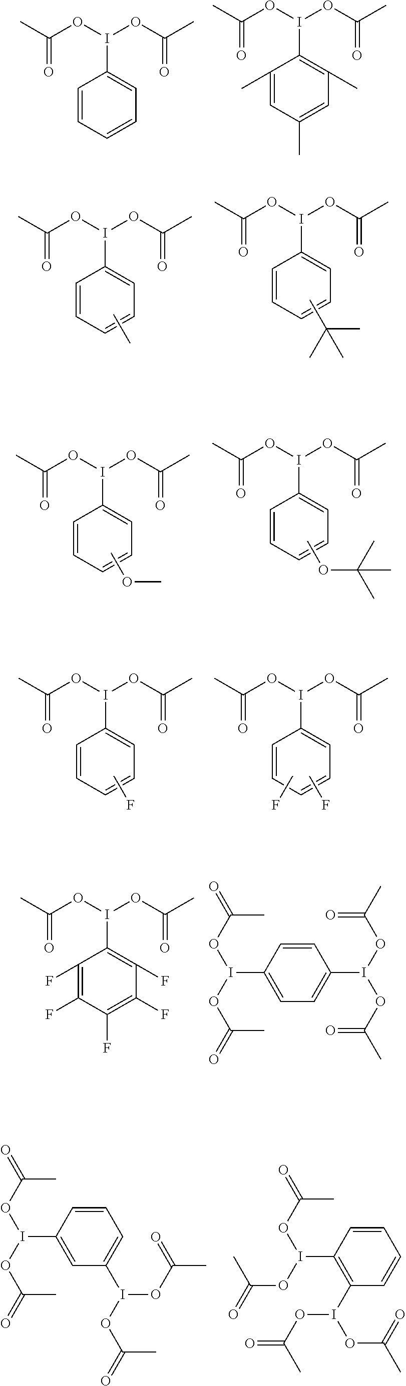

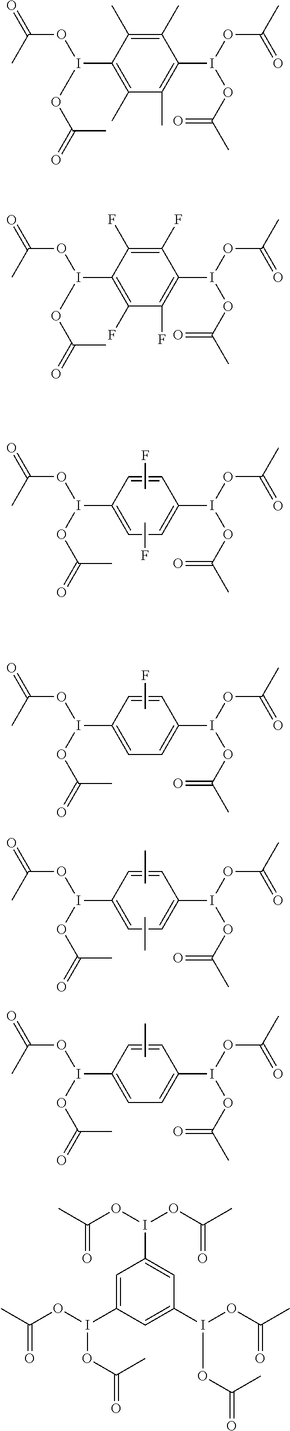

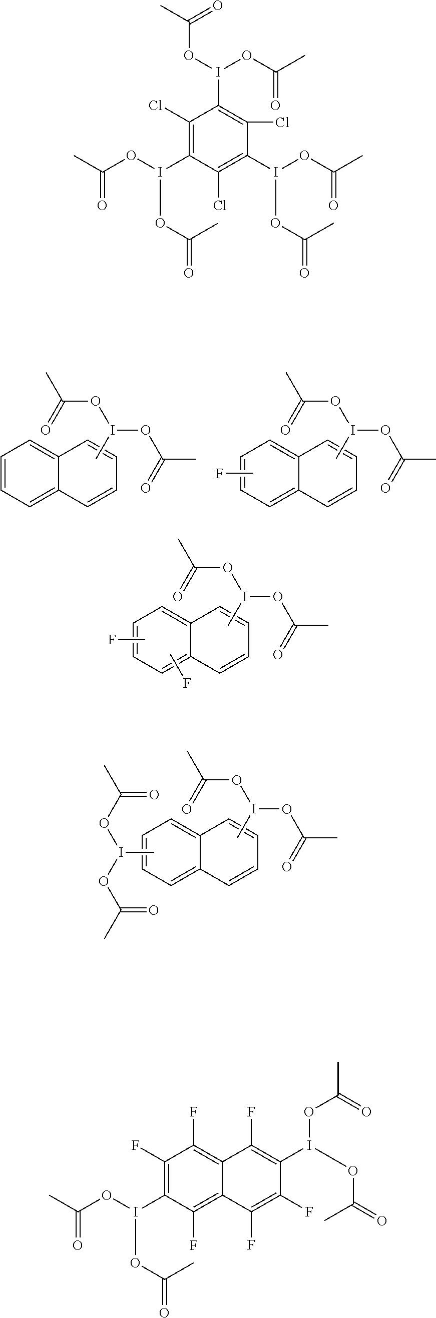

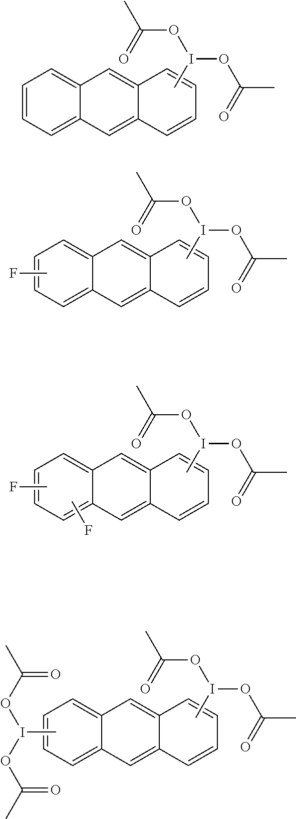

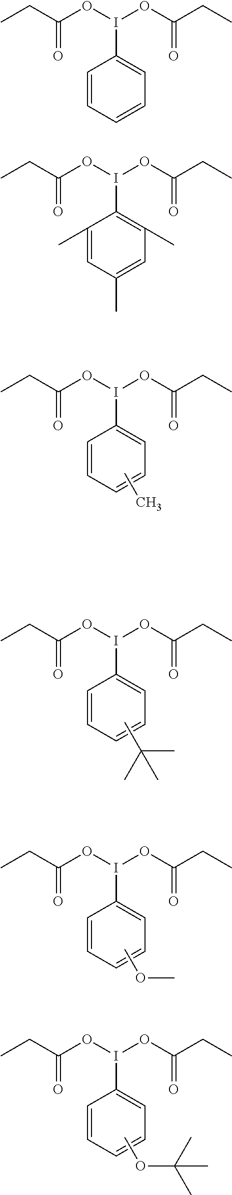

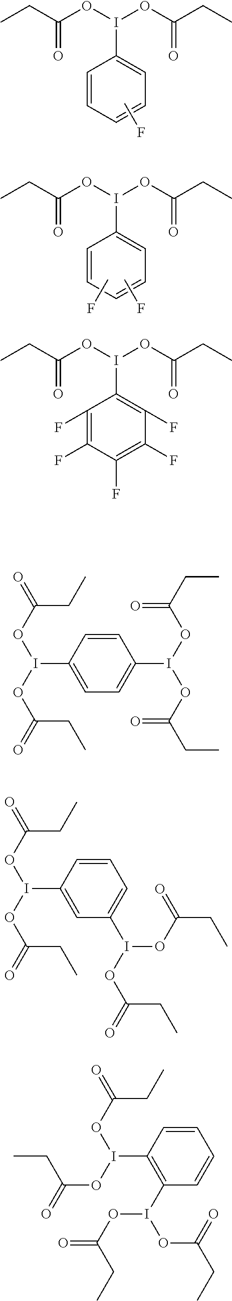

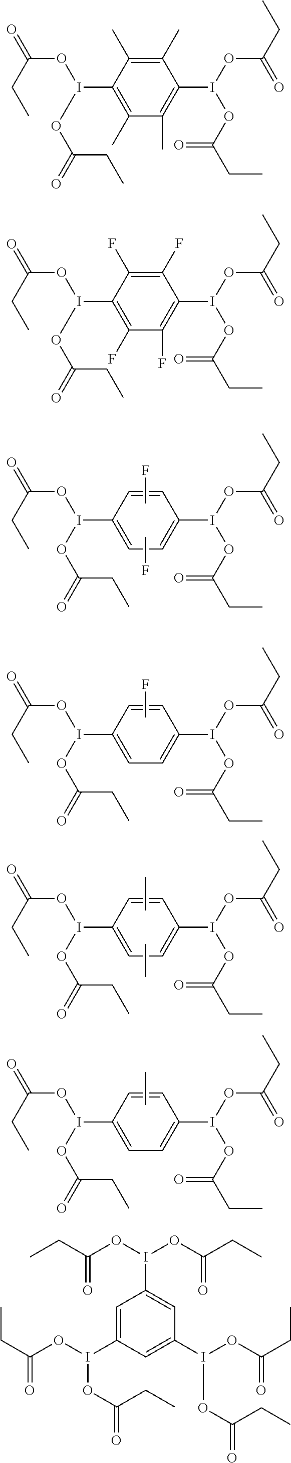

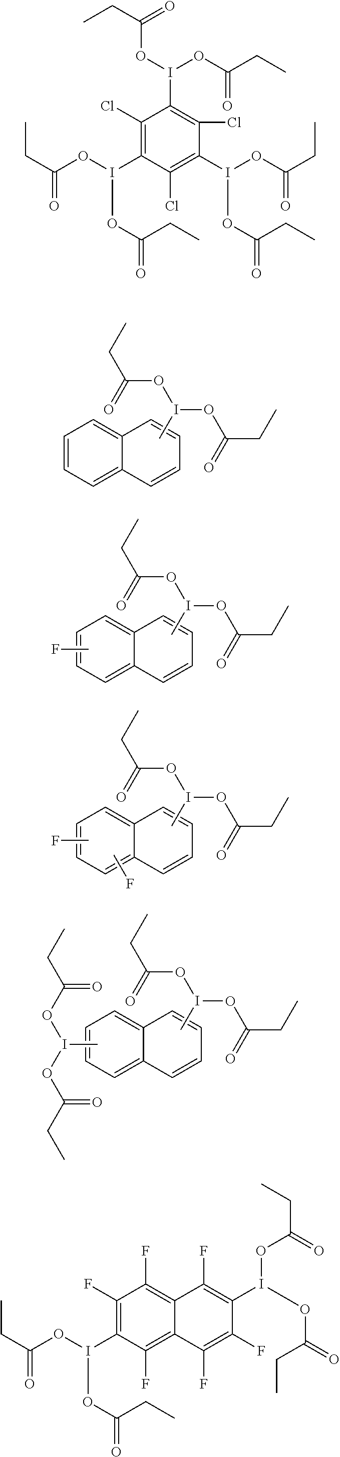

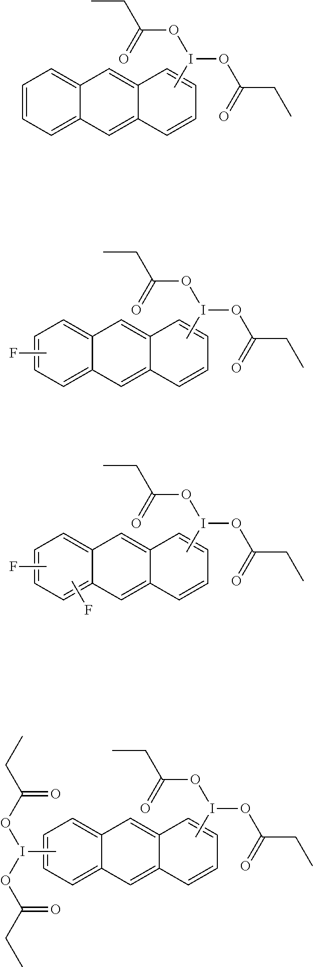

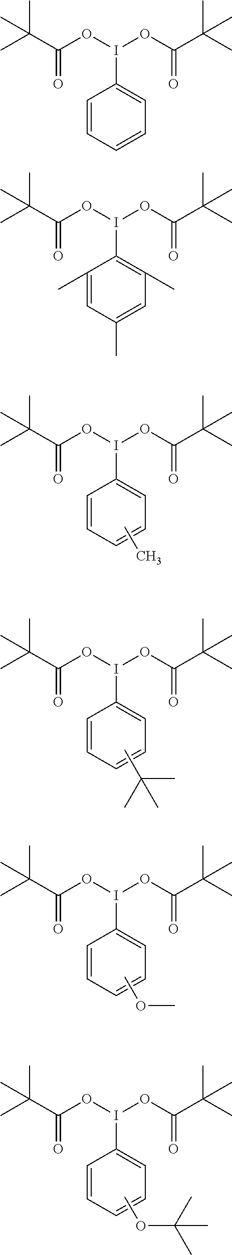

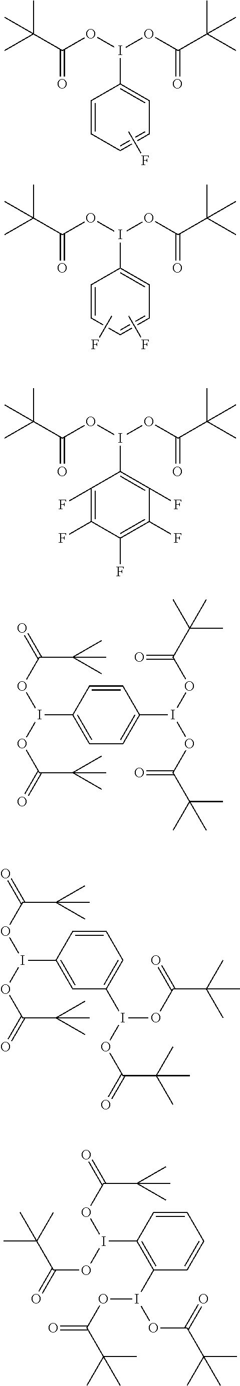

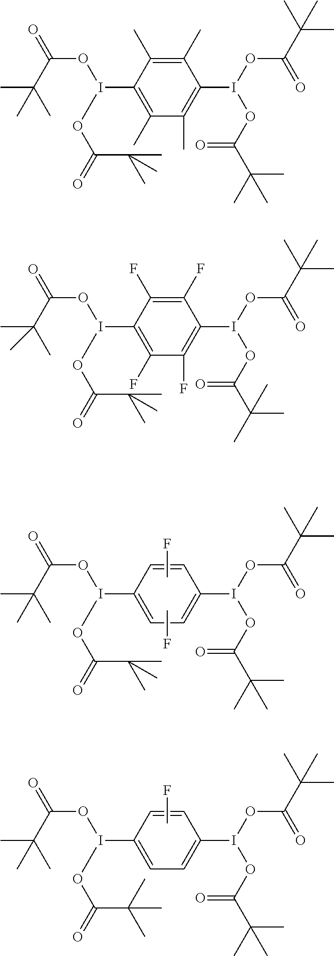

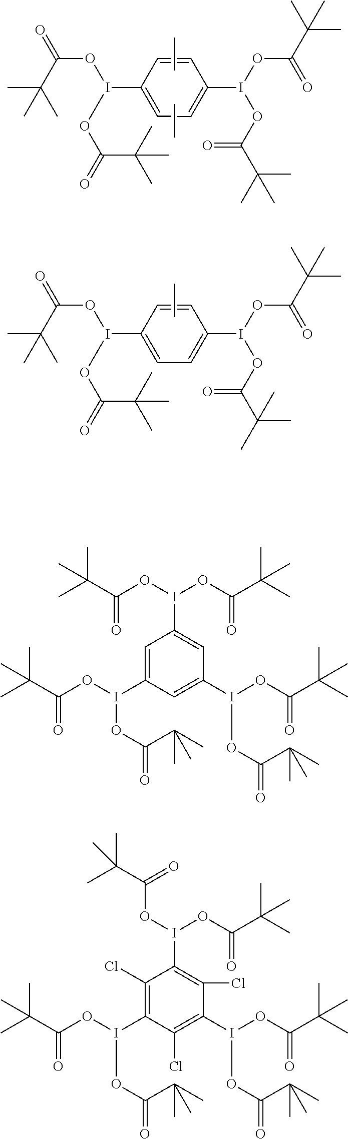

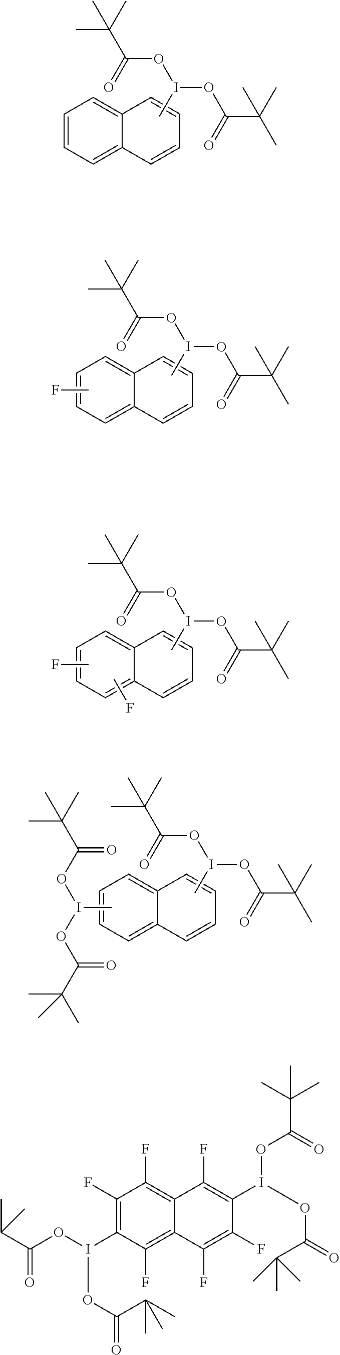

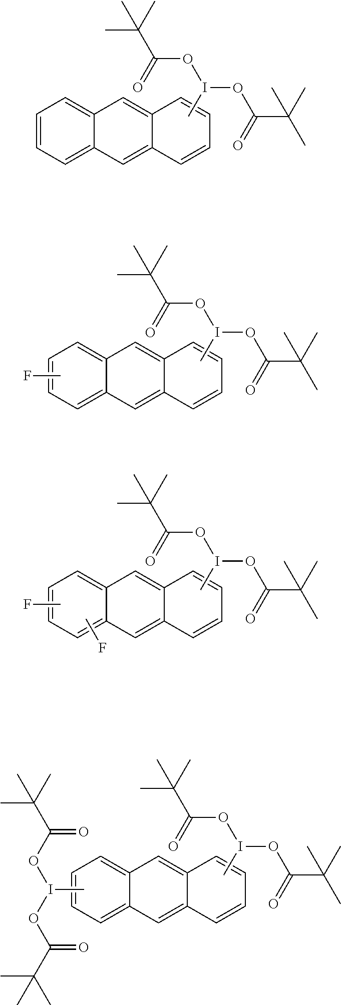

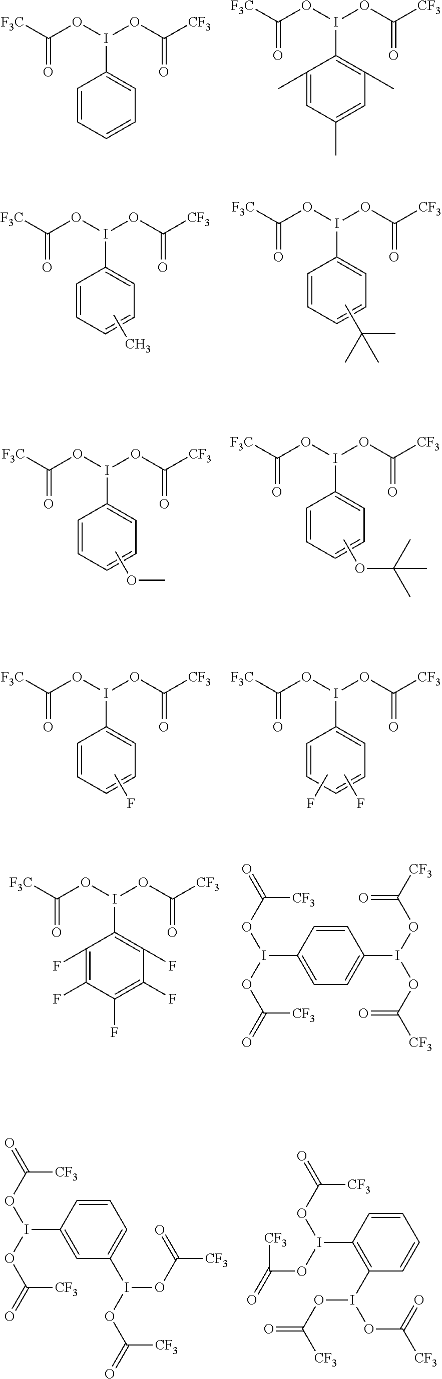

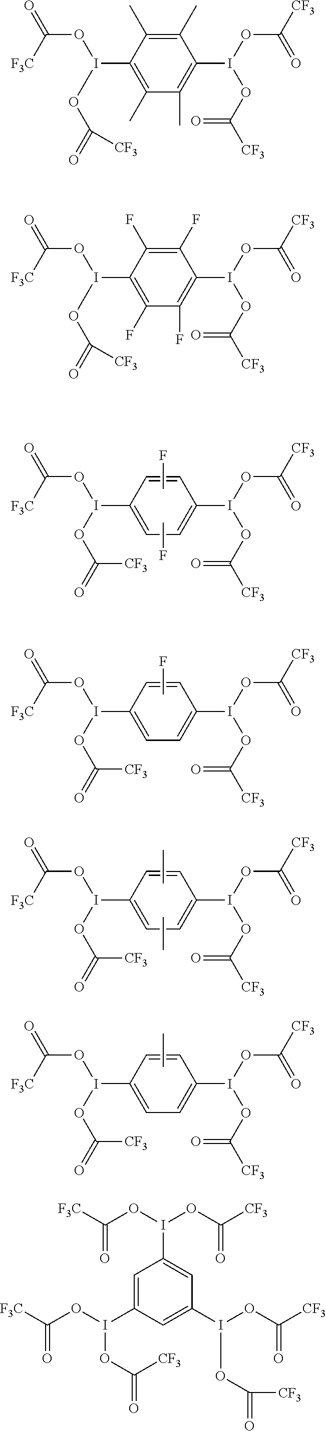

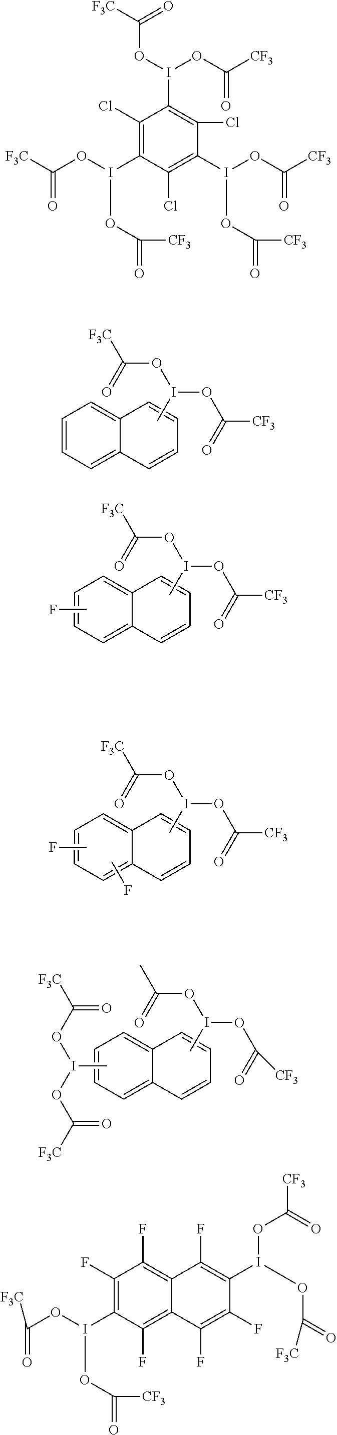

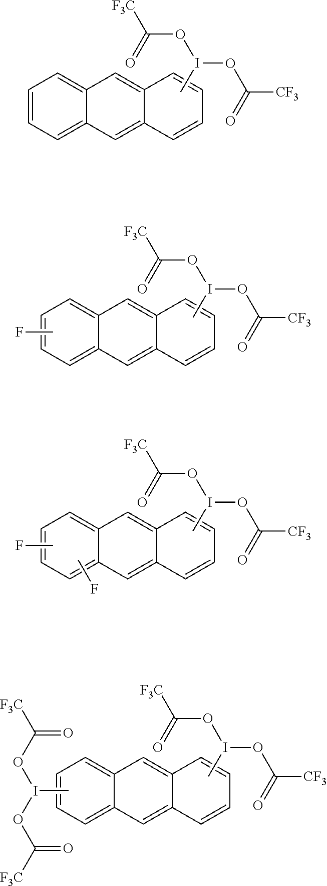

Examples of the hypervalent iodine compound having formula (4) are shown below, but not limited thereto.

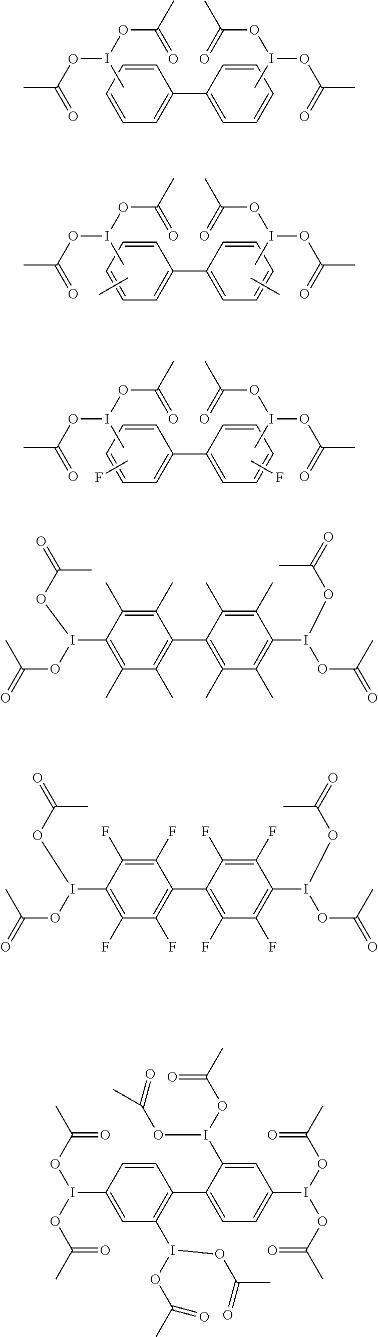

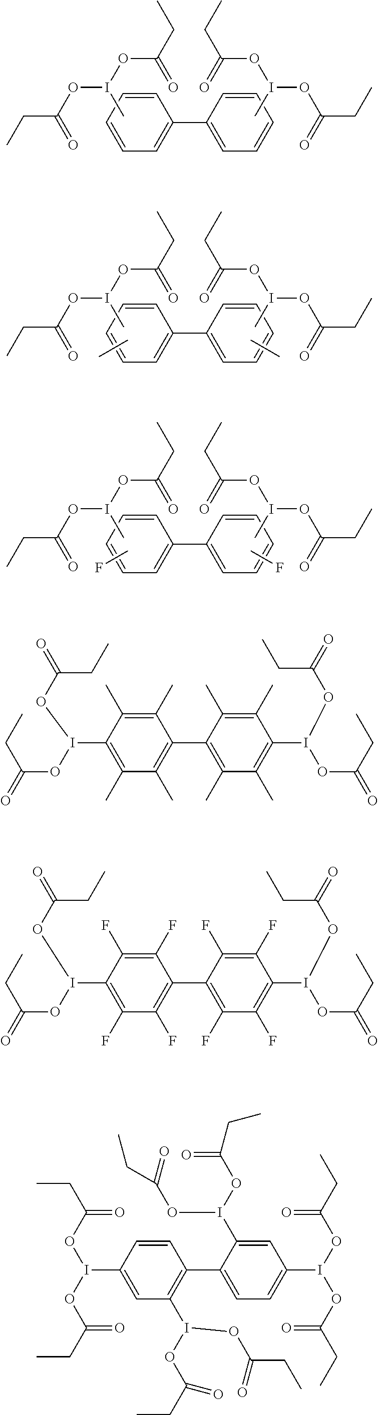

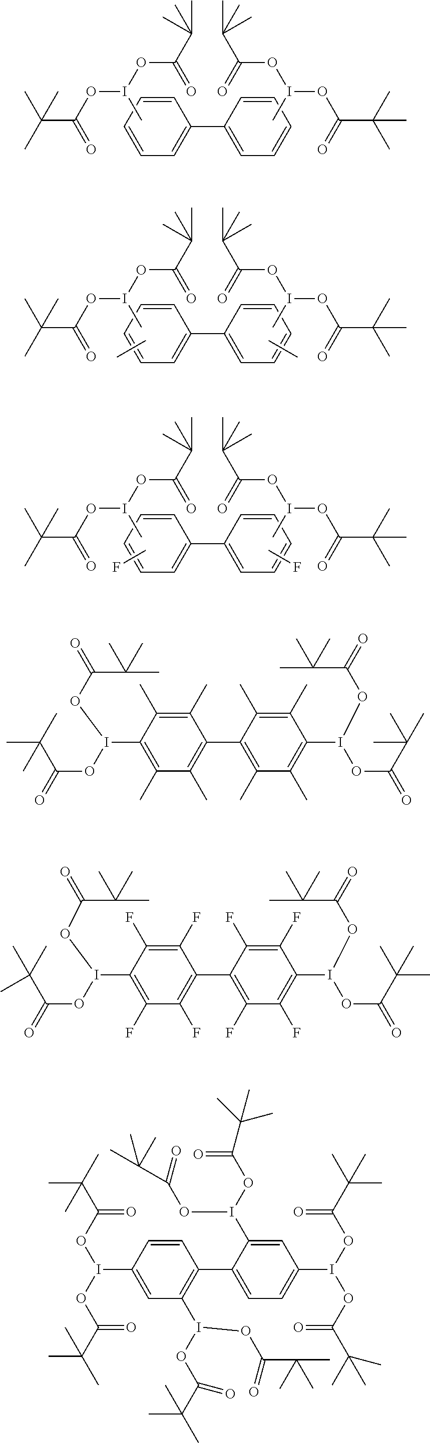

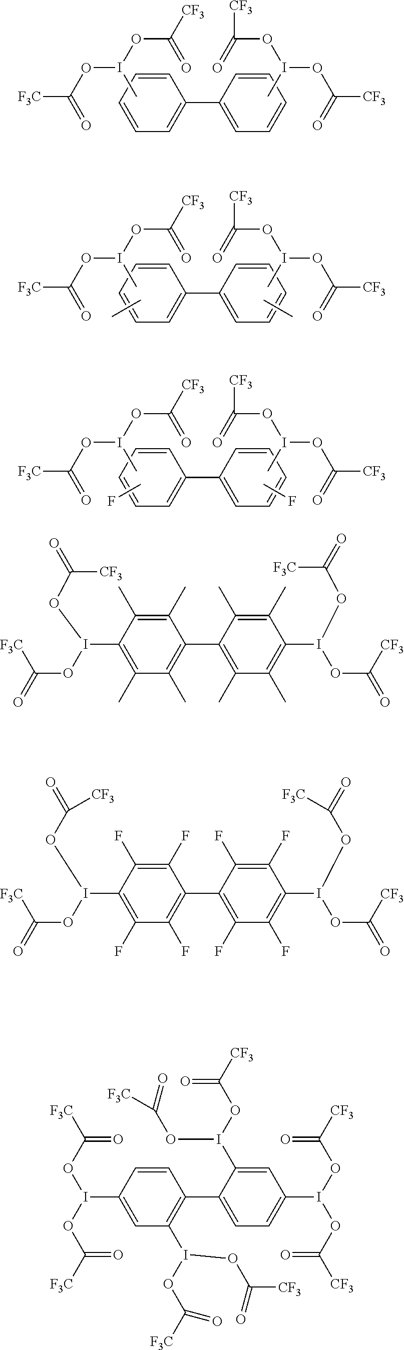

Examples of the hypervalent iodine compound having formula (5) are shown below, but not limited thereto.

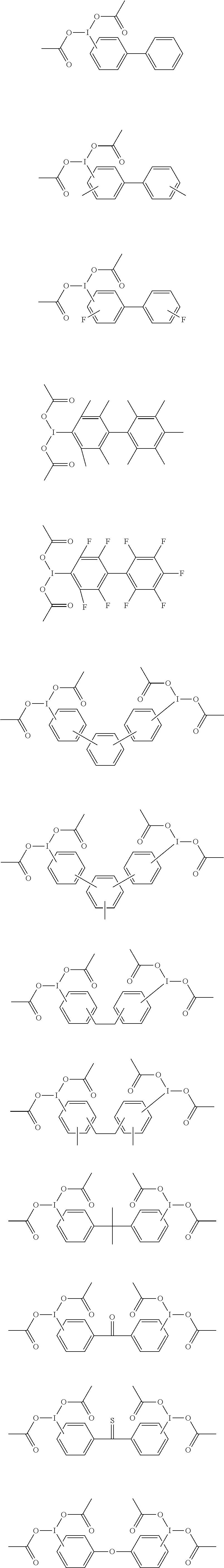

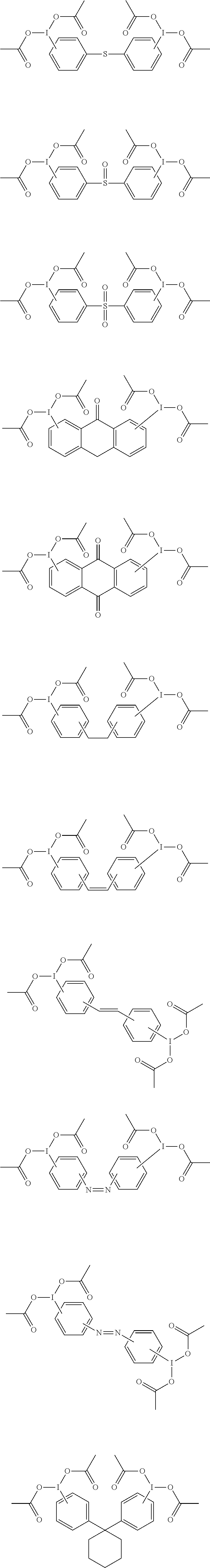

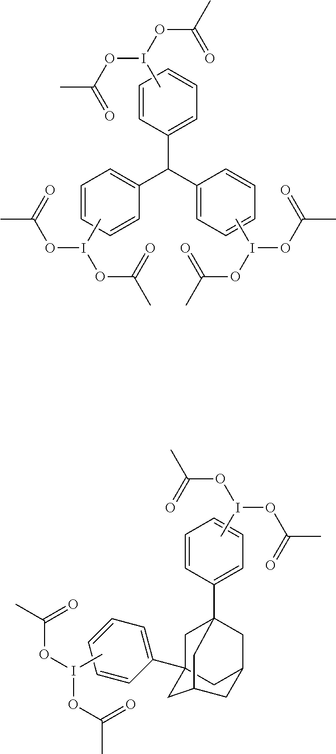

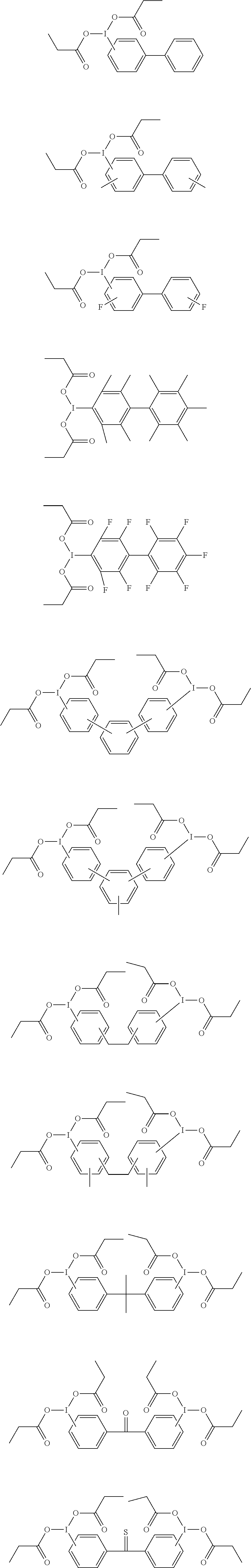

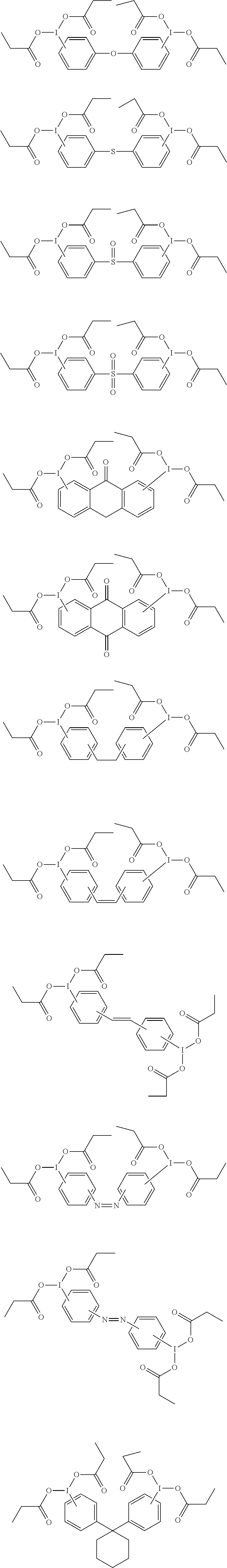

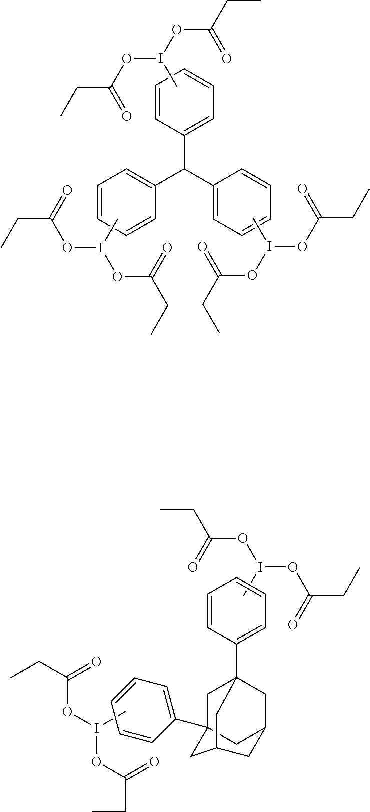

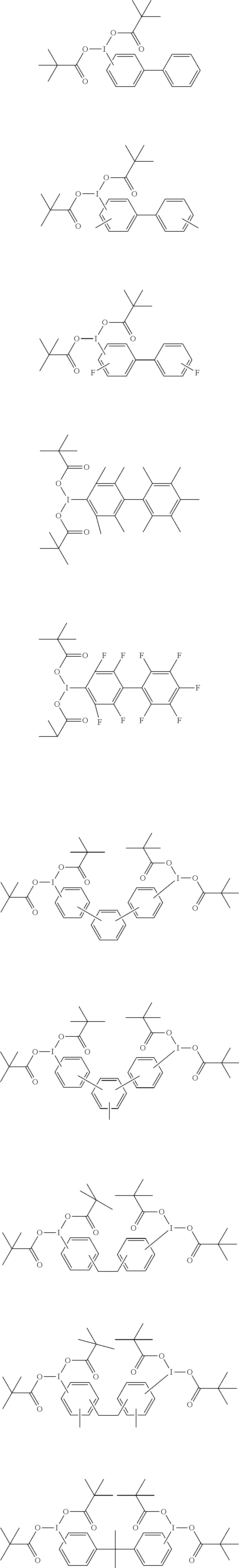

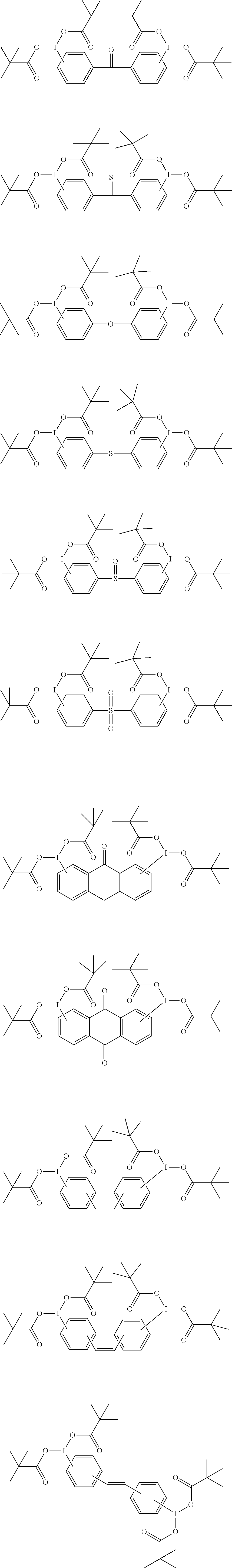

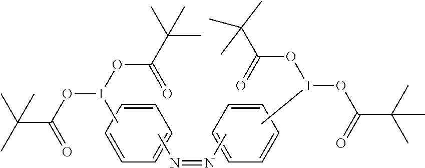

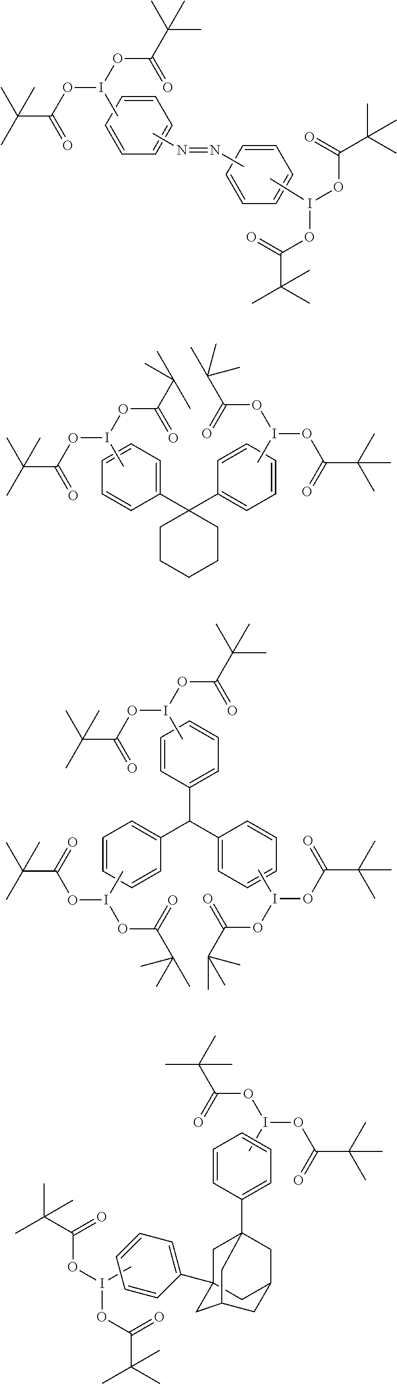

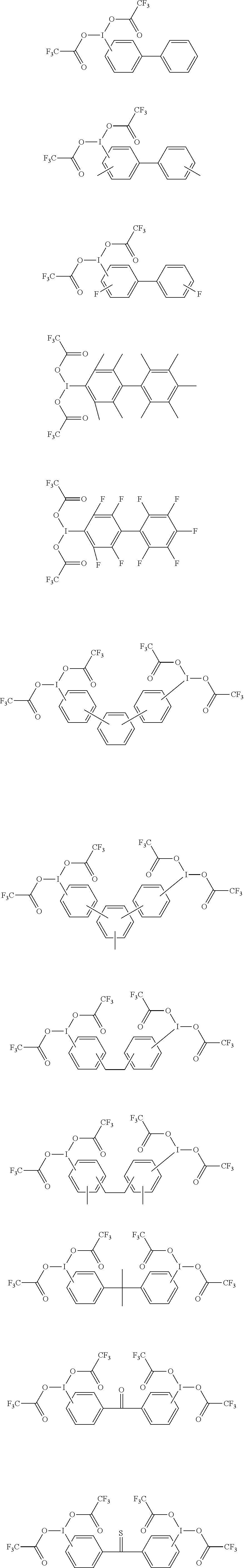

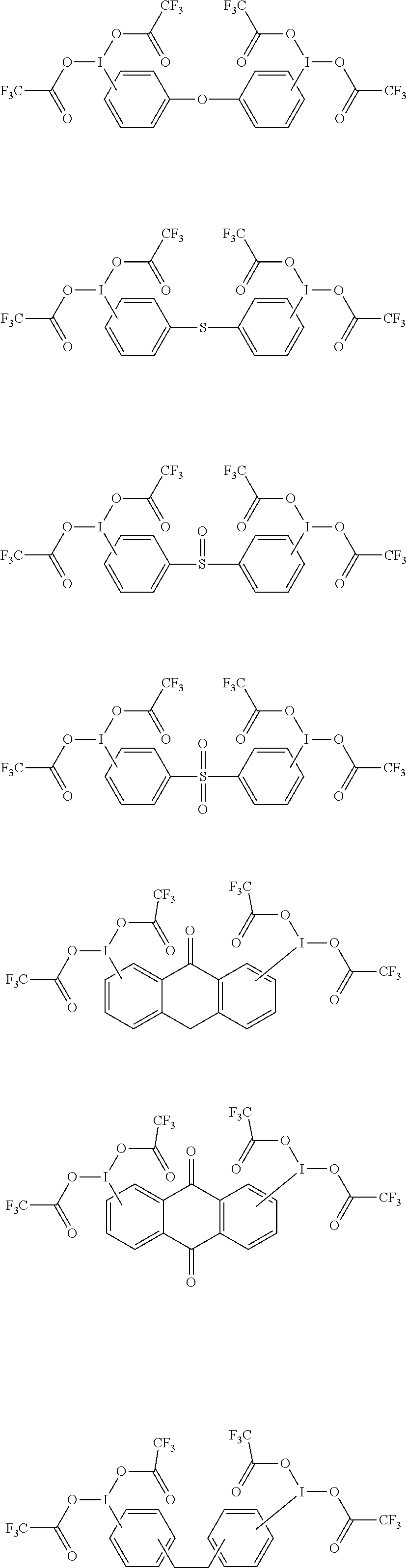

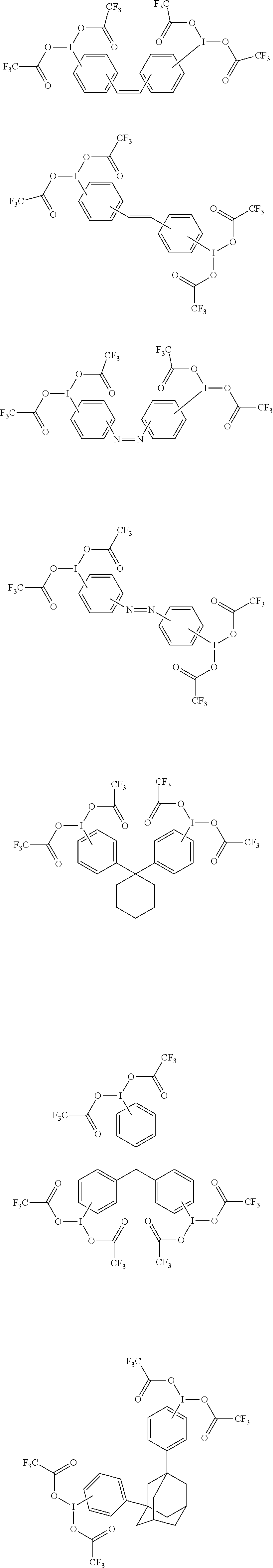

The carboxy-containing compound is preferably a polymer comprising repeat units having the formula (6) or a compound having the formula (7).

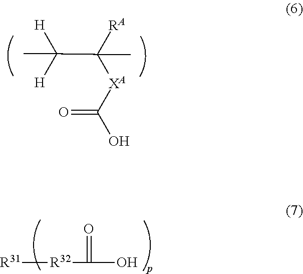

In formula (6), R^{A} is hydrogen, halogen, methyl or trifluoromethyl. X^{A} is a single bond, phenylene, naphthylene, or *—C(═O)—O—X^{A1}—. X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone.

In formula (7), p is 1, 2, 3 or 4.

In formula (7), R³¹ is a C₁-C₄₀ p-valent hydrocarbon group or C₂-C₄₀ p-valent heterocyclic group. When p=2, R³¹ may also be an ether bond, carbonyl group, azo group, thioether bond, carbonate bond, carbamate bond, sulfinyl group or sulfonyl group. Some or all of the hydrogen atoms in the p-valent hydrocarbon group or p-valent heterocyclic group may be substituted by a heteroatom-containing moiety, and some —CH₂— in the p-valent hydrocarbon group may be replaced by a heteroatom-containing moiety.

In formula (7), R³² is a single bond or C₁-C₁₀ hydrocarbylene group, some or all of the hydrogen atoms in the hydrocarbylene group may be substituted by a heteroatom-containing moiety, and some —CH₂— in the hydrocarbylene group may be replaced by a heteroatom-containing moiety. When p is 2, 3 or 4, a plurality of R³² may be identical or different.

The p-valent hydrocarbon group represented by R³¹ may be saturated or unsaturated and straight, branched or cyclic. The p-valent hydrocarbon group is obtained by eliminating “p” number of hydrogen atoms from a hydrocarbon. Suitable hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Examples of the C₁-C₄₀ alkane include methane, ethane, propane, butane, pentane, hexane, heptane, octane, nonane, decane, and structural isomers thereof.

Examples of the C₂-C₄₀ alkene include ethylene, propylene, butene, pentene, hexene, heptane, octene, nonene, decene, and structural isomers thereof.

Examples of the C₂-C₄₀ alkyne include acetylene, propyne, butyne, pentyne, hexyne, heptyne, octyne, nonyne, decyne, and structural isomers thereof.

Examples of the C₃-C₄₀ cyclic saturated hydrocarbon include cyclopropane, cyclobutane, cyclohexane, cycloheptane, cyclooctane, adamantane, and norbornane.

Examples of the C₃-C₄₀ cyclic unsaturated hydrocarbon include cyclopropene, cyclobutene, cyclopentene, cyclohexene, cycloheptene, cyclooctene, and norbornene.

Examples of the C₆-C₄₀ aromatic hydrocarbon include benzene, naphthalene and biphenyl.

The p-valent heterocyclic group represented by R³¹ is obtained by eliminating “p” number of hydrogen atoms from a heterocyclic compound. Suitable heterocyclic compounds include furane, pyridine, pyrazole, and thiazolidine.

Also included are the p-valent hydrocarbon groups or p-valent heterocyclic groups in which some or all of the hydrogen atoms are substituted by a moiety containing a heteroatom such as oxygen, sulfur, nitrogen or halogen so that the group may contain a hydroxy moiety, cyano moiety, fluorine, chlorine, bromine, or iodine; and the p-valent hydrocarbon group in which some —CH₂— is replaced by a moiety containing a heteroatom such as oxygen, sulfur or nitrogen so that the group may contain a carbonyl moiety, ether bond, thioether bond, ester bond, sulfonate ester bond, carbonate bond, carbamate bond, lactone ring, sultone ring, or carboxylic anhydride (—C(═O)—O—C(═O)—).

The hydrocarbylene group represented by R³² may be saturated or unsaturated and straight, branched or cyclic. Examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl; C₃-C₂₀ cyclic saturated hydrocarbylene groups such as cyclopentanediyl, cyclohexanediyl, norbornanediyl and adamantanediyl; C₂-C₂₀ unsaturated aliphatic hydrocarbylene groups such as vinylene and propene-1,3-diyl; C₆-C₂₀ arylene groups such as phenylene and naphthylene; and combinations thereof. In these hydrocarbylene groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, thioether bond, ester bond, sulfonate ester bond, carbonate bond, carbamate bond, lactone ring, sultone ring, or carboxylic anhydride (—C(═O)—O—C(═O)—).

Of the carboxylic acids having formula (7), those wherein p is 2, 3 or 4 are preferred. When these carboxylic acids are mixed with the hypervalent iodine compound, there is a likelihood of forming a robust resist film having a high molecular weight, which is preferred in view of etch resistance and developer resistance.

Examples of the carboxy-containing repeat unit having formula (6) are shown below, but not limited thereto. Herein R^{A} is as defined above.

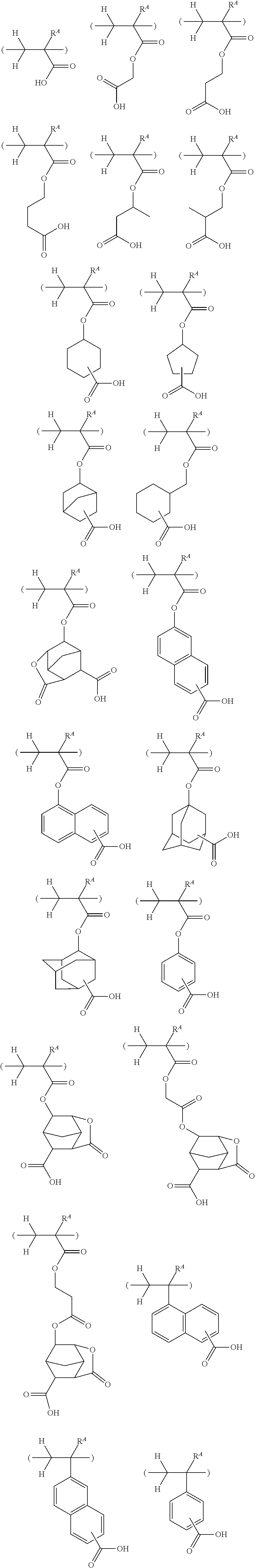

Examples of the carboxylic acid having formula (7) are shown below, but not limited thereto.

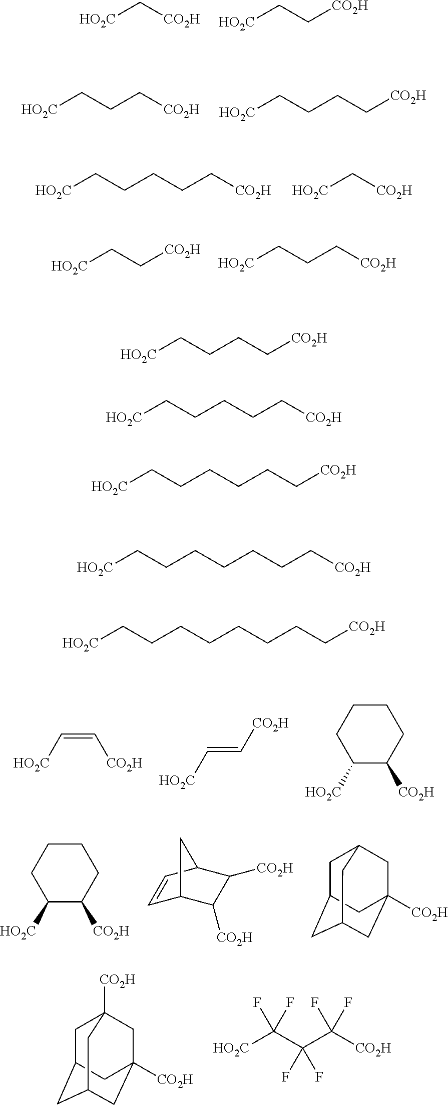

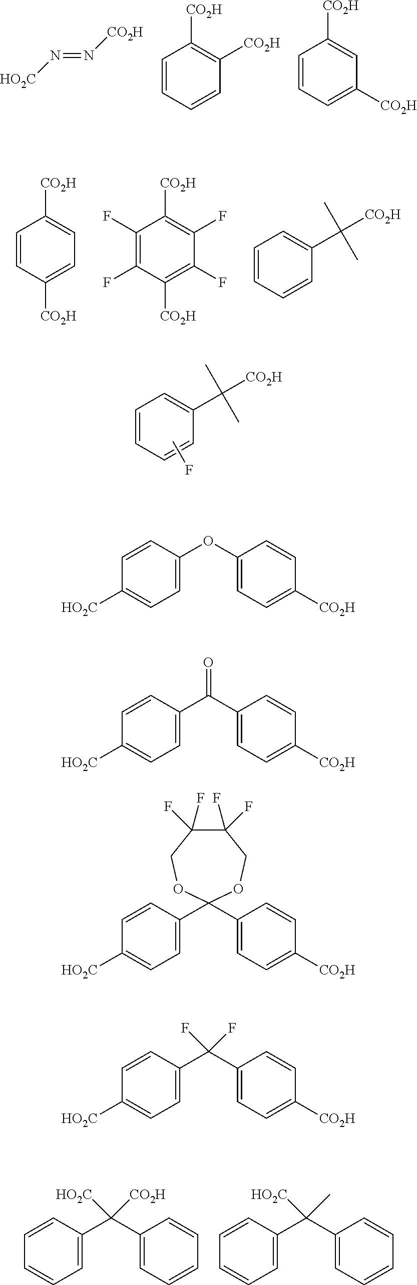

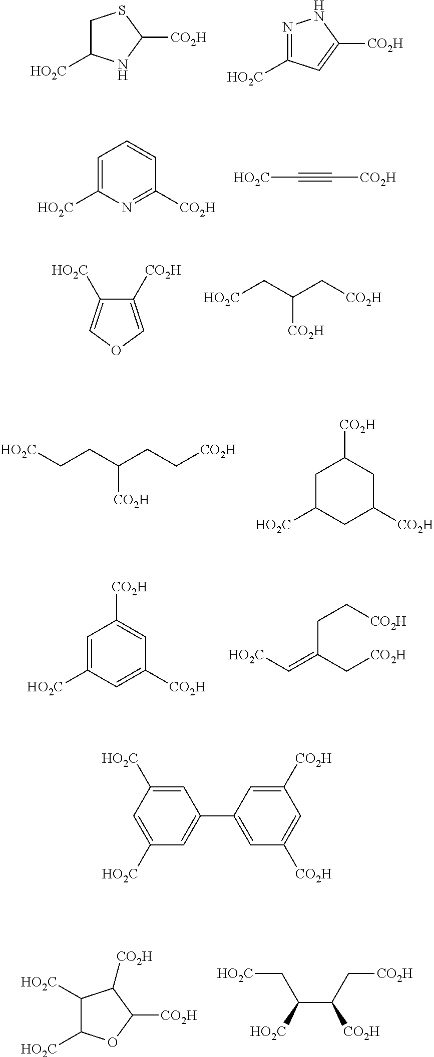

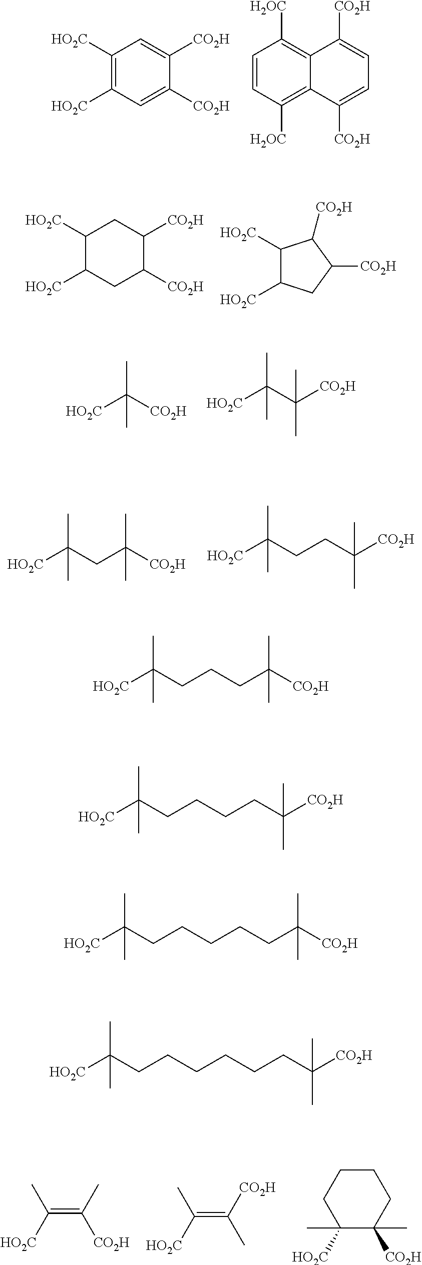

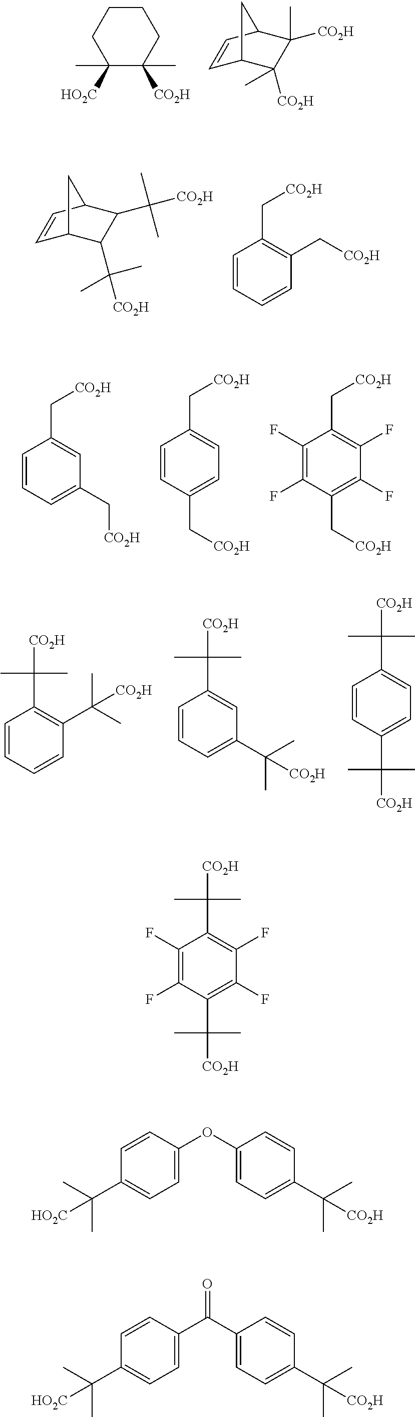

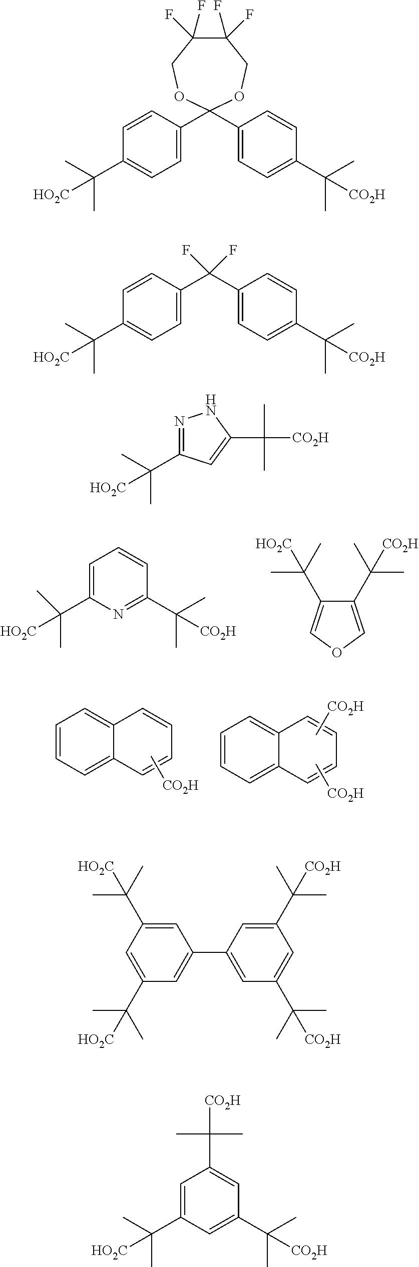

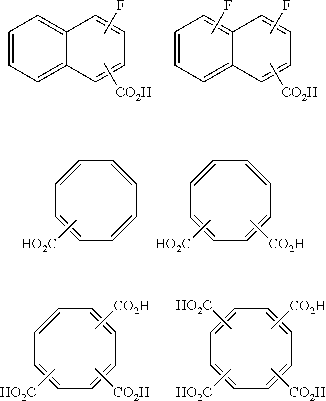

The carboxy-containing polymer comprising repeat units having formula (6) may further comprise repeat units other than the repeat units having formula (6). Although the other repeat units are not particularly limited, preference is given to repeat units capable of increasing the solvent solubility of a polymer which is substantially insoluble when the polymer consists of carboxy-containing repeat units. The preferred other repeat units include repeat units having a robust skeleton, typically repeat units having a cyclic structure from which high etch resistance is expectable and repeat units having a styrene skeleton.

Examples of the other repeat unit are shown below, but not limited thereto. Herein R^{A} is as defined above, and X^{B} is each independently —CH₂— or —O—.

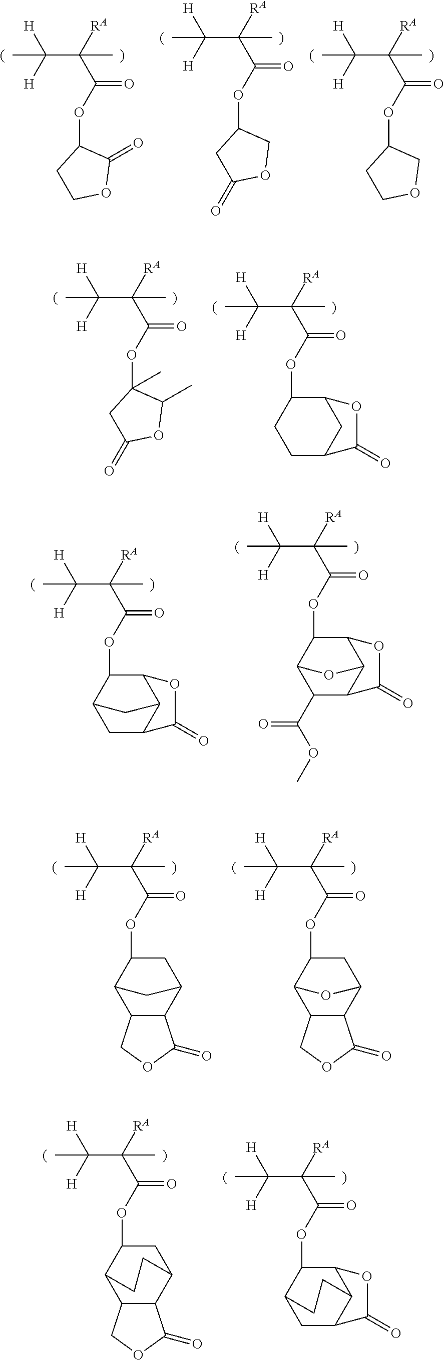

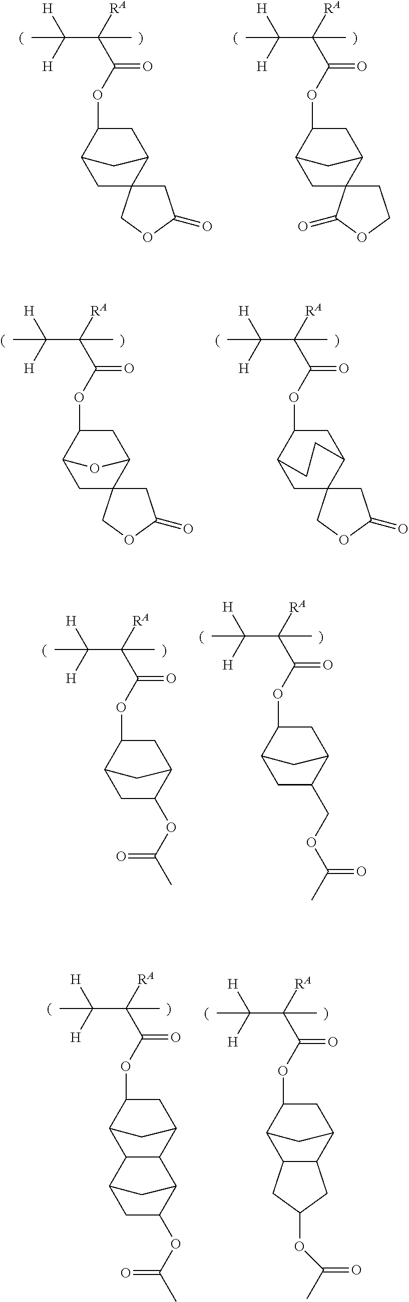

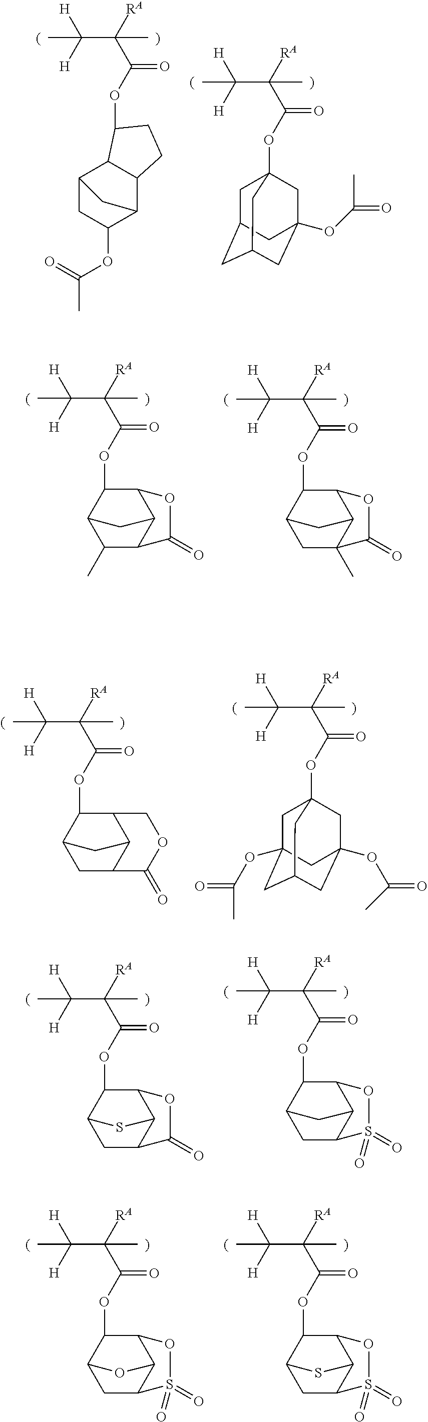

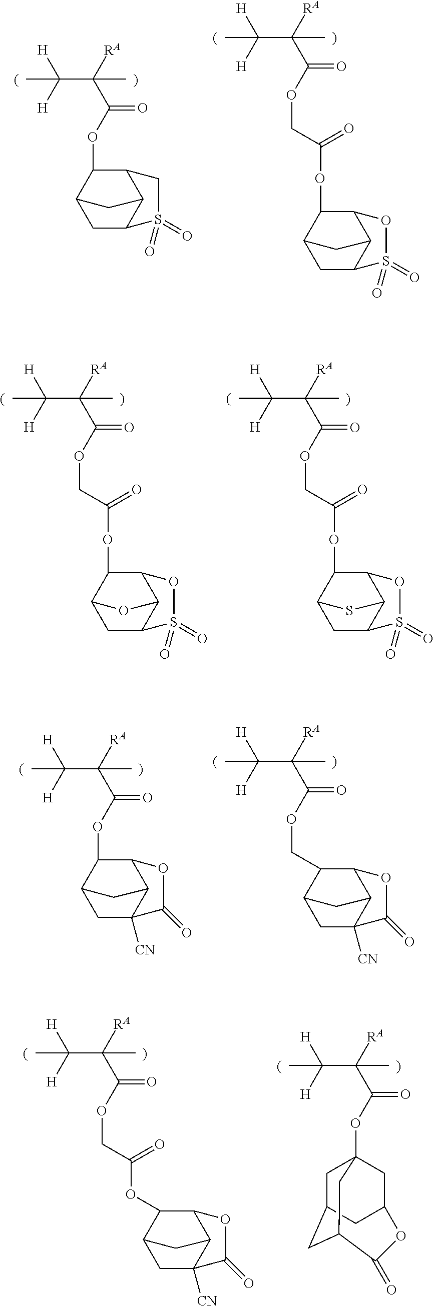

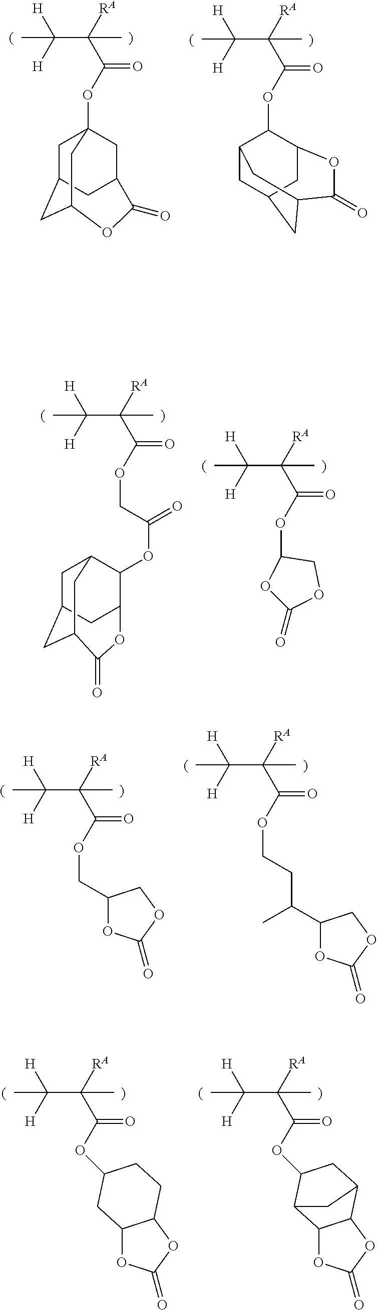

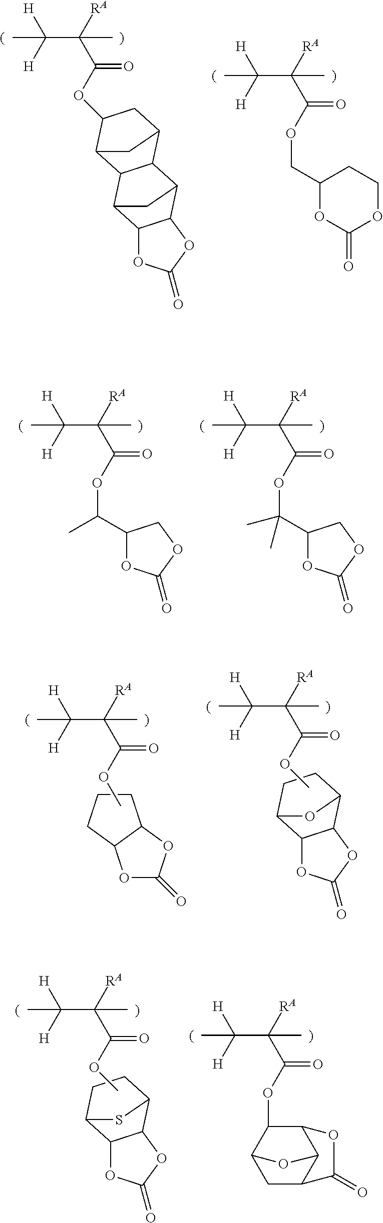

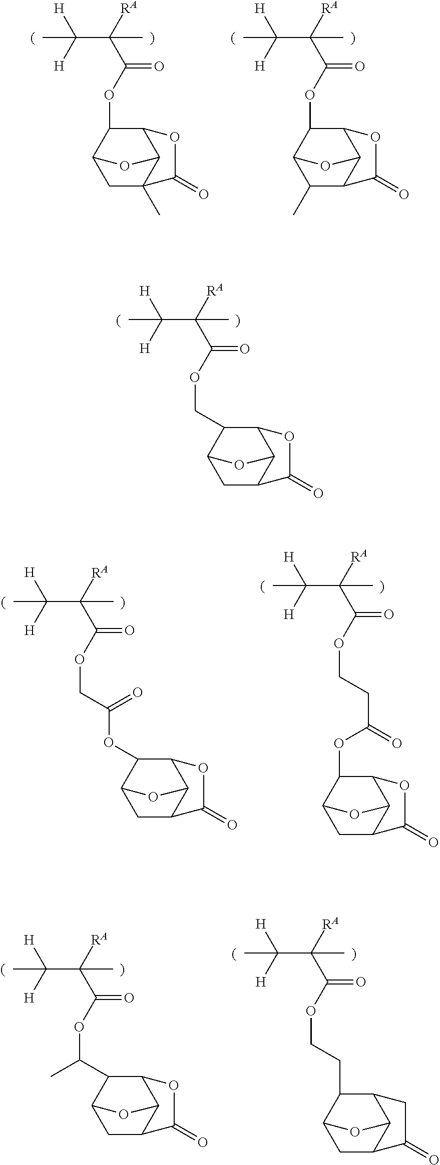

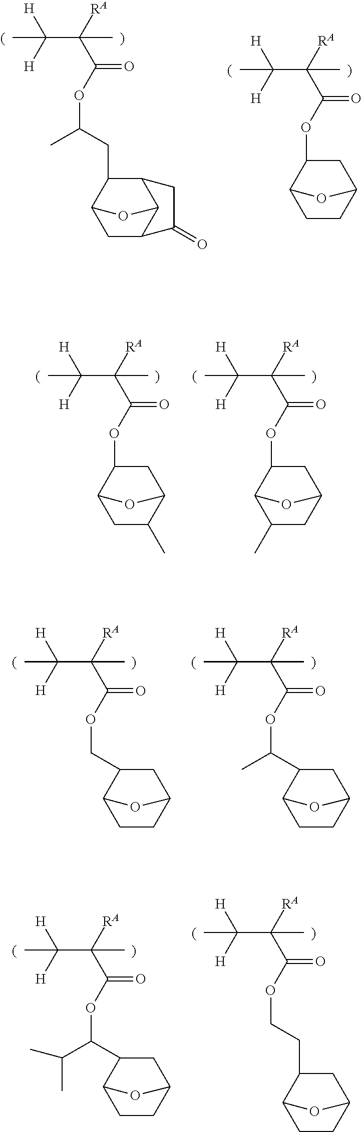

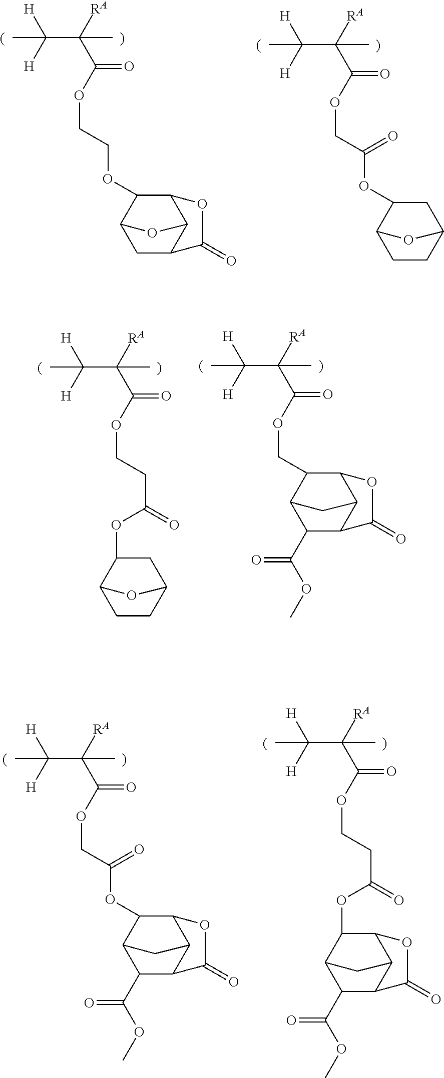

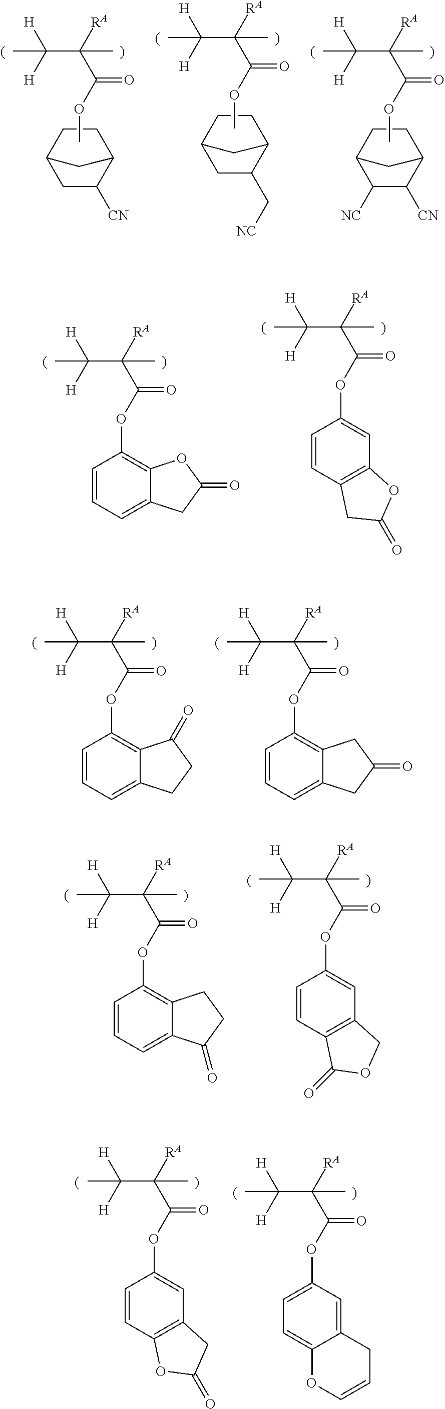

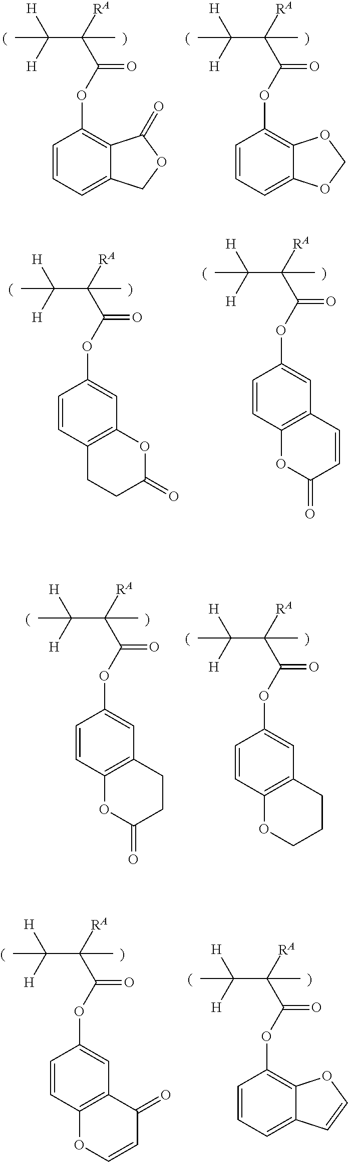

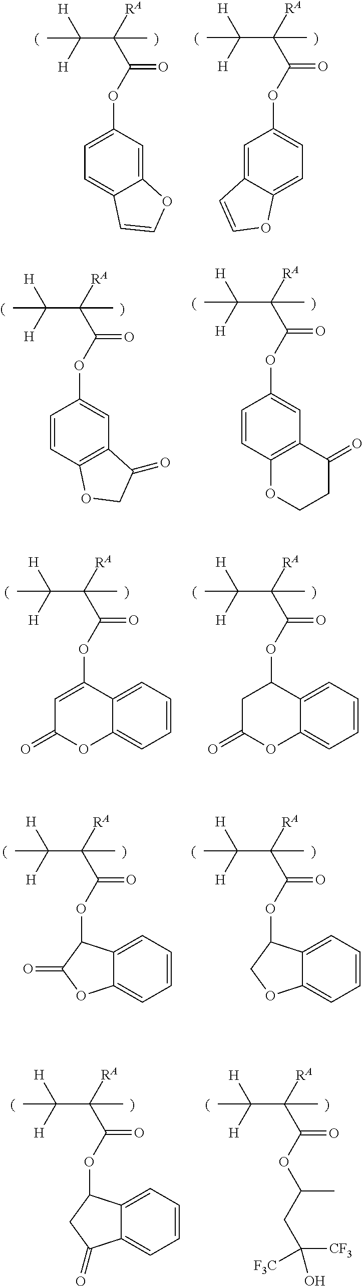

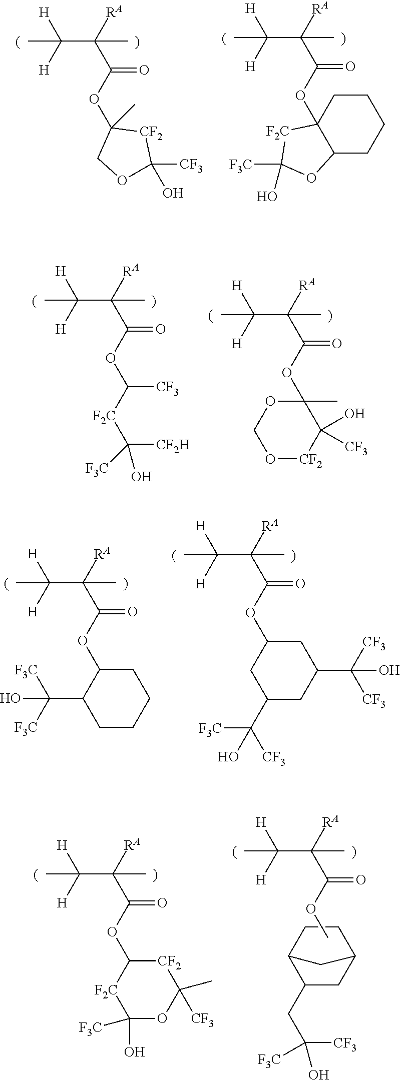

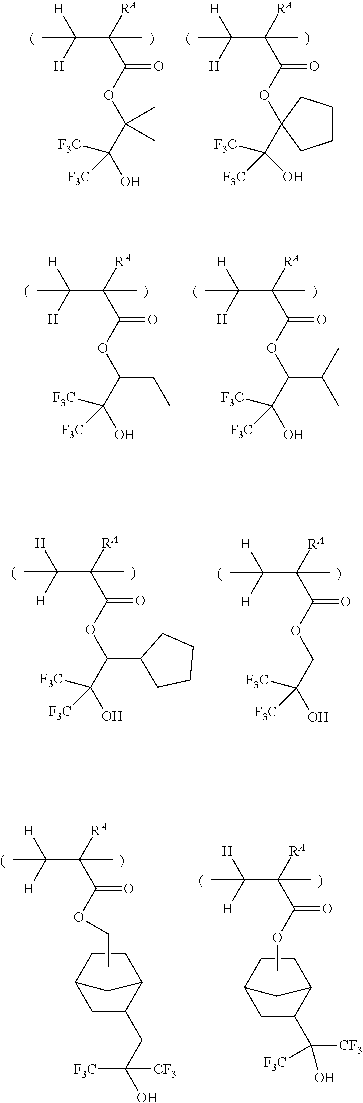

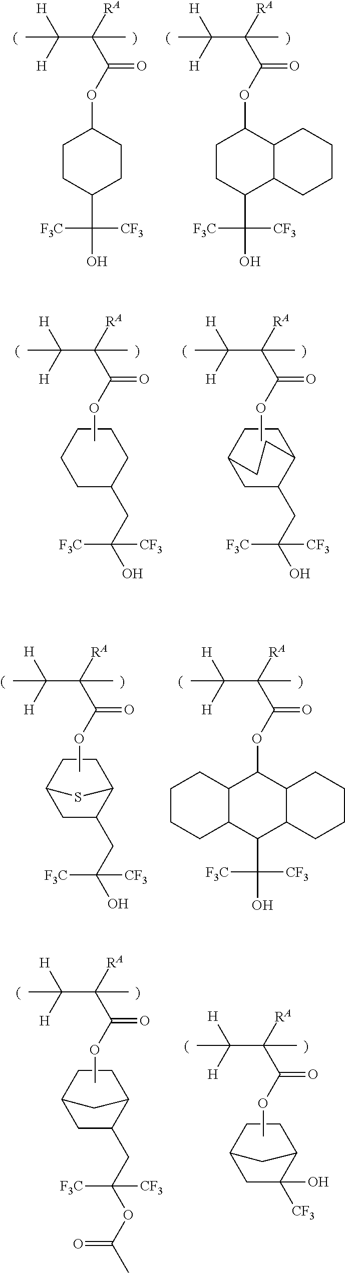

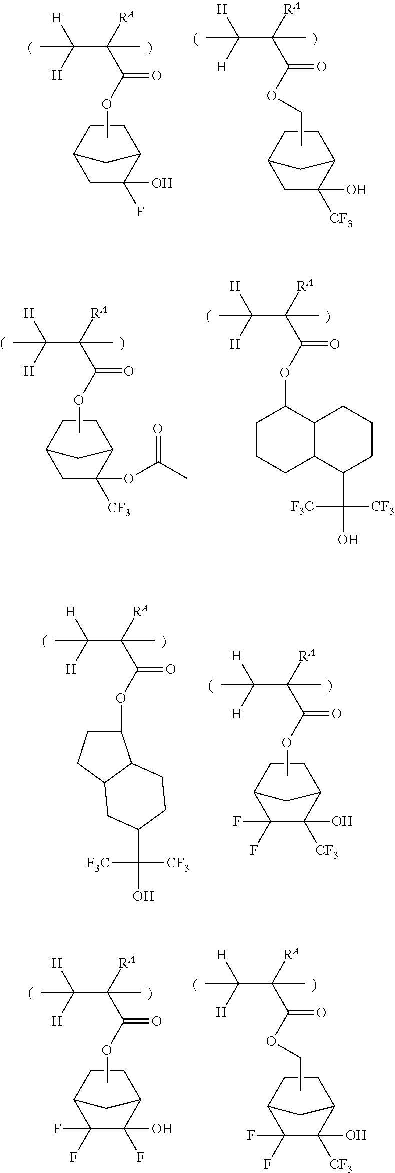

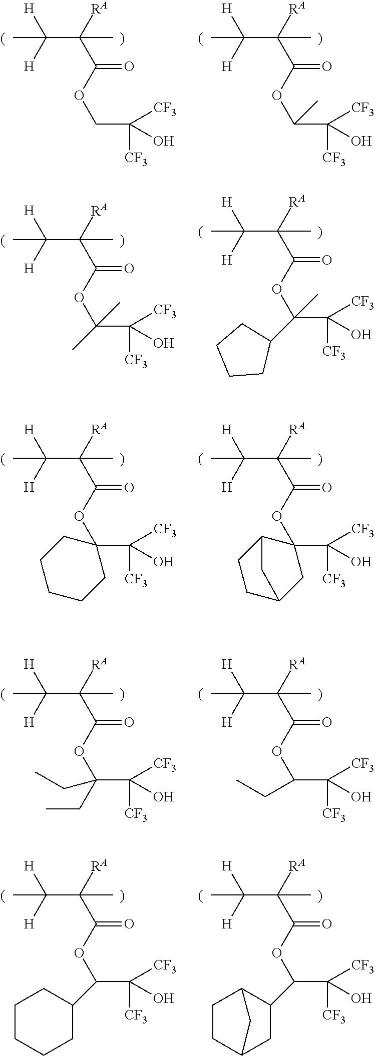

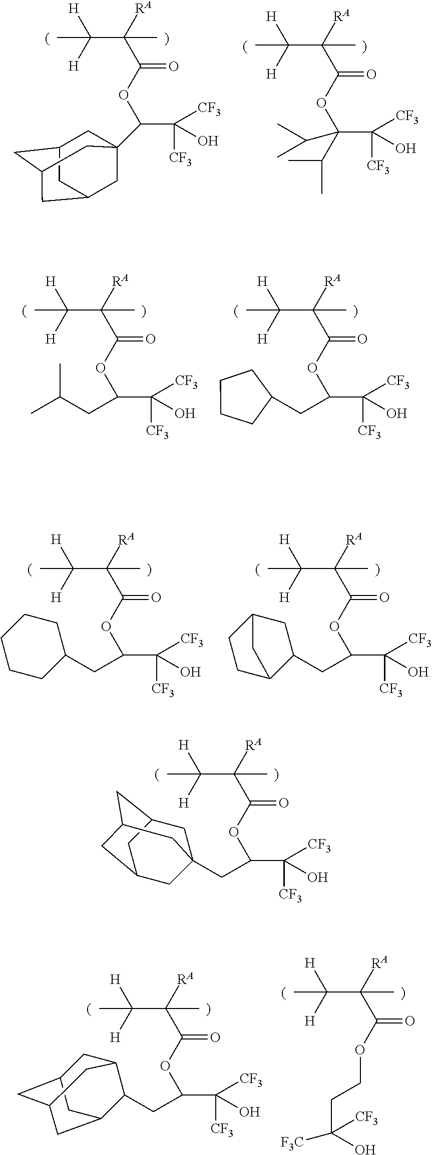

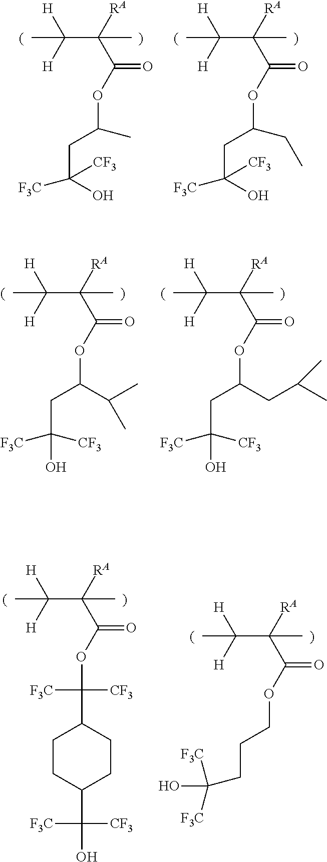

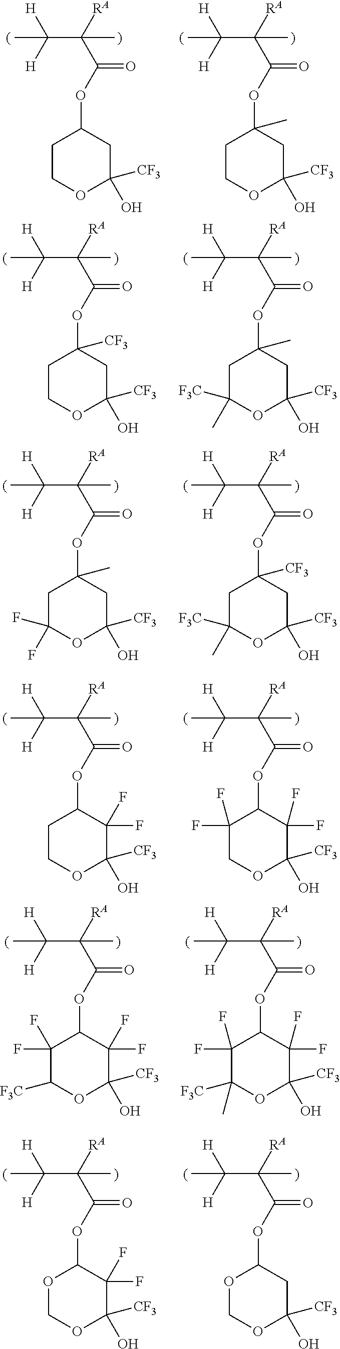

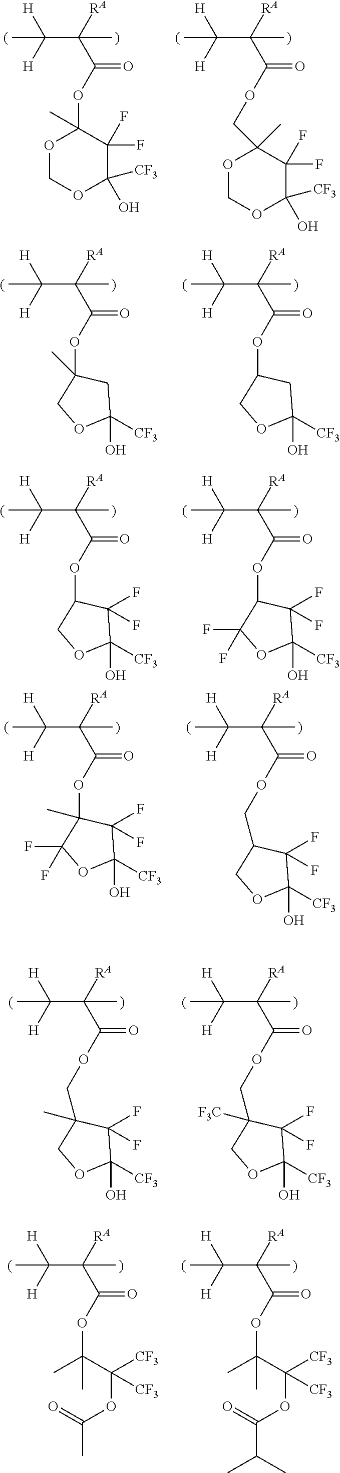

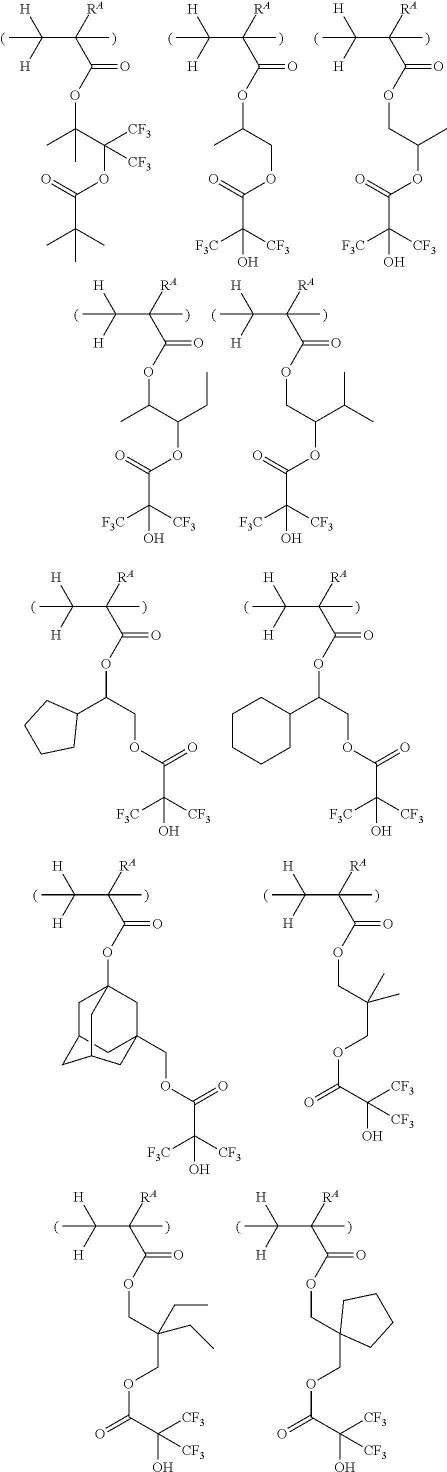

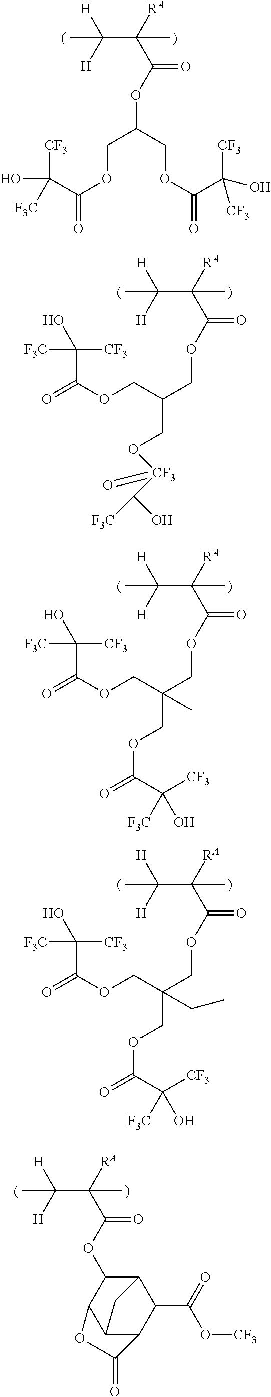

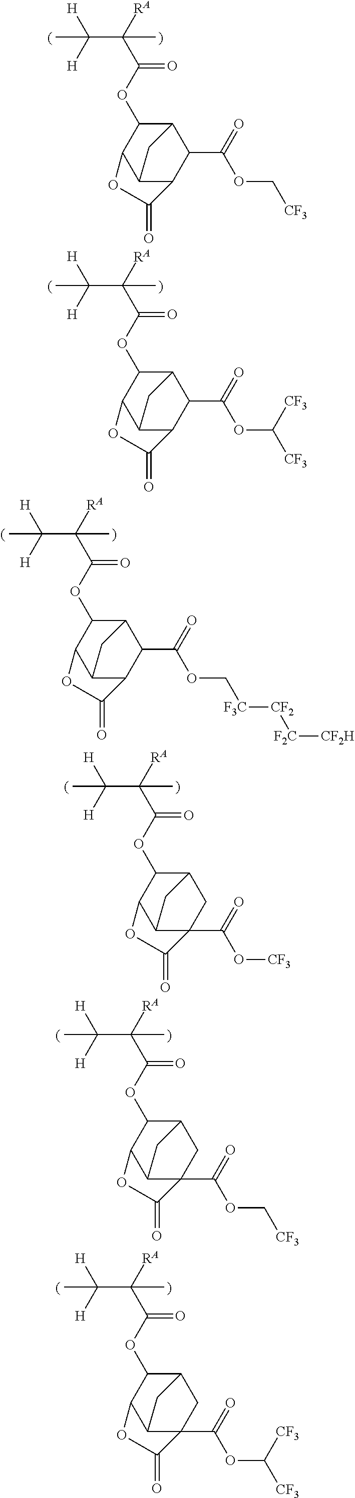

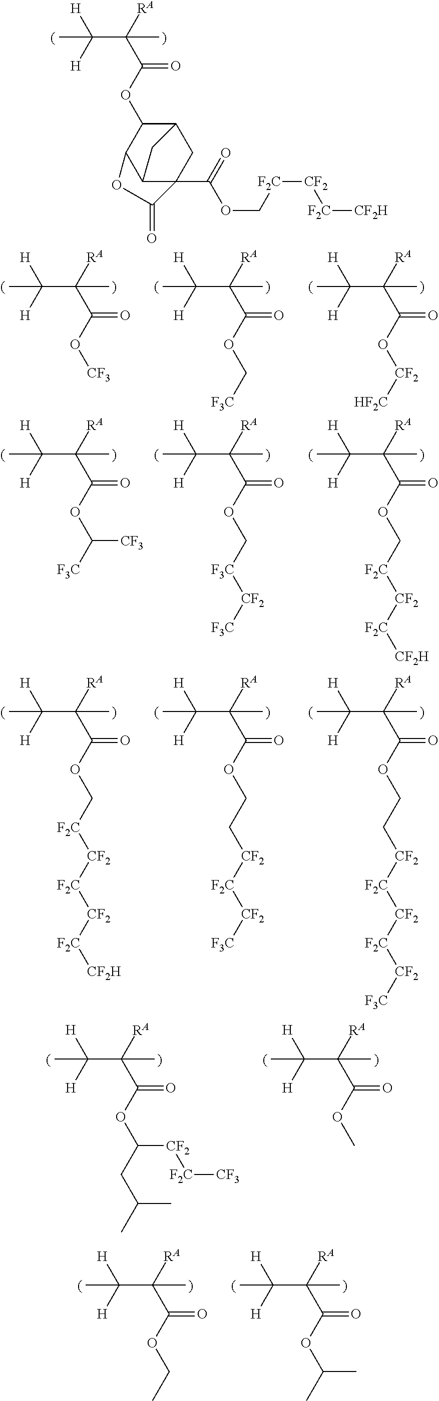

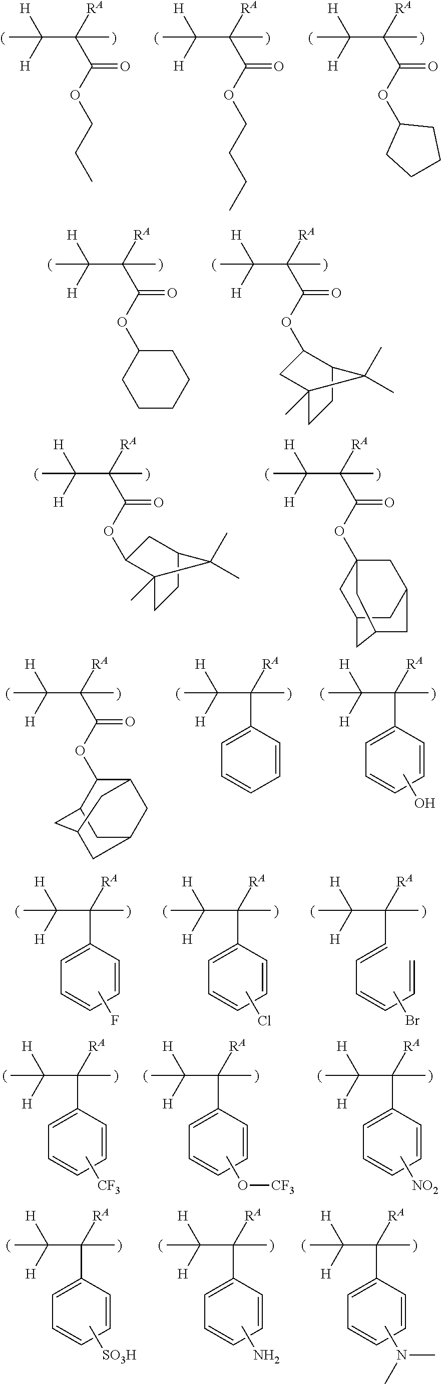

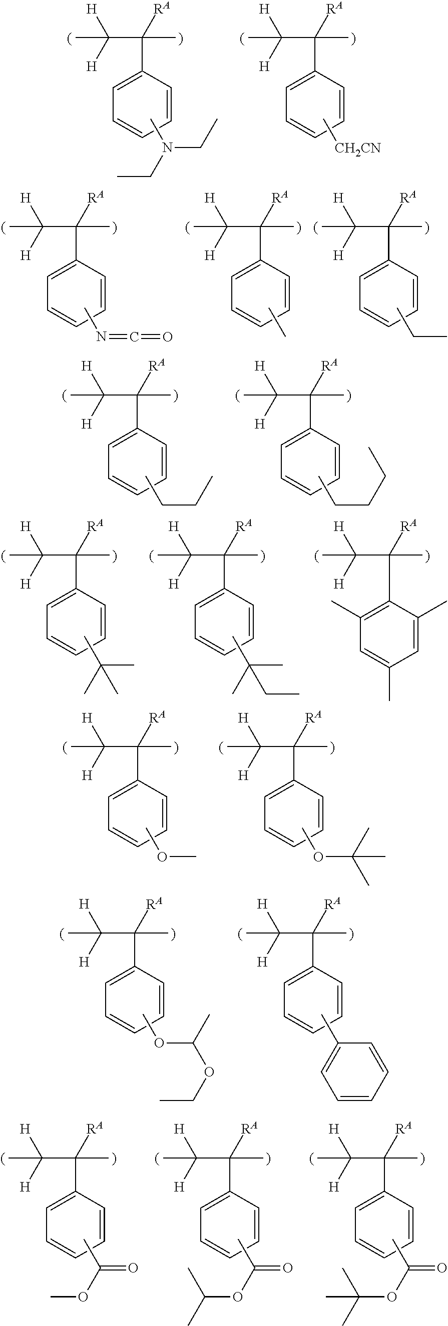

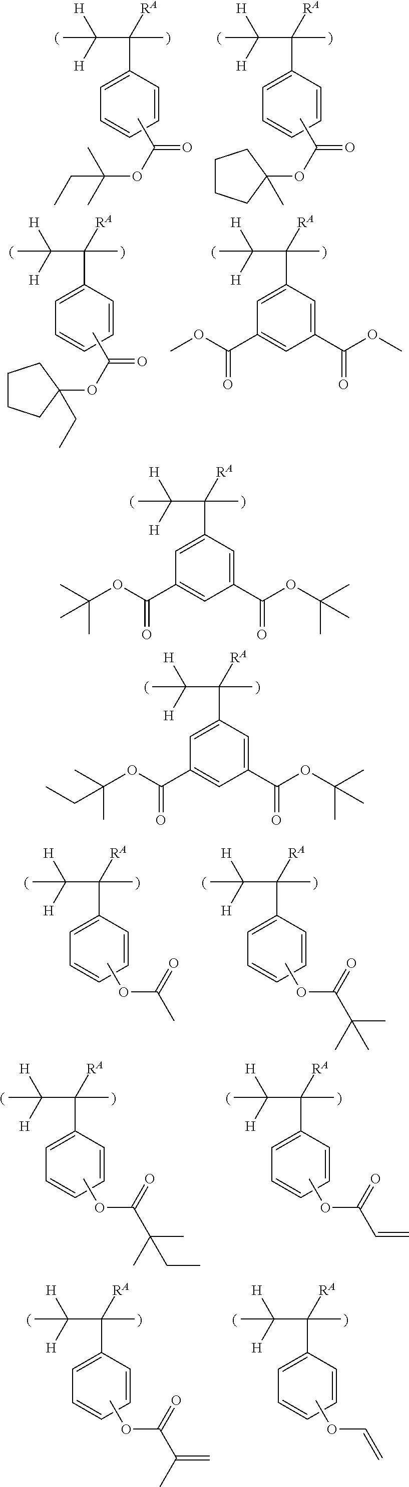

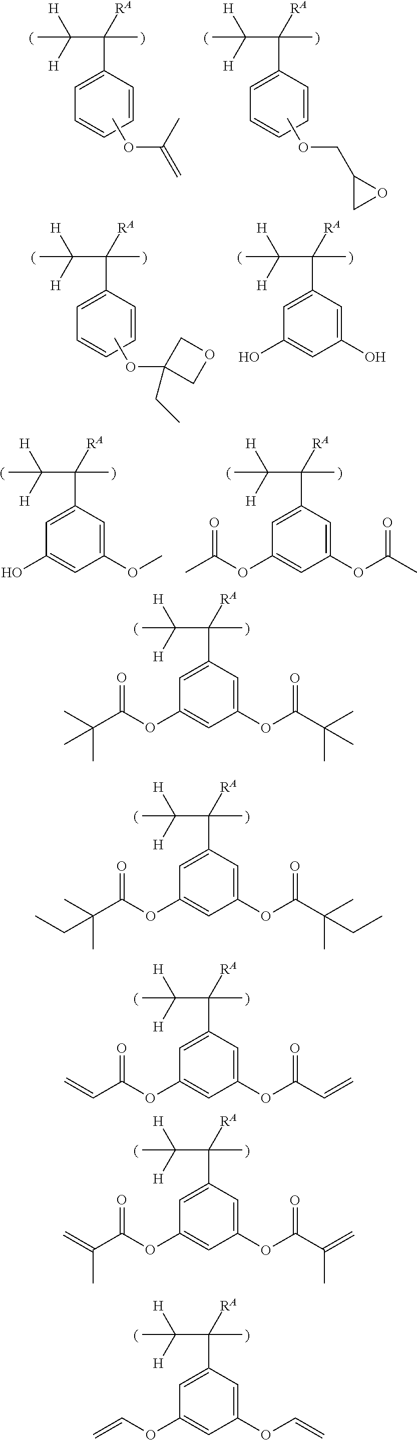

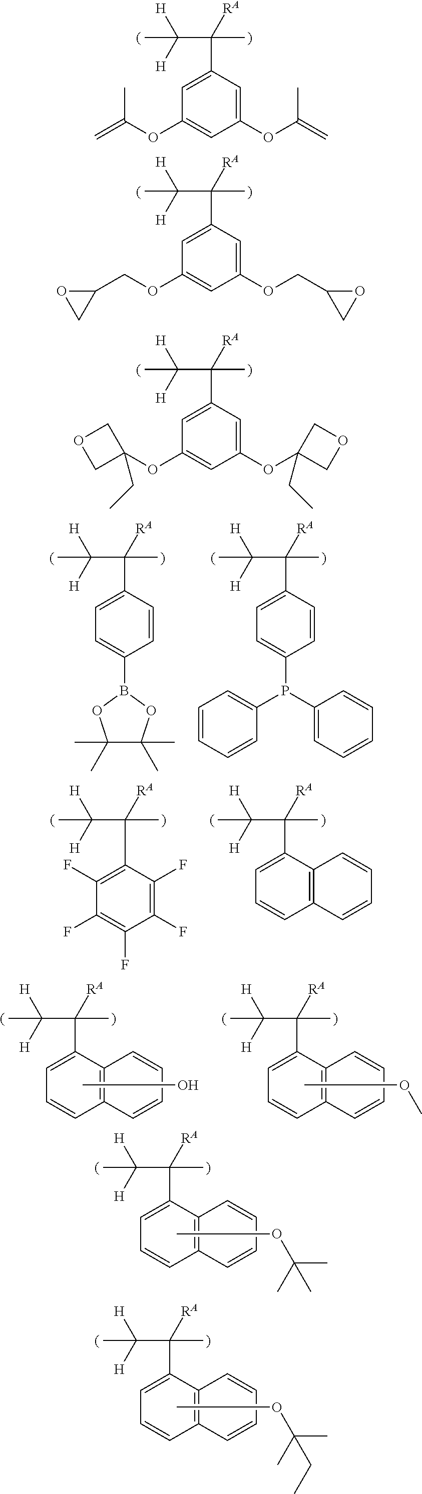

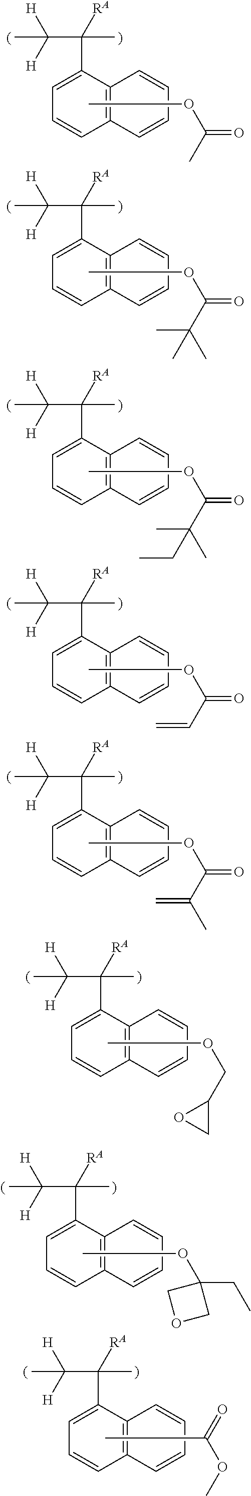

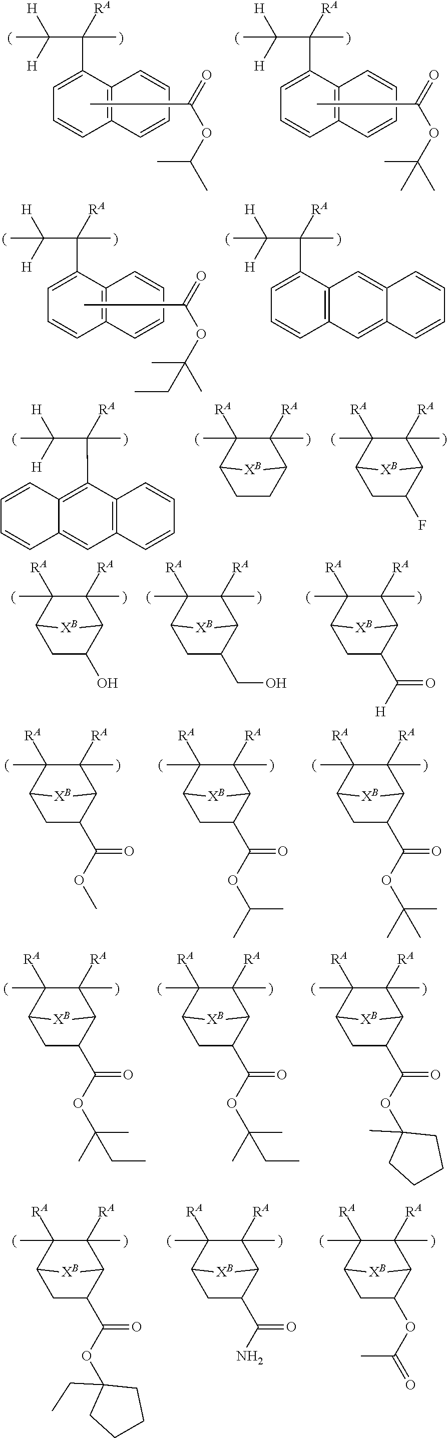

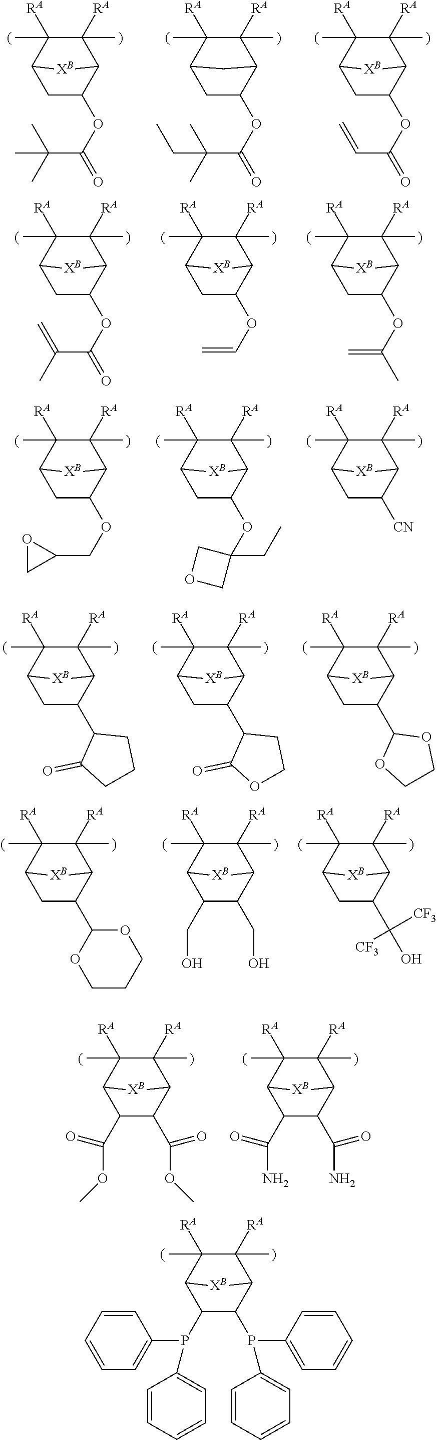

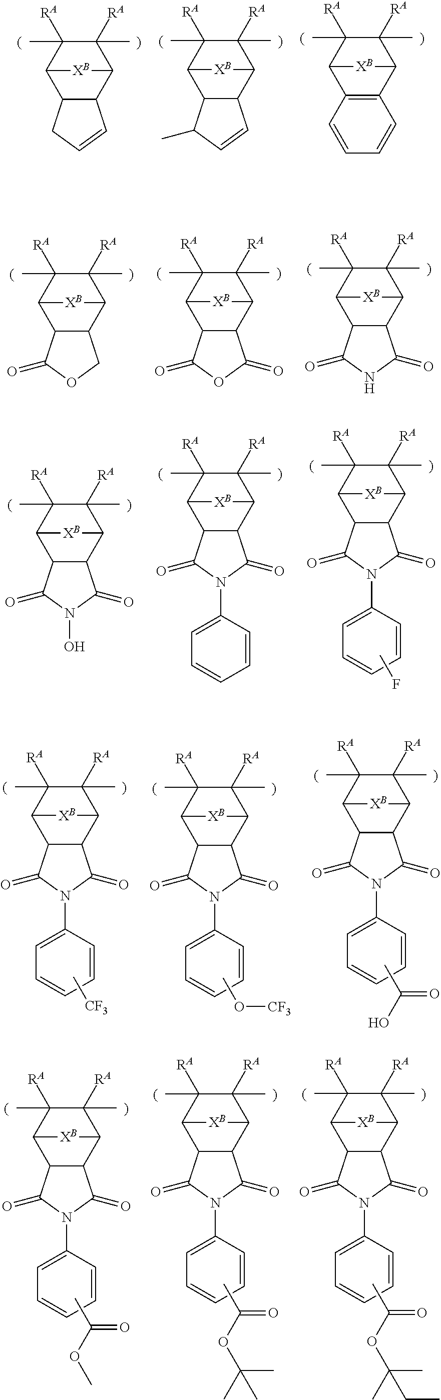

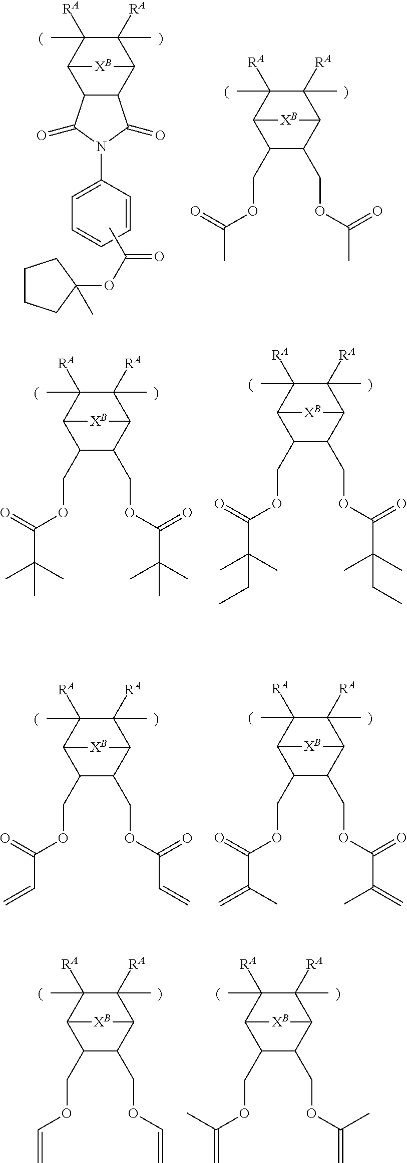

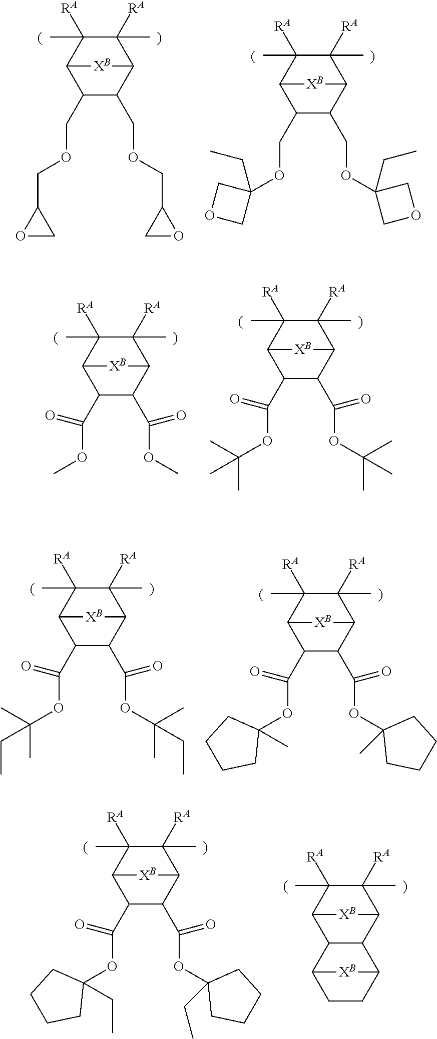

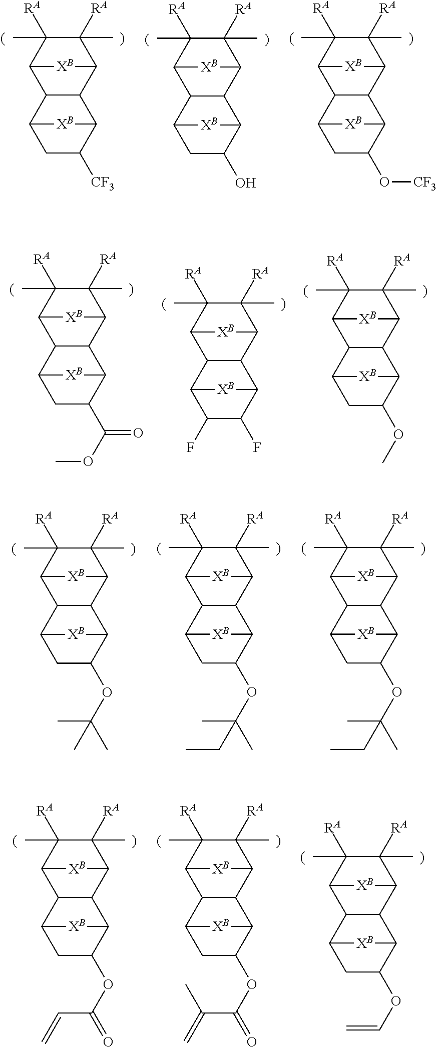

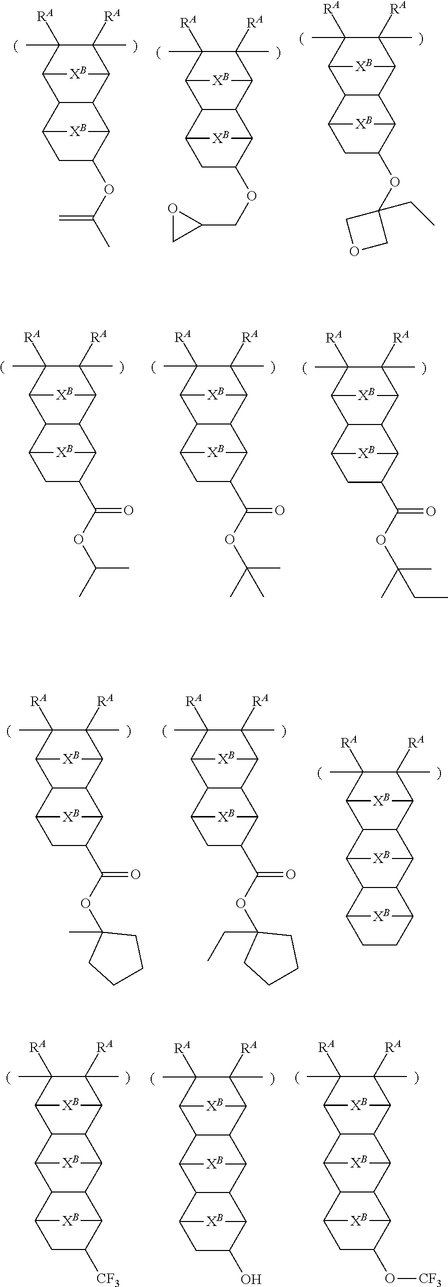

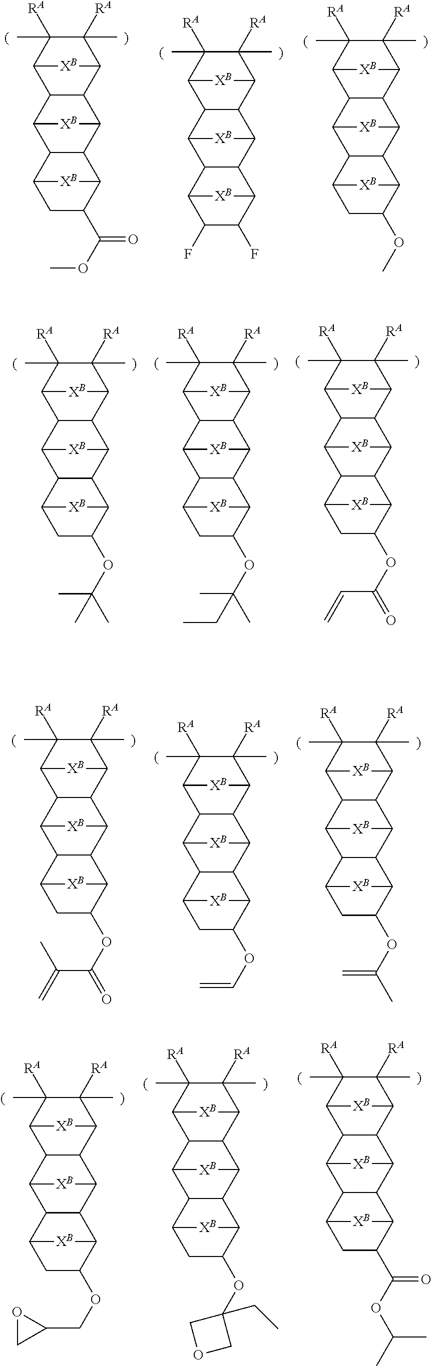

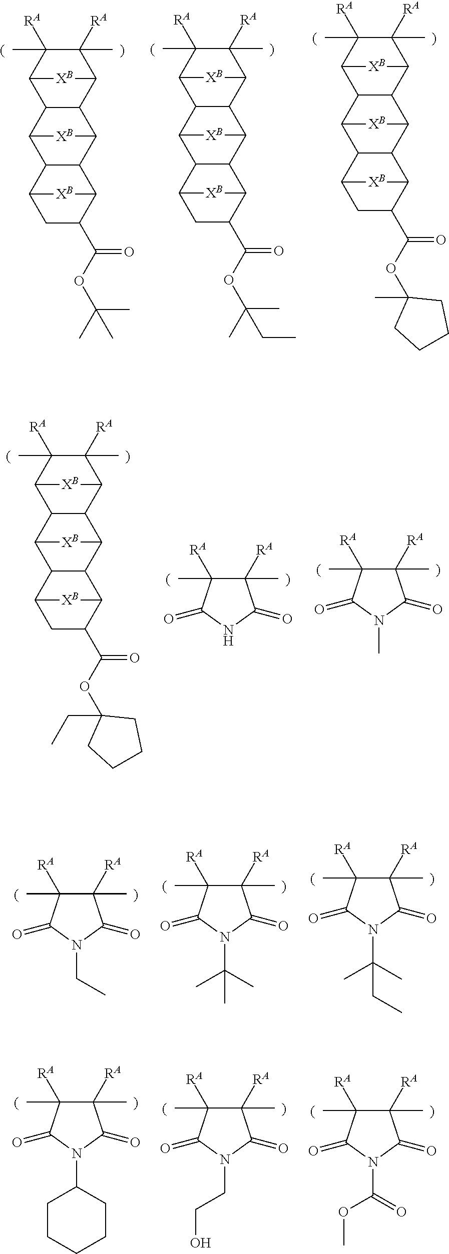

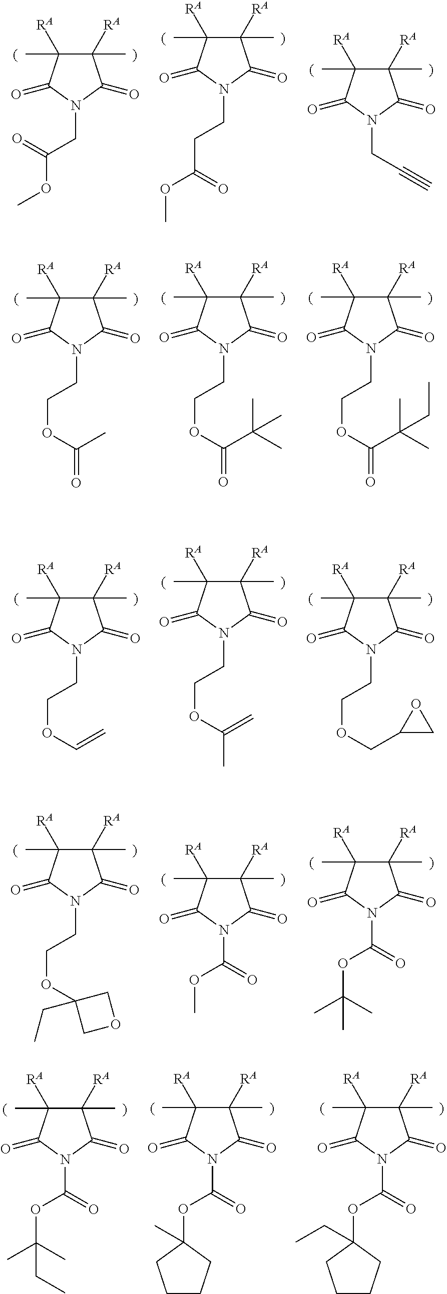

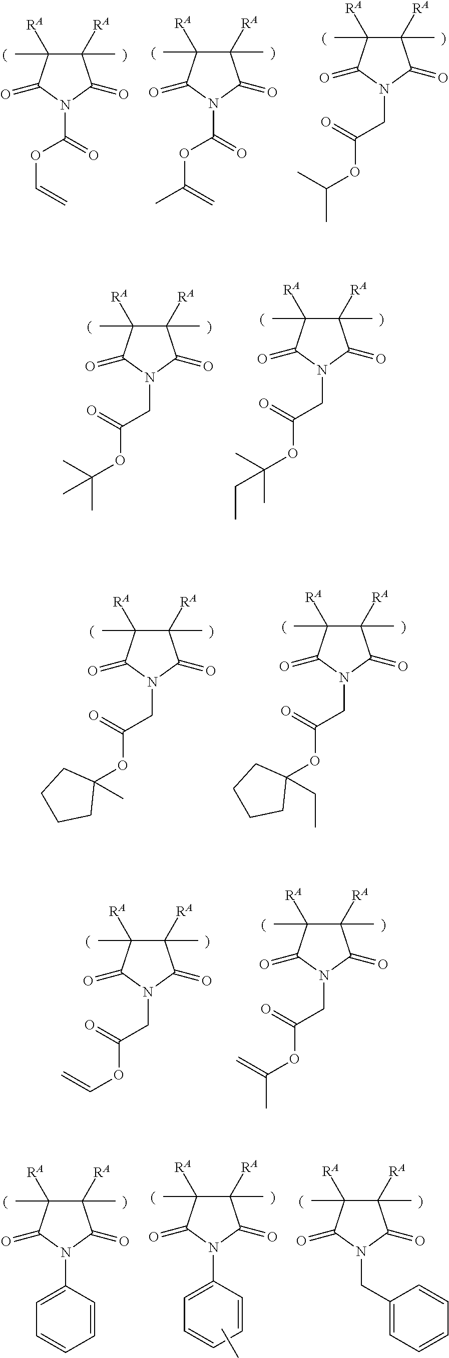

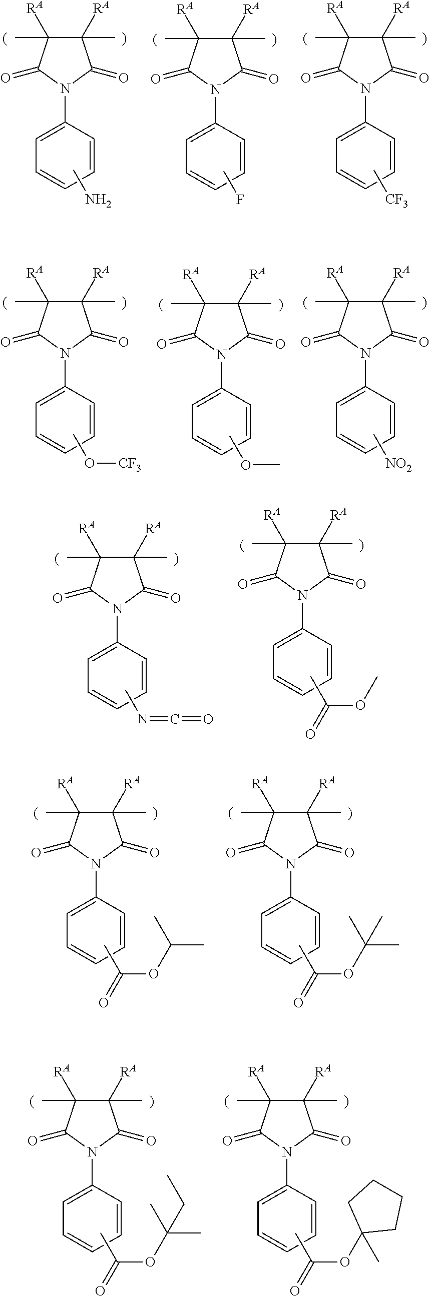

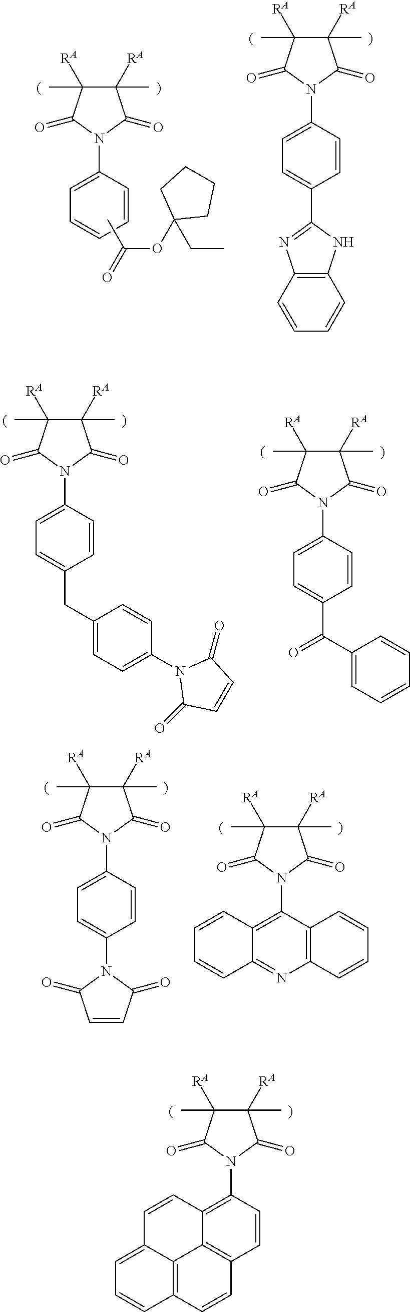

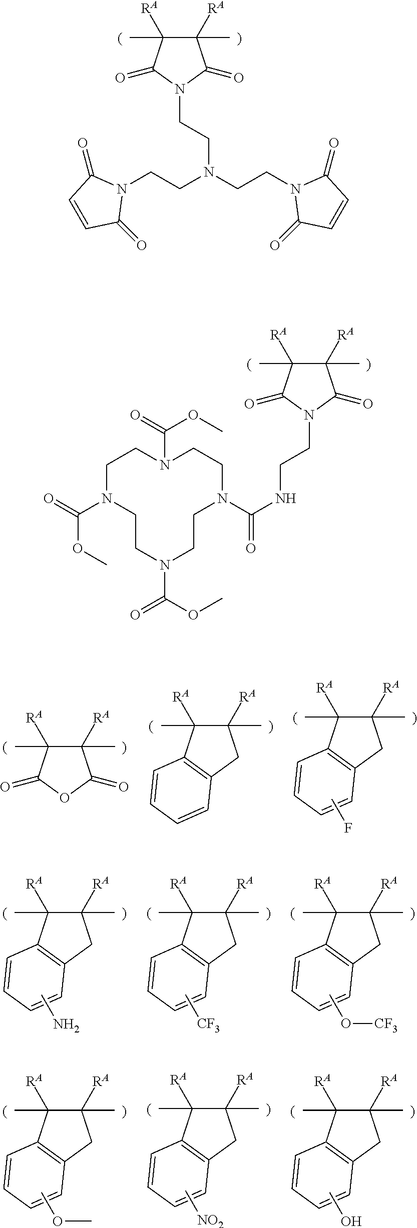

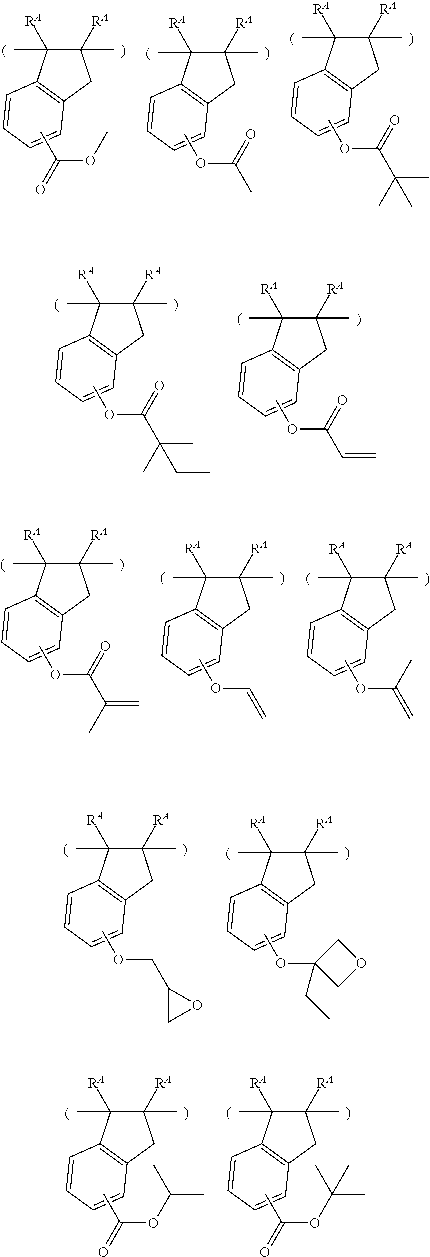

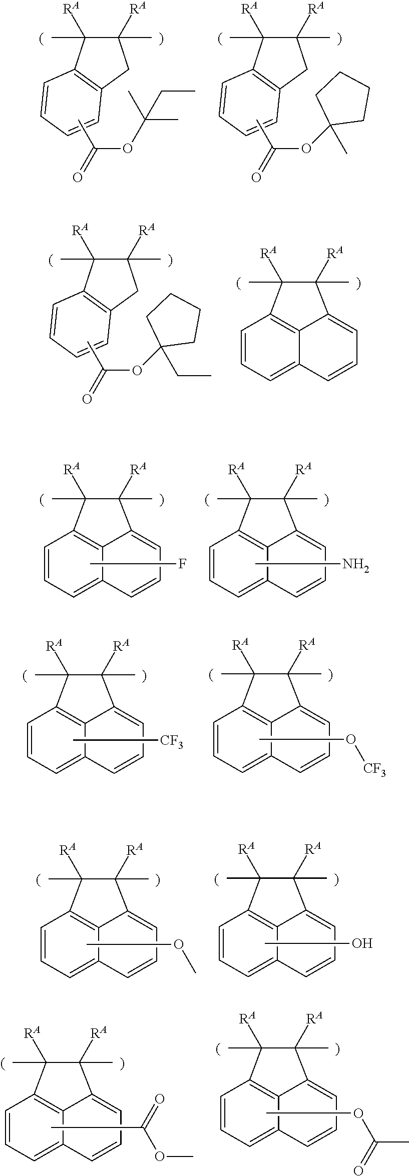

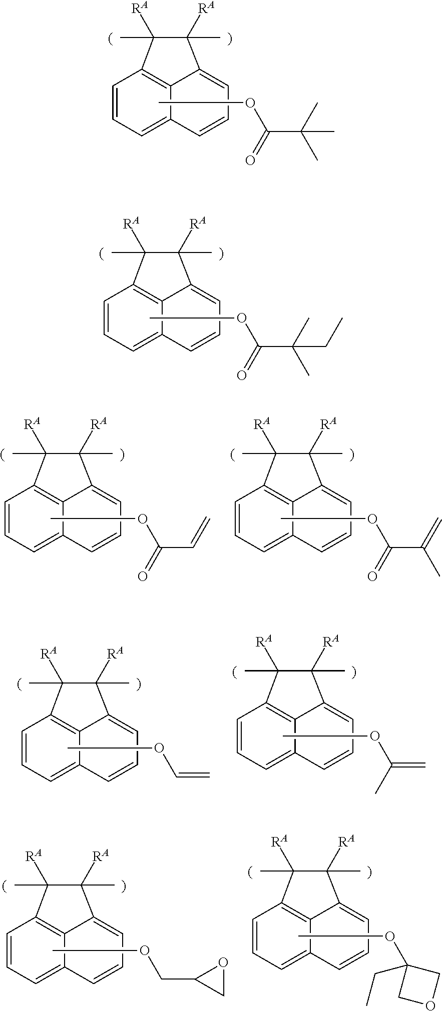

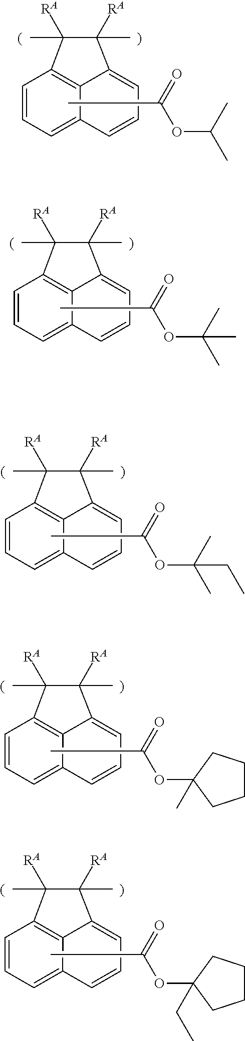

In the resist composition, the hypervalent iodine compound and the carboxy-containing compound (or when the carboxy-containing compound is a carboxylic acid-containing polymer, the carboxy-containing repeat units in the polymer) are preferably present such that the molar ratio of the hypervalent iodine compound to the carboxy-containing compound (or carboxy-containing repeat unit) may range from 10:90 to 90:10, more preferably from 20:80 to 80:20, even more preferably from 30:70 to 70:30. The hypervalent iodine compound may be used alone or in admixture. The carboxy-containing polymer may be used alone or as a mixture of two or more polymers having different compositional ratio, Mw and/or Mw/Mn.

In the carboxy-containing polymer, the molar ratio of carboxy-containing repeat units to other repeat units ranges preferably from 10:90 to 90:10, more preferably from 15:85 to 85:15, even more preferably from 20:80 to 80:20.

The carboxy-containing polymer should preferably have a weight average molecular weight (Mw) in the range of 1,000 to 500,000, and more preferably 3,000 to 100,000, as measured by GPC versus polystyrene standards using tetrahydrofuran (THF) solvent.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the carboxy-containing polymer should preferably have a narrow dispersity (Mw/Mn) of 1.0 to 2.0 in order to provide a resist composition suitable for micropatterning to a small feature size.

The carboxy-containing polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The amount of the initiator added is preferably 0.01 to 25 mol % of the total of monomers to be polymerized. The reaction temperature is preferably 50 to 150° C., more preferably 60 to 100° C. The reaction time is preferably 2 to 24 hours, more preferably 2 to 12 hours in view of production efficiency.

The polymerization initiator may be added to the monomer solution, which is fed to the reactor. Alternatively, a solution of the polymerization initiator is prepared separately from the monomer solution, and the monomer and initiator solutions are independently fed to the reactor. Since there is a possibility that the initiator generates a radical in the standby time, by which polymerization reaction takes place to form a ultrahigh molecular weight compound, it is preferred from the standpoint of quality control that the monomer solution and the initiator solution be independently prepared and added dropwise. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

The amount of each monomer in the monomer solution is set such that the content of the corresponding repeat unit may fall in the preferred range.

The resist composition further contains a solvent. The solvent is not particularly limited as long as the hypervalent iodine compound, the carboxy-containing compound and other components are dissolvable therein and a film can be formed from the resulting solution. Organic solvents are preferred. Suitable organic solvents include ketones such as cyclohexanone, methyl 2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, and 4-methyl-2-pentanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, methyl 2-hydroxyisobutyrate, and propylene glycol mono-tert-butyl ether acetate; carboxylic acids such as formic acid, acetic acid, and propionic acid; lactones such as γ-butyrolactone, and mixtures thereof.

The solvent is preferably present in such amounts that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent.

The resist composition may further contain a surfactant. The surfactant is preferably selected from fluorochemical and silicone surfactants. Exemplary surfactants are described, for example, in US 2008/0248425, paragraph [0276]. Also useful are surfactants other than the fluorochemical and silicone surfactants, as described, for example, in US 2008/0248425, paragraph [0280].

When used, the surfactant is preferably present in an amount of 0.0001 to 2% by weight based on the overall solids. The surfactant may be used alone or in admixture.

The resist composition may further contain a radical scavenger (or radical trapping agent). The radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpyperidine and 2,2,6,6-tetramethylpyperidine-N-oxy radical. Exemplary thiol compounds include dodecanethiol and hexadecanethiol.

When used, the radical scavenger is preferably present in an amount of 0.01 to 10% by weight based on the overall solids. The radical scavenger may be used alone or in admixture.

The resist composition may further contain a crosslinker. Since the crosslinker functions to promote crosslinking reaction during photolithography, a pattern having a higher glass transition temperature and a better resolution in fine line formation is obtained.

Suitable crosslinkers include compounds having a carbon-carbon unsaturated bond such as vinyl, (meth)acryloyl, allyl, alkynyl and aromatic ring as a functional group. Specifically, suitable vinyl-containing compounds include optionally substituted straight-chain alkenes, branched alkenes, and cyclic alkenes. Suitable (meth)acryloyl-containing compounds include optionally substituted acrylic acid, methacrylic acid, acrylates, and methacrylates. Suitable allyl-containing compounds include optionally substituted allyl alcohols, allyl ethers, allyl esters, allyl amides, allyl amines, allyl-containing isocyanurates. Suitable alkynyl-containing compounds include optionally substituted straight-chain alkynes, branched alkynes, cyclic alkynes, alkynyl alcohols, alkynyl ethers, alkynyl esters, alkynyl amides, alkynyl amines, and alkynyl-containing isocyanurates. Suitable aromatic ring-containing compounds include optionally substituted arenes, heteroarenes, styrene, stilbene, phenylacetylene, acenaphthylene, and chalcone. The crosslinker may contain only one of the foregoing functional groups or two or more functional groups. The number of functional groups in the crosslinker is preferably from 1 to 10, more preferably from 2 to 8.

When the resist composition contains the crosslinker, the amount of the crosslinker is preferably 0.01 to 50% by weight of the overall solids. The crosslinker may be used alone or in admixture.

When the resist composition contains the crosslinker, it may further contain a photopolymerization initiator. Upon receipt of high-energy radiation, the photopolymerization initiator generates radicals to promote crosslinking reaction of the crosslinker.

Examples of the photopolymerization initiator include benzophenone derivatives such as benzophenone, methyl O-benzoylbenzoate, 4-benzyol-4′-methyl diphenyl ketone, dibenzyl ketone, and fluorenone; acetophenone derivatives such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)benzyl]phenyl}-2-methylpropan-1-one, and methyl phenylglyoxylate; thioxanthone derivatives such as thioxanthone, 2-methylthioxanthone, 2-isopropylthioxanthone, 4-isopropylthioxanthone, 2-chlorothioxanthone, and diethylthioxanthone; benzyl derivatives such as benzyl, benzyl dimethyl ketal, and benzyl-β-methoxyethylacetal; benzoin derivatives such as benzoin, benzoin methyl ether, and 2-hydroxy-2-methyl-1-phenylpropan-1-one; oxime compounds such as 1-phenyl-1,2-butanedione-2-(O-methoxycarbonyl)oxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime, 1-phenyl-3-ethoxypropanetrione-2-(O-benzoyl)oxime 1,2-octanedione, 1-{4-(phenylthio)-2-(O-benzoyl)oxime ethanone, and 1-[9-ethyl-6-(2-methylbenzoyl)-9H-carbazol-3-yl]-1-(O-acetyloxime); α-hydroxyketone compounds such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropionyl)benzyl]phenyl}-2-methylpropane; α-aminoalkylphenone compounds such as 2-benzyl-2-dimethylamino-1-(4-morpholinophenyl)butanone-1 and 2-dimethylamino-2-(4-methylbenzyl)-1-(4-morpholin-4-ylphenyl)butan-1-one; phosphine oxide compounds such as bis(2,4,6-trimethylbenzoyl)phenylphosphine oxide, bis(2,6-dimethoxybenzoyl)-2,4,4-trimethylpentylphosphine oxide, and 2,4,6-trimethylbenzoyl diphenylphosphine oxide; and titanocene compounds such as bis(η5-2,4-cyclopentadien-1-yl)-bis(2,6-difluoro-3-(1H-pyrrol-1-yl)phenyl)titanium.

When the resist composition contains the photopolymerization initiator, the amount of the initiator is preferably 0.1 to 10% by weight, more preferably 0.1 to 5% by weight, even more preferably 0.1 to 1% by weight of the overall solids. A sufficient effect is available as long as the amount is 0.1% by weight or more.

The resist composition contains the hypervalent iodine compound and the carboxy-containing compound as main components, but not a polymer containing an acid labile group and a photoacid generator as used in conventional chemically amplified resist compositions. Nevertheless, this resist composition works such that the region thereof exposed to EB or EUV may become soluble in the developer to form a positive tone pattern. Although its mechanism is not well understood, the following mechanism is presumed.

The hypervalent iodine compound having formula (3), (4) or (5) is a three-coordinate compound having aryl and carboxylate ligands. When such a three-coordinate iodine compound is mixed with a carboxy-containing compound, replacement of carboxylate ligands takes place as equilibration reaction. If the original carboxylate ligands are removed by any suitable means, a hypervalent iodine compound having new ligands is created. For example, if 1-iodonaphthylene diacetate as a hypervalent iodine compound is mixed with a carboxy-containing compound, and the resulting low-boiling acetic acid is removed, then ligand exchange is completed. There is obtained a polymer in which the carboxy-containing compound is crosslinked with the hypervalent iodine compound.

The polymer crosslinked with the hypervalent iodine compound is formed during film preparation. The reason is that even when such a crosslinked polymer is previously synthesized, the polymer is not soluble in most organic solvents so that a solution may not be prepared. If the hypervalent iodine compound having a low solvent solubility because of inherently strong polarization has taken therein a carboxy-containing compound as a ligand, then the compound suffers from a further loss of solubility. It is thus desirable that a resist film be formed while ligand exchange reaction be completed by removing the original low-molecular-weight carboxylic acid component during film formation and subsequent bake steps.

After a resist film is formed from the resist composition, the hypervalent iodine compound as the main component is photo-decomposed in the exposure step to bring about a polarity switch, and a pattern is formed in the subsequent development step. Although its mechanism is not well understood, the following mechanism is presumed.

The resist film obtained from the resist composition contains the polymer to which the hypervalent iodine compound is bonded during film formation. Upon receipt of light, the hypervalent iodine compound is decomposed into a monovalent iodine compound. At the same time, the crosslink between the hypervalent iodine compound and the carboxy-containing compound is canceled and the molecular weight is reduced. As a result, the resist film in the exposed region is dissolved away in the organic solvent, yielding a pattern of positive tone.

From the foregoing presumption, the inventive resist composition is regarded as falling in the concept of non-chemically-amplified resist composition. There is no need for an acid labile group-containing polymer and a photoacid generator as used in conventional chemically amplified resist compositions. The inventive resist composition ensures that a small-size pattern is formed at a high resolution without any adverse effect (e.g., image blur) by acid diffusion.

The inventive resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small-size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, the inventive resist composition which does not resort to metal elements is advantageous in defectiveness over the metal resist and eliminates the problem of solvent solubility. The inventive resist composition has a wide range of application because it is applicable to positive tone. In the step of forming contact holes, for example, although a metal resist composition subject to negative tone development requires the reversal processing step after pillar pattern formation, the positive resist composition does not require the reversal step. From the aspect of process simplicity, the inventive resist composition is regarded more useful than the metal resist composition.

The resist film has a thickness of preferably 10 to 70 nm, more preferably 20 to 50 nm.

### Method for Preparing Laminate

The invention also provides a method for preparing a laminate for use in the two-layer resist process, comprising the steps of applying the adherent film-forming composition onto a substrate and heat treating the composition to form an adherent film thereon, and applying the resist composition onto the adherent film and heat treating the resist composition to form a resist film thereon.

The step of forming the adherent film is by applying the adherent film-forming composition onto a substrate by spin coating or the like, and baking the composition for evaporating off the solvent and promoting crosslinking reaction. The baking temperature is preferably 100 to 400° C., more preferably 150 to 300° C. and the baking time is preferably 10 to 600 seconds, more preferably 10 to 300 seconds.

The alternative step of forming the adherent film is by applying the adherent film-forming composition onto a substrate by spin coating or the like as above, and baking the composition in an atmosphere having an oxygen concentration of 0.1 to 21% for curing. A fully cured film is obtainable by baking the adherent film-forming composition in such an oxygen atmosphere. The baking temperature and time are as above.

The baking atmosphere may be air or air and an inert gas such as N₂, Ar or He. In the latter case, an atmosphere having an oxygen concentration of less than 0.1% is established. The baking temperature and time are as above. Even when the substrate contains a material which is less resistant to heating in an oxygen atmosphere, crosslinking reaction during adherent film formation can be promoted without causing degradation of the substrate.

The resist film may be formed on the adherent film by applying the resist composition thereto by any suitable technique such as spin coating, roll coating, flow coating, dip coating, spray coating or doctor coating and prebaking the composition on a hot plate, preferably at 60 to 200° C. for 10 seconds to 30 minutes, more preferably at 80 to 180° C. for 30 seconds to 20 minutes.

The method for preparing a laminate for use in the four-layer resist process comprises the steps of applying a resist underlying film-forming composition onto a substrate and heating to form a resist underlying film thereon, forming a silicon-containing intermediate film on the resist underlying film, applying an adherent film-forming composition onto the silicon-containing intermediate layer and heating to form an adherent film thereon, and applying a resist composition onto the adherent film and heating to form a resist film thereon.

The step of forming the resist underlying film is by applying the resist underlying film-forming composition onto a substrate by spin coating or the like, and baking the composition for evaporating off the solvent. The baking temperature may be set as appropriate depending on the type of resist underlying film, and is preferably about 100 to 400° C., more preferably about 150 to 300° C. The baking time may be set as appropriate depending on the type of resist underlying film, and is preferably about 10 to 600 seconds, more preferably about 10 to 300 seconds.

In one embodiment, a silicon-containing resist intermediate film is formed as the silicon-containing intermediate film by applying the silicon-containing resist intermediate film-forming composition by spin coating or the like, and baking to evaporate off the solvent. The baking temperature may be set as appropriate depending on the type of silicon-containing resist intermediate film, and is preferably about 100 to 400° C., more preferably about 150 to 300° C. The baking time may be set as appropriate depending on the type of silicon-containing resist intermediate film, and is preferably about 10 to 600 seconds, more preferably about 10 to 300 seconds.

In another embodiment, an inorganic hard mask intermediate film is formed as the silicon-containing intermediate film by forming a silicon oxide film, silicon nitride film or silicon oxynitride (SiON) film by the CVD or ALD method. With respect to the silicon nitride film, reference is made to JP-A 2002-334869 and WO 2004/066377. When a SiON film having a high antireflective function is formed as the inorganic hard mask intermediate film, the resist underlying film must be resistant to a temperature of 300 to 500° C. because the substrate temperature reaches 300 to 500° C. during formation of the SiON film.

In the four-layer resist process, the adherent film may be formed by spin coating or otherwise applying the adherent film-forming composition on the silicon-containing intermediate film, and baking to evaporate off the solvent and promote crosslinking reaction. The baking temperature and time may be the same as in the adherent film forming method in the two-layer resist process.

In the four-layer resist process, the resist film may be formed in the same way as in the resist film forming method in the two-layer resist process.

### Pattern Forming Process

A further embodiment of the invention is a pattern forming process comprising the steps of exposing the resist film in the laminate to i-line, KrF excimer laser, ArF excimer laser, EB or EUV, and developing the exposed resist film in a developer.

When the resist film is exposed to i-line, KrF excimer laser, ArF excimer laser, or EUV, exposure is performed directly or through a mask having the desired pattern so as to reach a dose of preferably about 1 to 300 mJ/cm², more preferably about 10 to 200 mJ/cm². On use of EB, imagewise writing is performed directly or through a mask having the desired pattern so as to reach a dose of preferably about 0.1 to 8,000 μC/cm², more preferably about 0.5 to 5,000 μC/cm². The pattern forming process is best suited in micropatterning using EB or EUV.

After the exposure, the resist film is baked (PEB) if necessary. Preferably PEB is performed on a hot plate or in an oven at 30 to 200° C. for 10 seconds to 30 minutes, more preferably at 60 to 120° C. for 30 seconds to 20 minutes.

After the exposure or PEB, the resist film is developed in a developer to form a pattern, if necessary. Typical of the developer are organic solvents such as 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, isopentyl acetate, butenyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole and 8-caprolactone. These organic solvents may be used alone or in admixture of two or more.

At the end of development, the resist film is rinsed if necessary. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Rinsing is effective for preventing the resist pattern from collapse or reducing defect formation. Rinsing is not essential. By omitting rinsing, the amount of the solvent used is saved.

### EXAMPLES

Examples of the invention are given below by way of illustration and not by way of limitation. The abbreviation “pbw” is parts by weight. It is noted that the molecular weight is measured by GPC using tetrahydrofuran (THF) or N,N-dimethylformamide (DMF) as elute, from which the weight average molecular weight (Mw) and number average molecular weight (Mn) versus polystyrene standards are determined and the dispersity (Mw/Mn) is computed therefrom.

### [1] Synthesis of Polymer for Adherent Film-Forming Composition

Polymers R-1 to R-8 for adherent film-forming material were synthesized using the following Compounds a-1 to a-6. Notably Compound a-5 was used as a 37 wt % aqueous solution.

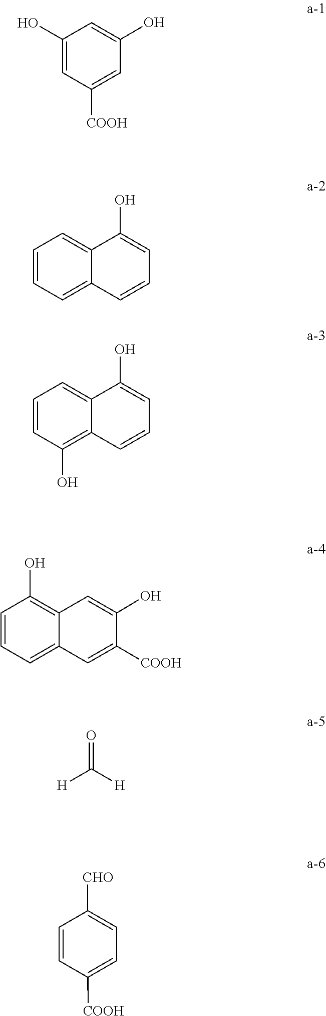 [SMILES: O=C(O)c1cc(O)cc(O)c1 ; Oc1cccc2ccccc12 ; Oc1cccc2c(O)cccc12 ; O=C(O)c1cc2cccc(O)c2cc1O ; C=O ; O=Cc1ccc(C(=O)O)cc1]

### Synthesis Example 1-1

### Synthesis of Polymer R-1

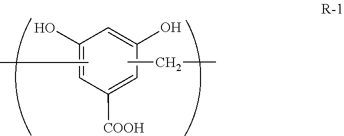

In nitrogen atmosphere, 20.0 g of Compound a-1, 10.0 g of Compound a-5 as 37 wt % aqueous solution, and 100 g of PGME were combined and stirred at a temperature of 100° C. until uniform. Then, 3.0 g of a 20 wt % PGME solution of p-toluenesulfonic acid monohydrate as previously prepared was slowly added to the solution, which was stirred at 110° C. for 24 hours. After cooling to room temperature, the solution was poured into 200 mL of ethyl acetate. The organic layer was taken out, washed with 100 g of 5 wt % nitric acid aqueous solution and then 5 times with 300 g of deionized water, and evaporated in vacuum to dryness. 60 g of THF was added to the residue to form a uniform solution. 150 g of hexane was added dropwise to the solution whereupon the polymer precipitated as a mass. After the solution was held static for a while, the supernatant was decanted off, and 60 g of THF was added to form a uniform solution. The series of steps were repeated two times. The polymer precipitated as mass was dried in vacuum at 80° C., yielding Polymer R-1. GPC analysis of Polymer R-1 showed a Mw of 1,100 and a Mw/Mn of 1.34.

### Synthesis Example 1-2

### Synthesis of Polymer R-2

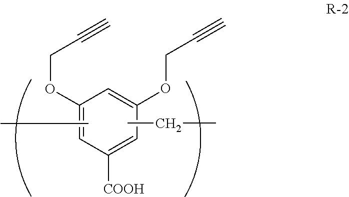

In nitrogen atmosphere, a reactor was charged with 10.0 g of Polymer R-1, 25.0 g of potassium carbonate, and 200 g of DMF. With the reactor temperature kept at 50° C., the contents were stirred until a uniform dispersion was obtained. To the dispersion, 28.6 g of propargyl bromide was slowly added. With the reactor temperature kept at 50° C., reaction was run for 16 hours. At the end of reaction, 200 mL of MIBK was added to the reaction solution, which was washed 6 times with 100 mL of deionized water. The organic layer was evaporated in vacuum to dryness. To the residue, 50 g of THF, 50 g of deionized water, and 4.8 g of sodium hydroxide were added to form a uniform dispersion. With the reactor temperature kept at 60° C., reaction was run for 6 hours. At the end of reaction, 200 mL of MIBK was added to the reaction solution. With cooling in an ice bath, 66 g of 10 wt % hydrochloric acid aqueous solution was slowly added for neutralization. After the water layer was removed, the organic layer was washed 5 times with 100 g of deionized water. The organic layer was recovered, and the solvent was distilled off. The remainder was evaporated in vacuum at 80° C. to dryness, yielding Polymer R-2. GPC analysis of Polymer R-2 showed a Mw of 1,560 and a Mw/Mn of 1.31.

### Synthesis Example 1-3

### Synthesis of Polymer R-3

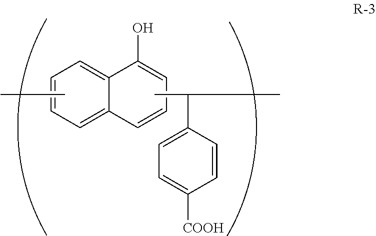

In nitrogen atmosphere, 20.0 g of Compound a-2, 18.7 g of Compound a-6, and 200 g of PGME were combined and stirred at a temperature of 100° C. until uniform. Then, 4.0 g of a 25 wt % sodium hydroxide aqueous solution was slowly added to the solution, which was stirred at 110° C. for 24 hours. After cooling to room temperature, 300 mL of MIBK was added to the solution. The organic layer was washed 2 times with 100 g of 5 wt % nitric acid aqueous solution and then 5 times with 200 g of deionized water, and evaporated in vacuum to dryness. 100 g of PGME was added to the residue to form a uniform solution. 200 g of hexane was added dropwise to the solution whereupon the polymer precipitated as a mass. After the solution was held static for a while, the supernatant was decanted off, and 200 g of PGME was added to form a uniform solution. The series of steps were repeated two times. The polymer precipitated as mass was dried in vacuum at 80° C., yielding Polymer R-3. GPC analysis of Polymer R-3 showed a Mw of 1,620 and a Mw/Mn of 1.89.

### Synthesis Example 1-4

### Synthesis of Polymer R-4

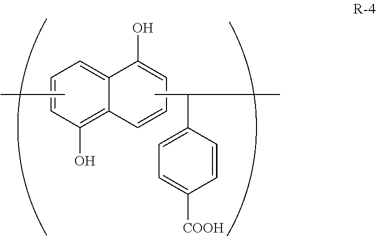

In nitrogen atmosphere, 20.0 g of Compound a-3, 15.0 g of Compound a-6, and 200 g of PGME were combined and stirred at a temperature of 100° C. until uniform. Then, 4.0 g of a 25 wt % sodium hydroxide aqueous solution was slowly added to the solution, which was stirred at 110° C. for 24 hours. After cooling to room temperature, 300 mL of MIBK was added to the solution. The organic layer was washed 2 times with 100 g of 5 wt % nitric acid aqueous solution and then 5 times with 200 g of deionized water, and evaporated in vacuum to dryness. 100 g of PGME was added to the residue to form a uniform solution. 200 g of hexane was added dropwise to the solution whereupon the polymer precipitated as a mass. After the solution was held static for a while, the supernatant was decanted off, and 200 g of PGME was added to form a uniform solution. The series of steps were repeated two times. The polymer precipitated as mass was dried in vacuum at 80° C., yielding Polymer R-4. GPC analysis of Polymer R-4 showed a Mw of 2,820 and a Mw/Mn of 2.34.

### Synthesis Example 1-5

### Synthesis of Polymer R-5

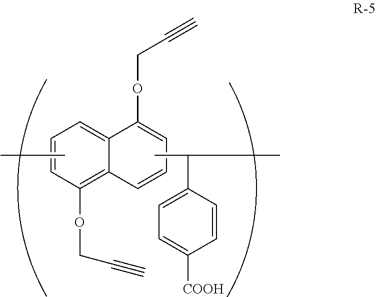

In nitrogen atmosphere, a reactor was charged with 10.0 g of Polymer R-4, 14.2 g of potassium carbonate, and 150 g of DMF. With the reactor temperature kept at 50° C., the contents were stirred until a uniform dispersion was obtained. To the dispersion, 16.3 g of propargyl bromide was slowly added. With the reactor temperature kept at 50° C., reaction was run for 16 hours. At the end of reaction, 200 mL of MIBK was added to the reaction solution, which was washed 6 times with 100 mL of deionized water. The organic layer was evaporated in vacuum to dryness. To the residue, 50 g of THF, 50 g of deionized water, and 2.7 g of sodium hydroxide were added to form a uniform dispersion. With the reactor temperature kept at 60° C., reaction was run for 6 hours. At the end of reaction, 200 mL of MIBK was added to the reaction solution. With cooling in an ice bath, 38 g of 10 wt % hydrochloric acid aqueous solution was slowly added for neutralization. After the water layer was removed, the organic layer was washed 5 times with 100 g of deionized water. The organic layer was recovered, and the solvent was distilled off. The remainder was evaporated in vacuum at 80° C. to dryness, yielding Polymer R-5. GPC analysis of Polymer R-5 showed a Mw of 4,390 and a Mw/Mn of 2.41.

### Synthesis Example 1-6

### Synthesis of Polymer R-6

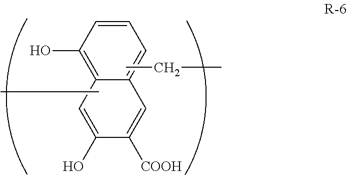

In nitrogen atmosphere, 20.0 g of Compound a-4, 6.4 g of Compound a-5 as aqueous solution, and 100 g of PGME were combined and stirred at a temperature of 100° C. until uniform. Then, 4.0 g of a 25 wt % sodium hydroxide aqueous solution was slowly added to the solution, which was stirred at 110° C. for 24 hours. After cooling to room temperature, 200 mL of MIBK was added to the solution. The organic layer was washed 2 times with 100 g of 5 wt % nitric acid aqueous solution and then 5 times with 200 g of deionized water, and evaporated in vacuum to dryness. 60 g of PGME was added to the residue to form a uniform solution. 150 g of hexane was added dropwise to the solution whereupon the polymer precipitated as a mass. After the solution was held static for a while, the supernatant was decanted off, and 60 g of PGME was added to form a uniform solution. The series of steps were repeated two times. The polymer precipitated as mass was dried in vacuum at 80° C., yielding Polymer R-6. GPC analysis of Polymer R-6 showed a Mw of 3,800 and a Mw/Mn of 2.46.

### Synthesis Example 1-7

### Synthesis of Polymer R-7

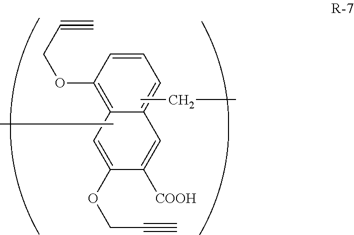

In nitrogen atmosphere, a reactor was charged with 10.0 g of Polymer R-6, 19.2 g of potassium carbonate, and 150 g of DMF. With the reactor temperature kept at 50° C., the contents were stirred until a uniform dispersion was obtained. To the dispersion, 22.0 g of propargyl bromide was slowly added. With the reactor temperature kept at 50° C., reaction was run for 16 hours. At the end of reaction, 150 mL of MIBK was added to the reaction solution, which was washed 6 times with 100 mL of deionized water. The organic layer was evaporated in vacuum to dryness. To the residue, 50 g of THF, 50 g of deionized water, and 3.7 g of sodium hydroxide were added to form a uniform dispersion. With the reactor temperature kept at 60° C., reaction was run for 6 hours. At the end of reaction, 200 mL of MIBK was added to the reaction solution. With cooling in an ice bath, 51 g of 10 wt % hydrochloric acid aqueous solution was slowly added for neutralization. After the water layer was removed, the organic layer was washed 5 times with 100 g of deionized water. The organic layer was recovered, and the solvent was distilled off. The remainder was dried in vacuum at 80° C., yielding Polymer R-7. GPC analysis of Polymer R-7 showed a Mw of 6,600 and a Mw/Mn of 2.58.

### Synthesis Example 1-8

### Synthesis of Polymer R-8

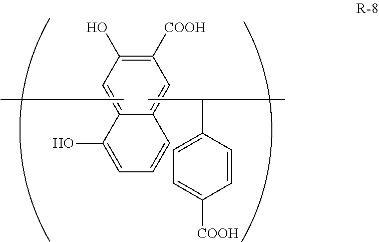

In nitrogen atmosphere, 20.0 g of Compound a-4, 111.8 g of Compound a-6, and 200 g of PGME were combined and stirred at a temperature of 100° C. until uniform. Then, 4.0 g of 25 wt % sodium hydroxide aqueous solution was slowly added to the solution, which was stirred at 110° C. for 24 hours. After cooling to room temperature, 300 mL of MIBK was added to the solution. The organic layer was washed 2 times with 100 g of 5 wt % nitric acid aqueous solution and then 5 times with 200 g of deionized water, and evaporated in vacuum to dryness. 100 g of PGME was added to the residue to form a uniform solution. 200 g of hexane was added dropwise to the solution whereupon the polymer precipitated as a mass. After the solution was held static for a while, the supernatant was decanted off, and 200 g of PGME was added to form a uniform solution. The series of steps were repeated two times. The polymer precipitated as mass was dried in vacuum at 80° C., yielding Polymer R-8. GPC analysis of Polymer R-8 showed a Mw of 1,050 and a Mw/Mn of 1.28.

### [2] Synthesis of Polymer for Resist Composition

Polymers P-1 to P-5 for resist compositions were synthesized using the following compounds.

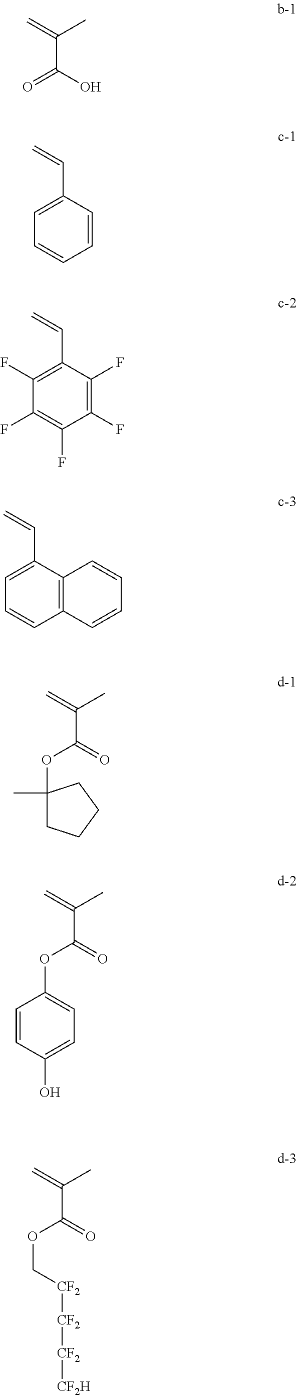

### Synthesis Example 2-1

### Synthesis of Polymer P-1

In nitrogen atmosphere, a flask was charged with 56 g of Monomer b-1, 36 g of Monomer c-1, 5.4 g of dimethyl 2,2′-azobis(isobutyrate) (V-601, FUJIFILM Wako Pure Chemical Corp.), and 180 g of methyl ethyl ketone (MEK) to form a monomer/initiator solution. Another flask in nitrogen atmosphere was charged with 55 g of MEK and heated at 80° C. with stirring, after which the monomer/initiator solution was added dropwise over 4 hours. After the completion of dropwise addition, the polymerization solution was continuously stirred for 2 hours while keeping the temperature of 80° C. It was then cooled to room temperature. With vigorous stirring, the polymerization solution was added dropwise to 4,000 g of hexane whereupon a polymer precipitated. The polymer was collected by filtration, washed twice with 1,200 g of hexane, and vacuum dried at 50° C. for 20 hours, obtaining Polymer P-1 in white powder form. Amount 90 g and yield 98%. Polymer P-1 had a Mw of 8,000 and a Mw/Mn of 1.42 as measured by GPC versus polystyrene standards using THF solvent.

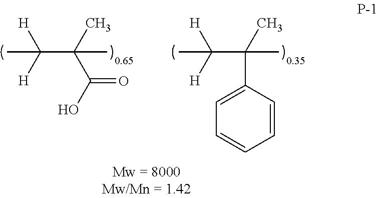

### Synthesis Examples 2-2 to 2-5

### Synthesis of Polymers P-2 to P-5

Polymers P-2 to P-5 shown in Table 1 were prepared by the same procedure as in Synthesis Example 2-1 except that the type and amount of monomers used were changed.

TABLE 1

| | | Incorporation | | Incorporation | | |
|---|---|---|---|---|---|---|
| Polymer | Unit 1 | ratio (mol %) | Unit 2 | ratio (mol %) | Mw | Mw/Mn |
| P-1 | b-1 | 65 | c-1 | 35 | 8,000 | 1.42 |
| P-2 | b-1 | 50 | c-2 | 50 | 8,400 | 1.51 |
| P-3 | b-1 | 60 | c-3 | 40 | 8,100 | 1.42 |
| P-4 | b-1 | 60 | d-3 | 40 | 8,100 | 1.42 |
| P-5 | d-1 | 65 | d-2 | 35 | 8,000 | 1.44 |

### [3] Preparation of Adherent Film-Forming Composition

### Preparation Examples 1-1 to 1-9

Adherent film-forming compositions UL-1 to UL-09 were prepared by dissolving the components shown in Table 2 in an organic solvent containing 0.1 wt % of surfactant FC-4430 (3M), and filtering the solution through a fluoro-resin filter having a pore size of 0.1 μm.

TABLE 2

| | | Adherent | | Thermal acid | | | |
|---|---|---|---|---|---|---|---|
| | | film-forming | Polymer | generator | Crosslinker | Solvent 1 | Solvent 2 |
| | | composition | (pbw) | (pbw) | (pbw) | (pbw) | (pbw) |
| Preparation | 1-1 | UL-01 | R-1 (100) | AG-1 (2) | XL-1 (10) | PGMEA (600) | PGEE (1000) |
| Example | 1-2 | UL-02 | R-2 (100) | AG-1 (2) | — | PGMEA (600) | PGEE (1000) |
| | 1-3 | UL-03 | R-3 (100) | AG-1 (2) | XL-1 (10) | PGMEA (600) | PGEE (1000) |
| | 1-4 | UL-04 | R-4 (100) | AG-1 (2) | — | PGMEA (600) | PGEE (1000) |
| | 1-5 | UL-05 | R-5 (100) | AG-1 (2) | — | PGMEA (600) | PGEE (1000) |
| | 1-6 | UL-06 | R-6 (100) | AG-1 (2) | XL-2 (10) | PGMEA (600) | PGEE (1000) |
| | 1-7 | UL-07 | R-7 (100) | AG-1 (2) | — | PGMEA (600) | PGEE (1000) |
| | 1-8 | UL-08 | R-8 (100) | AG-1 (2) | XL-3 (10) | PGMEA (600) | PGEE (1000) |
| | 1-9 | UL-09 | R-9 (100) | AG-1 (2) | — | PGMEA (600) | PGEE (1000) |

In Table 2, thermal acid generator AG-1, crosslinkers XL-1 to XL-3, Polymer R-9 for comparative adherent film-forming compositions, and organic solvents are identified below. GPC analysis of Polymer R-9 showed a Mw of 1,100 and a Mw/Mn of 1.22.

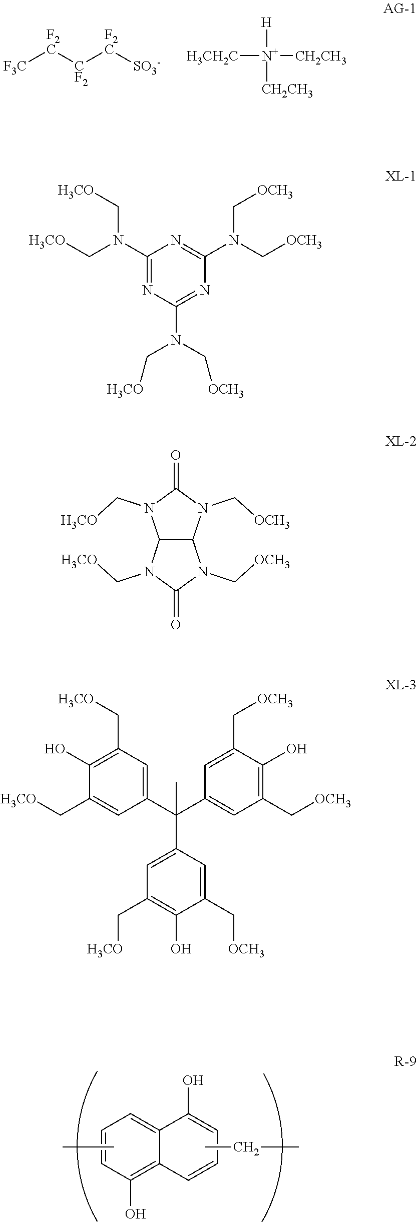

### Solvent:

PGMEA (propylene glycol methyl ether acetate)
PGEE (propylene glycol ethyl ether)

### [4] Preparation of Resist Composition

### Preparation Examples 2-1 to 2-10 and Comparative Preparation Examples 1-1 to 1-2

Resist compositions (R-H1 to R-10) were prepared by dissolving a hypervalent iodine compound and a carboxy-containing compound in a solvent containing 0.01 wt % of a surfactant (PF-636, Omnova Solutions, Inc.) in accordance with the recipe shown in Table 3, and filtering the solution through a Teflon® filter having a pore size of 0.2 μm. Also, resist compositions (CR-01 and CR-02) were prepared by dissolving a polymer, a photoacid generator, and a sensitivity modifier in a solvent containing 0.01 wt % of a surfactant (PF-636) in accordance with the recipe shown in Table 4, and filtering the solution through a Teflon® filter having a pore size of 0.2 μm.

TABLE 3

| | | | Hypervalent | Hypervalent | Carboxy- | | |
|---|---|---|---|---|---|---|---|
| | | | iodine | iodine | containing | | |
| | | Resist | compound 1 | compound 2 | compound | Solvent 1 | Solvent 2 |
| | | composition | (pbw) | (pbw) | (pbw) | (pbw) | (pbw) |
| Preparation | 2-1 | R-01 | I-1 (12) | — | P-1 (9) | PGMEA (800) | AcOH (200) |
| Example | 2-2 | R-02 | I-2 (10) | — | P-1 (9) | PGMEA (800) | AcOH (200) |
| | 2-3 | R-03 | I-3 (10) | — | P-1 (9) | PGMEA (800) | AcOH (200) |
| | 2-4 | R-04 | I-1 (6) | I-2 (5) | P-1 (9) | PGMEA (800) | AcOH (200) |
| | 2-5 | R-05 | I-1 (12) | — | P-2 (17) | PGMEA (800) | AcOH (200) |
| | 2-6 | R-06 | I-1 (12) | — | P-3 (11) | PGMEA (800) | AcOH (200) |
| | 2-7 | R-07 | I-1 (12) | — | P-4 (17) | PGMEA (800) | AcOH (200) |
| | 2-8 | R-08 | I-1 (12) | — | m-1 (7) | PGMEA (800) | AcOH (200) |
| | 2-9 | R-09 | I-1 (12) | — | m-2 (4) | PGMEA (800) | AcOH (200) |
| | 2-10 | R-10 | I-1 (12) | — | m-3 (7) | PGMEA (800) | AcOH (200) |

TABLE 4

| | | | | Photoacid | Sensitivity | | |
|---|---|---|---|---|---|---|---|
| | | Resist | Polymer | generator | modifier | Solvent 1 | Solvent 2 |
| | | composition | (pbw) | (pbw) | (pbw) | (pbw) | (pbw) |
| Comparative | 1-1 | CR-01 | P-5 (80) | PAG-1 (19) | Q-1 (6) | PGMEA (1890) | GBL (210) |
| Preparation | 1-2 | CR-02 | P-5 (80) | PAG-1 (19) | I-1 (5) | PGMEA (1890) | GBL (210) |
| Example | | | | | | | |

In Tables 3 and 4, the hypervalent iodine compound (I-1 to I-3), carboxy-containing compound (m-1 to m-3), photoacid generator (PAG-1), sensitivity modifier (Q-1), and solvent are identified below.

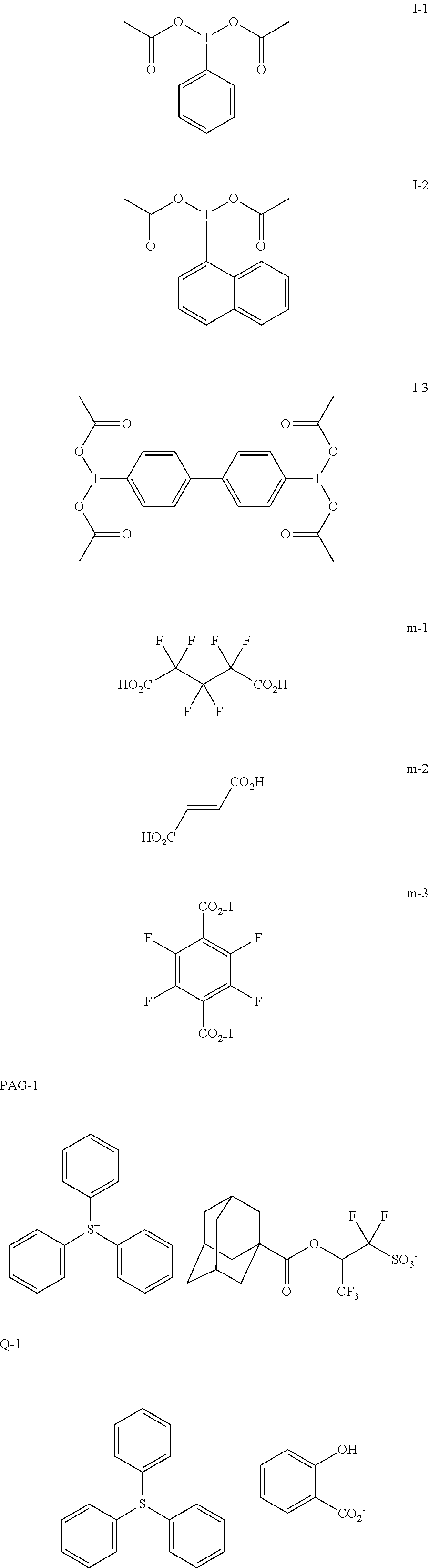

### Solvent:

AcOH (acetic acid)
GBL (γ-butyrolactone)

### [5] Preparation of Laminate and EUV Lithography Test

### (2-Layer Resist Process, Line-and-Space Pattern)

### Examples 1-1 to 1-17 and Comparative Examples 1-1 to 1-5

Each of adherent film-forming compositions (UL-01 to UL-09) was spin coated on a silicon substrate and baked (PAB) on a hotplate at the temperature shown in Table 5 for 60 seconds to form an adherent film of 40 nm thick. In Comparative Example 1-2, a silicon-containing spin-on hard mask SHB-A940 (Shin-Etsu Chemical Co., Ltd., silicon content 43 wt %) was formed on a substrate to a thickness of 40 nm. In Comparative Example 1-3, an antireflective film DUV-42 (Nissan Chemical Corp.) was formed on a substrate to a thickness of 40 nm.

Subsequently each of the resist compositions (R-01 to R-10, CR-01 to CR-02) was spin coated on the film and prebaked (PAB) on a hotplate at the temperature shown in Table 5 for 60 seconds to form a resist film of 40 nm thick. Using an EUV scanner NXE3400 (ASML, NA 0.33, σ 0.9, 900 dipole illumination), the resist film was exposed to EUV through a mask bearing a 36-nm 1:1 line-and-space (LS) pattern. The resist film was baked (PEB) on a hotplate at the temperature shown in Table 5 for 60 seconds and developed in the developer shown in Table 5 for 30 seconds to form a LS pattern having a space width of 18 nm and a pitch of 36 nm.

The LS pattern was observed under CD-SEM (CG-6300, Hitachi High-Technologies Corp.) and evaluated for sensitivity, LWR and maximum resolution by the following methods. The results are shown in Table 5.

### [Evaluation of Sensitivity]

The optimum dose Eop (mJ/cm²) which provided an LS pattern with a space width of 18 nm and a pitch of 36 nm was determined and reported as sensitivity.

### [Evaluation of LWR]

An LS pattern was formed by exposure in the optimum dose (Eop). The space width was measured at longitudinally spaced apart 10 points, from which a 3-fold value (3σ) of the standard deviation (σ) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

TABLE 5

| | | | Adherent | | | | | | |
|---|---|---|---|---|---|---|---|---|---|
| | | Adherent | film bake | | PAB/PEB | | | | Maximum |
| | | film-forming | temperature | Resist | temperature | | Eop | LWR | resolution |
| | | composition | (° C.) | composition | (° C.) | Developer | (mJ/cm²) | (nm) | (nm) |
| Exa maple | 1-1 | UL-01 | 285 | R-01 | 110/90 | nBA | 40 | 3.5 | 13 |
| | 1-2 | UL-01 | 285 | R-02 | 110/90 | nBA | 45 | 3.0 | 13 |
| | 1-3 | UL-01 | 285 | R-03 | 110/90 | nBA | 47 | 3.0 | 13 |
| | 1-4 | UL-01 | 285 | R-04 | 110/90 | nBA | 47 | 3.1 | 13 |
| | 1-5 | UL-01 | 285 | R-05 | 110/90 | nBA | 43 | 3.0 | 13 |
| | 1-6 | UL-01 | 285 | R-06 | 110/90 | nBA | 45 | 3.0 | 13 |
| | 1-7 | UL-01 | 285 | R-07 | 110/90 | nBA | 47 | 3.1 | 13 |
| | 1-8 | UL-01 | 285 | R-08 | 110/90 | nBA | 40 | 3.3 | 14 |
| | 1-9 | UL-01 | 285 | R-09 | 110/90 | nBA | 45 | 3.5 | 14 |
| | 1-10 | UL-01 | 285 | R-10 | 110/90 | nBA | 45 | 3.3 | 14 |
| | 1-11 | UL-02 | 285 | R-02 | 110/90 | nBA | 50 | 3.7 | 15 |
| | 1-12 | UL-03 | 285 | R-03 | 110/90 | nBA | 40 | 3.3 | 14 |
| | 1-13 | UL-04 | 285 | R-05 | 110/90 | nBA | 45 | 3.4 | 13 |
| | 1-14 | UL-05 | 285 | R-06 | 110/90 | nBA | 45 | 3.2 | 13 |
| | 1-15 | UL-06 | 285 | R-07 | 110/90 | nBA | 50 | 3.4 | 15 |
| | 1-16 | UL-07 | 285 | R-08 | 110/90 | nBA | 40 | 3.6 | 15 |
| | 1-17 | UL-08 | 285 | R-09 | 110/90 | nBA | 50 | 3.4 | 15 |
| Comparative | 1-1 | UL-09 | 285 | R-01 | 110/90 | nBA | 48 | 3.4 | 17 |
| Example | 1-2 | — | — | R-01 | 110/90 | nBA | 44 | 3.4 | 17 |
| | 1-3 | — | — | R-01 | 110/90 | nBA | 48 | 3.6 | 17 |
| | 1-4 | UL-01 | 285 | CR-01 | 105/90 | TMAH | 85 | 4.4 | 18 |
| | 1-5 | UL-01 | 285 | CR-02 | 105/90 | TMAH | 85 | 5.0 | 18 |

Developer:
nBA (n-butyl acetate)
TMAH (2.38 wt % tetramethylammonium hydroxide aqueous solution)

As shown in Table 5, a comparison of Examples with Comparative Examples 1-1 to 1-3 reveals that excellent resolution is achieved in the 2-layer resist process using the adherent film-forming composition. As compared with Comparative Examples 1-4 and 1-5 using chemically amplified resist compositions relying on acid-catalyzed reaction, better sensitivity, resolution and LWR are obtained. The 2-layer resist process using the laminate within the scope of the invention succeeded in forming LS patterns having satisfactory resolution via EUV exposure.

### [6] Preparation of Laminate and EUV Lithography Test

### (4-Layer Resist Process, Line-and-Space Pattern)

### Examples 2-1 to 2-17 and Comparative Examples 2-1 to 2-5

Spin-on carbon ODL-301 (Shin-Etsu Chemical Co., Ltd., carbon content 88 wt %) was coated on a silicon substrate and baked at 350° C. for 60 seconds to form a resist underlying film having a thickness of 200 nm. An SiON hard mask intermediate film (thickness 40 nm) was formed thereon by the CVD method. Each of adherent film-forming compositions (UL-01 to UL-09) was spin coated on the intermediate film and baked (PAB) on a hotplate at the temperature shown in Table 6 for 60 seconds to form an adherent film of 5 nm thick. In Comparative Example 2-2, a silicon-containing spin-on hard mask SHB-A940 (Shin-Etsu Chemical Co., Ltd., silicon content 43 wt %) was formed on a substrate to a thickness of 40 nm. In Comparative Example 2-3, an antireflective film DUV-42 (Nissan Chemical Corp.) was formed on a substrate to a thickness of 40 nm.

Subsequently each of the resist compositions (R-01 to R-10, CR-01 to CR-02) was spin coated on the film and prebaked (PAB) on a hotplate at the temperature shown in Table 6 for 60 seconds to form a resist film of 40 nm thick. Using an EUV scanner NXE3400 (ASML, NA 0.33, σ 0.9, 90° dipole illumination), the resist film was exposed to EUV through a mask bearing a 36-nm 1:1 line-and-space (LS) pattern. The resist film was baked (PEB) on a hotplate at the temperature shown in Table 6 for 60 seconds and developed in the developer shown in Table 6 for 30 seconds to form a LS pattern having a space width of 18 nm and a pitch of 36 nm.

The LS pattern was observed under CD-SEM (CG-6300, Hitachi High-Technologies Corp.) and evaluated for sensitivity, LWR and maximum resolution by the following methods. The results are shown in Table 6.

### [Evaluation of Sensitivity]

The optimum dose Eop (mJ/cm²) which provided an LS pattern with a space width of 18 nm and a pitch of 36 nm was determined and reported as sensitivity.

### [Evaluation of LWR]

An LS pattern was formed by exposure in the optimum dose (Eop). The space width was measured at longitudinally spaced apart 10 points, from which a 3-fold value (3σ) of the standard deviation (σ) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

TABLE 6

| | | | Adherent | | | | | | |
|---|---|---|---|---|---|---|---|---|---|
| | | Adherent | film bake | | PAB/PEB | | | | Maximum |
| | | film-forming | temperature | Resist | temperature | | Eop | LWR | resolution |
| | | composition | (° C.) | composition | (° C.) | Developer | (mJ/cm²) | (nm) | (nm) |
| Example | 2-1 | UL-01 | 285 | R-01 | 110/90 | nBA | 40 | 3.5 | 13 |
| | 2-2 | UL-01 | 285 | R-02 | 110/90 | nBA | 45 | 3.0 | 13 |
| | 2-3 | UL-01 | 285 | R-03 | 110/90 | nBA | 47 | 3.0 | 13 |
| | 2-4 | UL-01 | 285 | R-04 | 110/90 | nBA | 47 | 3.1 | 13 |
| | 2-5 | UL-01 | 285 | R-05 | 110/90 | nBA | 43 | 3.0 | 13 |
| | 2-6 | UL-01 | 285 | R-06 | 110/90 | nBA | 45 | 3.0 | 13 |
| | 2-7 | UL-01 | 285 | R-07 | 110/90 | nBA | 47 | 3.1 | 13 |
| | 2-8 | UL-01 | 285 | R-08 | 110/90 | nBA | 40 | 3.3 | 14 |
| | 2-9 | UL-01 | 285 | R-09 | 110/90 | nBA | 45 | 3.5 | 14 |
| | 2-10 | UL-01 | 285 | R-10 | 110/90 | nBA | 45 | 3.3 | 14 |
| | 2-11 | UL-02 | 285 | R-02 | 110/90 | nBA | 50 | 3.7 | 15 |
| | 2-12 | UL-03 | 285 | R-03 | 110/90 | nBA | 40 | 3.3 | 14 |
| | 2-13 | UL-04 | 285 | R-05 | 110/90 | nBA | 45 | 3.4 | 13 |
| | 2-14 | UL-05 | 285 | R-06 | 110/90 | nBA | 45 | 3.2 | 13 |
| | 2-15 | UL-06 | 285 | R-07 | 110/90 | nBA | 50 | 3.4 | 15 |
| | 2-16 | UL-07 | 285 | R-08 | 110/90 | nBA | 40 | 3.6 | 15 |
| | 2-17 | UL-08 | 285 | R-09 | 110/90 | nBA | 50 | 3.4 | 15 |
| Comparative | 2-1 | UL-09 | 285 | R-01 | 110/90 | nBA | 48 | 3.4 | 17 |
| Example | 2-2 | — | — | R-01 | 110/90 | nBA | 44 | 3.4 | 17 |
| | 2-3 | — | — | R-01 | 110/90 | nBA | 48 | 3.6 | 17 |
| | 2-4 | UL-01 | 285 | CR-01 | 105/90 | TMAH | 85 | 4.4 | 18 |
| | 2-5 | UL-01 | 285 | CR-02 | 105/90 | TMAH | 85 | 5.0 | 18 |

Developer:
nBA (n-butyl acetate)
TMAH (2.38 wt % tetramethylammonium hydroxide aqueous solution)

As shown in Table 6, a comparison of Examples with Comparative Examples 2-1 to 2-3 reveals that excellent resolution is achieved in the 4-layer resist process using the adherent film-forming composition. As compared with Comparative Examples 2-4 and 2-5 using chemically amplified resist compositions relying on acid-catalyzed reaction, better sensitivity, resolution and LWR are obtained. The 4-layer resist process using the laminate within the scope of the invention is successful in forming LS patterns having satisfactory resolution via EUV exposure.

### [7] Preparation of Laminate and EUV Lithography Test

### (4-Layer Resist Process, Contact Hole Pattern)

### Examples 3-1 to 3-17 and Comparative Examples 3-1 to 3-5

Spin-on carbon ODL-301 (Shin-Etsu Chemical Co., Ltd., carbon content 88 wt %) was coated on a silicon substrate and baked at 350° C. for 60 seconds to form a resist underlying film having a thickness of 200 nm. Silicon-containing spin-on hard mask SHB-A940 (Shin-Etsu Chemical Co., Ltd., silicon content 43 wt %) was coated thereon and baked at 220° C. for 60 seconds to form a silicon-containing intermediate film having a thickness of 40 nm. Each of adherent film-forming compositions (UL-01 to UL-09) was spin coated on the intermediate film and baked (PAB) on a hotplate at the temperature shown in Table 7 for 60 seconds to form an adherent film of 5 nm thick. In Comparative Example 3-2, a silicon-containing spin-on hard mask SHB-A940 (Shin-Etsu Chemical Co., Ltd., silicon content 43 wt %) was formed on a substrate to a thickness of 40 nm. In Comparative Example 3-3, an antireflective film DUV-42 (Nissan Chemical Corp.) was formed on a substrate to a thickness of 40 nm.

Subsequently each of the resist compositions (R-01 to R-10, CR-01 to CR-02) was spin coated on the film and prebaked (PAB) on a hotplate at the temperature shown in Table 7 for 60 seconds to form a resist film of 50 nm thick. Using an EUV scanner NXE3400 (ASML, NA 0.33, σ 0.9, 900 dipole illumination), the resist film was exposed to EUV through a mask bearing a hole pattern with a pitch of 64 nm+20% bias (on-wafer size). The resist film was baked (PEB) on a hotplate at the temperature shown in Table 7 for 60 seconds and developed in the developer shown in Table 7 for 30 seconds to form a hole pattern having a size of 32 nm.

The hole pattern was observed under CD-SEM (CG-6300, Hitachi High-Technologies Corp.) and evaluated for sensitivity, CDU and maximum resolution by the following methods. The results are shown in Table 7.

### [Evaluation of Sensitivity]

The optimum dose Eop (mJ/cm²) which provided a contact hole pattern with a size of 22 nm was determined and reported as sensitivity.

### [Evaluation of CDU]

The size of 50 holes which were printed at Eop was measured, from which a 3-fold value (3σ) of the standard deviation (σ) was computed and reported as CDU. A smaller value of CDU indicates a hole pattern with more uniform hole diameter.

### [Evaluation of Maximum Resolution]

A hole pattern was formed while reducing the exposure dose little by little from the optimum dose (Eop). The hole diameter (nm) which could be resolved was determined and reported as maximum resolution. A smaller value indicates a pattern having a better maximum resolution and smaller hole diameter.

TABLE 7

| | | | Adherent | | | | | | |
|---|---|---|---|---|---|---|---|---|---|
| | | Adherent | film bake | | PAB/PEB | | | | Maximum |
| | | film-forming | temperature | Resist | temperature | | Eop | CDU | resolution |
| | | composition | (° C.) | composition | (° C.) | Developer | (mJ/cm²) | (nm) | (nm) |
| Example | 3-1 | UL-01 | 285 | R-01 | 110/90 | nBA | 36 | 2.4 | 25 |
| | 3-2 | UL-01 | 285 | R-02 | 110/90 | nBA | 41 | 2.1 | 24 |
| | 3-3 | UL-01 | 285 | R-03 | 110/90 | nBA | 43 | 2.1 | 24 |
| | 3-4 | UL-01 | 285 | R-04 | 110/90 | nBA | 43 | 2.3 | 25 |
| | 3-5 | UL-01 | 285 | R-05 | 110/90 | nBA | 39 | 2.1 | 24 |
| | 3-6 | UL-01 | 285 | R-06 | 110/90 | nBA | 41 | 2.2 | 25 |
| | 3-7 | UL-01 | 285 | R-07 | 110/90 | nBA | 43 | 2.3 | 25 |
| | 3-8 | UL-01 | 285 | R-08 | 110/90 | nBA | 36 | 2.4 | 25 |
| | 3-9 | UL-01 | 285 | R-09 | 110/90 | nBA | 41 | 2.5 | 24 |
| | 3-10 | UL-01 | 285 | R-10 | 110/90 | nBA | 41 | 2.4 | 24 |
| | 3-11 | UL-02 | 285 | R-02 | 110/90 | nBA | 46 | 2.6 | 25 |
| | 3-12 | UL-03 | 285 | R-03 | 110/90 | nBA | 36 | 2.4 | 25 |
| | 3-13 | UL-04 | 285 | R-05 | 110/90 | nBA | 41 | 2.5 | 25 |
| | 3-14 | UL-05 | 285 | R-06 | 110/90 | nBA | 41 | 2.2 | 25 |
| | 3-15 | UL-06 | 285 | R-07 | 110/90 | nBA | 46 | 2.5 | 25 |
| | 3-16 | UL-07 | 285 | R-08 | 110/90 | nBA | 36 | 2.8 | 25 |
| | 3-17 | UL-08 | 285 | R-09 | 110/90 | nBA | 46 | 2.8 | 25 |
| Comparative | 3-1 | UL-09 | 285 | R-01 | 110/90 | nBA | 44 | 2.8 | 25 |
| Example | 3-2 | — | — | R-01 | 110/90 | nBA | 40 | 2.8 | 24 |
| | 3-3 | — | — | R-01 | 110/90 | nBA | 44 | 3.0 | 24 |
| | 3-4 | UL-01 | 285 | CR-01 | 105/90 | TMAH | 50 | 4.2 | 27 |
| | 3-5 | UL-01 | 285 | CR-02 | 105/90 | TMAH | 50 | 4.2 | 27 |

Developer:
nBA (n-butyl acetate)
TMAH (2.38 wt % tetramethylammonium hydroxide aqueous solution)

As shown in Table 7, a comparison of Examples with Comparative Examples 3-1 to 3-3 reveals that patterns having improved CDU are formed in the 4-layer resist process using the adherent film-forming composition. As compared with Comparative Examples 3-4 and 3-5 using chemically amplified resist compositions relying on acid-catalyzed reaction, better sensitivity, resolution and LWR are obtained. The 4-layer resist process using the laminate within the scope of the invention is successful in forming contact hole patterns having satisfactory CDU via EUV exposure.

Japanese Patent Application No. 2024-112836 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A laminate comprising a substrate, an adherent film on the substrate, and a resist film on the adherent film, wherein
said adherent film is formed of an adherent film-forming composition comprising a polymer comprising repeat units having the formula (1) or (2) and an organic solvent, 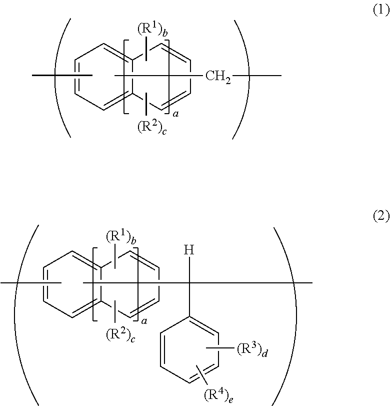
wherein a is 0, 1 or 2, b is an integer meeting 0≤b≤4a+2, c is an integer meeting 1≤c≤4a+2, and 1≤b+c≤4a+2, d is 0, 1, 2, 3, 4 or 5, e is 0, 1, 2, 3, 4 or 5, and 1≤d+e≤5,
R¹ is hydroxy or 2-propynyloxy,
R² is carboxy or carboxymethoxy,
R³ is hydroxy or 2-propynyloxy,
R⁴ is carboxy or carboxymethoxy,
said resist film is formed of a resist composition comprising at least one hypervalent iodine compound selected from a hypervalent iodine compound having the formula (3), a hypervalent iodine compound having the formula (4), and a hypervalent iodine compound having the formula (5), a carboxy-containing compound, and a solvent, 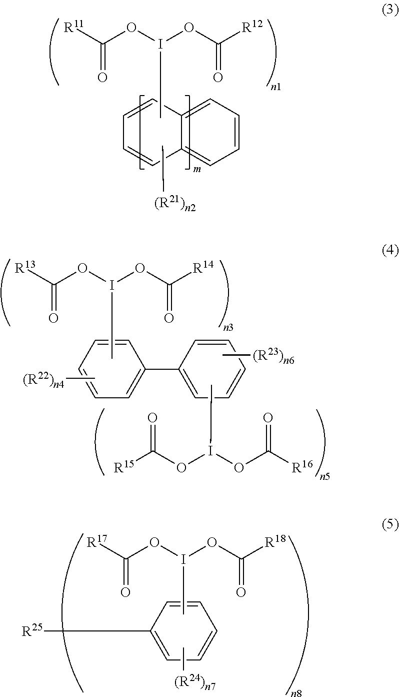
wherein m is 0, 1 or 2; when m=0, n1 is 1, 2 or 3, n2 is 0, 1, 2, 3, 4 or 5 and 1≤n1+n2≤6; when m=1, n1 is 1, 2 or 3, n2 is 0, 1, 2, 3, 4, 5, 6 or 7 and 1≤n1+n2≤8; when m=2, n1 is 1, 2 or 3, n2 is 0, 1, 2, 3, 4, 5, 6, 7, 8 or 9 and 1≤n1+n2≤10, n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
R¹¹ to R¹⁸ are each independently halogen or a C₁-C₁₀ hydrocarbyl group which may contain a heteroatom, R¹¹ and R¹², R¹³ and R¹⁴, R¹⁵ and R¹⁶, or R¹⁷ and R¹⁸ may bond together to form a ring with the carbon atoms to which they are attached and the intervenient atoms, and
R²¹ to R²⁴ are each independently halogen or a C₁-C₄₀ hydrocarbyl group which may contain a heteroatom; when n2 is 2 or more, a plurality of R²¹ may be identical or different and a plurality of R²¹ may bond together to form a ring with the carbon atoms on the aromatic ring to which they are attached; when n4 is 2 or more, a plurality of R²² may be identical or different and a plurality of R²² may bond together to form a ring with the carbon atoms on the aromatic ring to which they are attached; when n6 is 2 or more, a plurality of R²³ may be identical or different and a plurality of R²³ may bond together to form a ring with the carbon atoms on the aromatic ring to which they are attached; when n7 is 2 or more, a plurality of R²⁴ may be identical or different and a plurality of R²⁴ may bond together to form a ring with the carbon atoms on the aromatic ring to which they are attached;
R²⁵ is a C₁-C₄₀ (n8)-valent hydrocarbon group or C₂-C₄₀ (n8)-valent heterocyclic group; when n8=2, R²⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R²⁴ and R²⁵ may bond together to form a ring with the carbon atoms to which they are attached and the intervenient atoms.

2. The laminate of claim 1, further comprising a resist underlying film and a silicon-containing intermediate film between the substrate and the adherent film in the described order from the substrate side.

3. The laminate of claim 1 wherein the polymer comprising repeat units having the formula (1) or (2) has a weight average molecular weight of 500 to 20,000.

4. The laminate of claim 1 wherein the adherent film-forming composition further comprises at least one additive selected from a surfactant, crosslinker and thermal acid generator.

5. The laminate of claim 1 wherein the adherent film has a thickness of 2 to 50 nm.

6. The laminate of claim 1 wherein the carboxy-containing compound is a polymer comprising repeat units having the formula (6) or a compound having the formula (7): 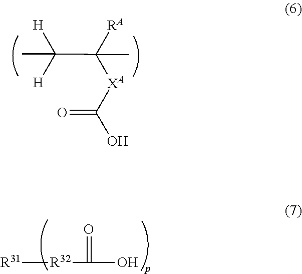
wherein R^{A} is hydrogen, halogen, methyl or trifluoromethyl,
X^{A} is a single bond, phenylene, naphthylene, or *—C(═O)—O—X^{A1}—, X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone,
p is 1, 2, 3 or 4,
R³¹ is a C₁-C₄₀ p-valent hydrocarbon group or C₂-C₄₀ p-valent heterocyclic group; when p=2, R³¹ may also be an ether bond, carbonyl group, azo group, thioether bond, carbonate bond, carbamate bond, sulfinyl group or sulfonyl group; some or all of the hydrogen atoms in the p-valent hydrocarbon group or p-valent heterocyclic group may be substituted by a heteroatom-containing moiety, some —CH₂— in the p-valent hydrocarbon group may be replaced by a heteroatom-containing moiety,
R³² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety; when p is 2, 3 or 4, a plurality of R³² may be identical or different.

7. A method for preparing a laminate, comprising the steps of:
applying an adherent film-forming composition onto a substrate and heating to form an adherent film thereon, and
applying a resist composition onto the adherent film and heating to form a resist film thereon,
said adherent film-forming composition comprising a polymer comprising repeat units having the formula (1) or (2) and an organic solvent, 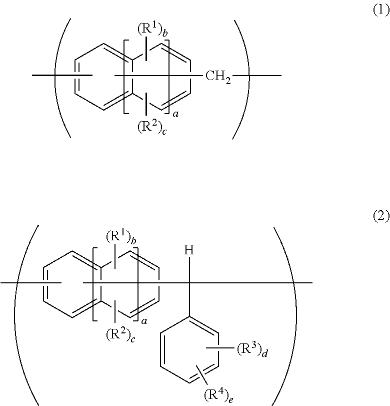
wherein a is 0, 1 or 2, b is an integer meeting 0≤b≤4a+2, c is an integer meeting 1≤c≤4a+2, and 1≤b+c≤4a+2, d is 0, 1, 2, 3, 4 or 5, e is 0, 1, 2, 3, 4 or 5, and 1≤d+e≤5,
R¹ is hydroxy or 2-propynyloxy,
R² is carboxy or carboxymethoxy,
R³ is hydroxy or 2-propynyloxy,
R⁴ is carboxy or carboxymethoxy,
said resist composition comprising at least one hypervalent iodine compound selected from a hypervalent iodine compound having the formula (3), a hypervalent iodine compound having the formula (4), and a hypervalent iodine compound having the formula (5), a carboxy-containing compound, and a solvent, 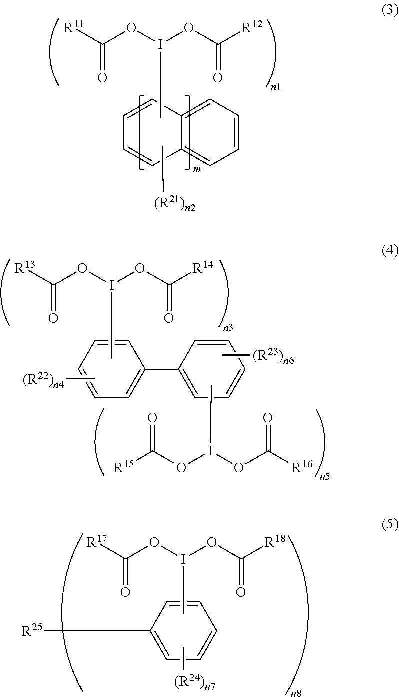
wherein m is 0, 1 or 2; when m=0, n1 is 1, 2 or 3, n2 is 0, 1, 2, 3, 4 or 5 and 1≤n1+n2≤6; when m=1, n1 is 1, 2 or 3, n2 is 0, 1, 2, 3, 4, 5, 6 or 7 and 1≤n1+n2≤8; when m=2, n1 is 1, 2 or 3, n2 is 0, 1, 2, 3, 4, 5, 6, 7, 8 or 9 and 1≤n1+n2≤10, n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
R¹¹ to R¹⁸ are each independently halogen or a C₁-C₁₀ hydrocarbyl group which may contain a heteroatom, R¹¹ and R¹², R¹³ and R¹⁴, R¹⁵ and R¹⁶, or R¹⁷ and R¹⁸ may bond together to form a ring with the carbon atoms to which they are attached and the intervenient atoms, and
R²¹ to R²⁴ are each independently halogen or a C₁-C₄₀ hydrocarbyl group which may contain a heteroatom; when n2 is 2 or more, a plurality of R²¹ may be identical or different and a plurality of R²¹ may bond together to form a ring with the carbon atoms on the aromatic ring to which they are attached; when n4 is 2 or more, a plurality of R²² may be identical or different and a plurality of R²² may bond together to form a ring with the carbon atoms on the aromatic ring to which they are attached; when n6 is 2 or more, a plurality of R²³ may be identical or different and a plurality of R²³ may bond together to form a ring with the carbon atoms on the aromatic ring to which they are attached; when n7 is 2 or more, a plurality of R²⁴ may be identical or different and a plurality of R²⁴ may bond together to form a ring with the carbon atoms on the aromatic ring to which they are attached;
R²⁵ is a C₁-C₄₀ (n8)-valent hydrocarbon group or C₂-C₄₀ (n8)-valent heterocyclic group; when n8=2, R²⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R²⁴ and R²⁵ may bond together to form a ring with the carbon atoms to which they are attached and the intervenient atoms.

8. A method for preparing a laminate, comprising the steps of:
applying a resist underlying film-forming composition onto a substrate and heating to form a resist underlying film thereon,
forming a silicon-containing intermediate film on the resist underlying film,
applying an adherent film-forming composition onto the silicon-containing intermediate layer and heating to form an adherent film thereon, and
applying a resist composition onto the adherent film and heating to form a resist film thereon,
said adherent film-forming composition comprising a polymer comprising repeat units having the formula (1) or (2) and an organic solvent, 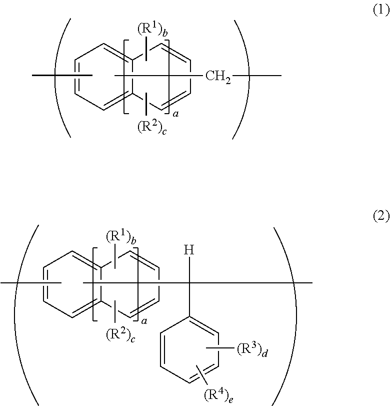
wherein a is 0, 1 or 2, b is an integer meeting 0≤b≤4a+2, c is an integer meeting 1≤c≤4a+2, and 1≤b+c≤4a+2, d is 0, 1, 2, 3, 4 or 5, e is 0, 1, 2, 3, 4 or 5, and 1≤d+e≤5,
R¹ is hydroxy or 2-propynyloxy,
R² is carboxy or carboxymethoxy,
R³ is hydroxy or 2-propynyloxy,
R⁴ is carboxy or carboxymethoxy,
said resist composition comprising at least one hypervalent iodine compound selected from a hypervalent iodine compound having the formula (3), a hypervalent iodine compound having the formula (4), and a hypervalent iodine compound having the formula (5), a carboxy-containing compound, and a solvent, 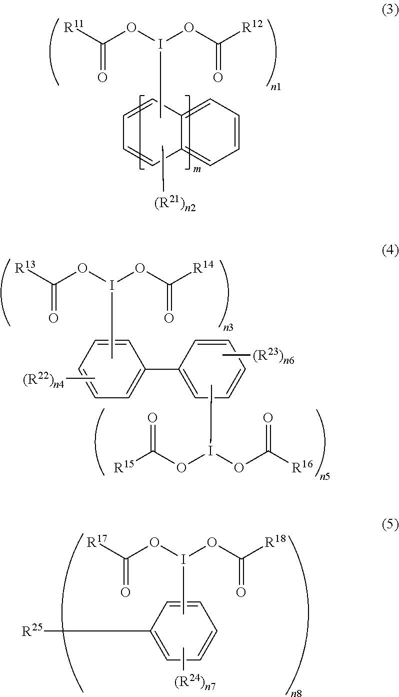
wherein m is 0, 1 or 2; when m=0, n1 is 1, 2 or 3, n2 is 0, 1, 2, 3, 4 or 5 and 1≤n1+n2≤6; when m=1, n1 is 1, 2 or 3, n2 is 0, 1, 2, 3, 4, 5, 6 or 7 and 1≤n1+n2≤8; when m=2, n1 is 1, 2 or 3, n2 is 0, 1, 2, 3, 4, 5, 6, 7, 8 or 9 and 1≤n1+n2≤10, n3 is 1 or 2, n4 is 0, 1, 2, 3 or 4, 1≤n3+n4≤5, n5 is 1 or 2, n6 is 0, 1, 2, 3 or 4, 1≤n5+n6≤5, n7 is 0, 1, 2, 3 or 4, n8 is 1, 2, 3 or 4,
R¹¹ to R¹⁸ are each independently halogen or a C₁-C₁₀ hydrocarbyl group which may contain a heteroatom, R¹¹ and R¹², R¹³ and R¹⁴, R¹⁵ and R¹⁶, or R¹⁷ and R¹⁸ may bond together to form a ring with the carbon atoms to which they are attached and the intervenient atoms, and
R²¹ to R²⁴ are each independently halogen or a C₁-C₄₀ hydrocarbyl group which may contain a heteroatom; when n2 is 2 or more, a plurality of R²¹ may be identical or different and a plurality of R²¹ may bond together to form a ring with the carbon atoms on the aromatic ring to which they are attached; when n4 is 2 or more, a plurality of R²² may be identical or different and a plurality of R²² may bond together to form a ring with the carbon atoms on the aromatic ring to which they are attached; when n6 is 2 or more, a plurality of R²³ may be identical or different and a plurality of R²³ may bond together to form a ring with the carbon atoms on the aromatic ring to which they are attached; when n7 is 2 or more, a plurality of R²⁴ may be identical or different and a plurality of R²⁴ may bond together to form a ring with the carbon atoms on the aromatic ring to which they are attached;
R²⁵ is a C₁-C₄₀ (n8)-valent hydrocarbon group or C₂-C₄₀ (n8)-valent heterocyclic group; when n8=2, R²⁵ may also be an ether bond, carbonyl group, azo group, thioether bond, carbonate bond, carbamate bond, sulfinyl group, sulfonyl group or thioketone bond; some or all of the hydrogen atoms in the (n8)-valent hydrocarbon group or (n8)-valent heterocyclic group may be substituted by a heteroatom-containing moiety, some —CH₂— in the (n8)-valent hydrocarbon group may be replaced by a heteroatom-containing moiety, R²⁴ and R²⁵ may bond together to form a ring with the carbon atoms to which they are attached and the intervenient atoms.

9. The method of claim 8 wherein the step of forming a silicon-containing intermediate film includes applying a silicon-containing intermediate film material onto the resist underlying film and heating the material coating.

10. The method of claim 8 wherein the silicon-containing intermediate film is an inorganic hard mask intermediate film selected from a silicon oxide film, silicon nitride film and silicon oxynitride film, which are formed by the CVD or ALD method.

11. The method of claim 7 wherein the carboxy-containing compound is a polymer comprising repeat units having the formula (6) or a compound having the formula (7), 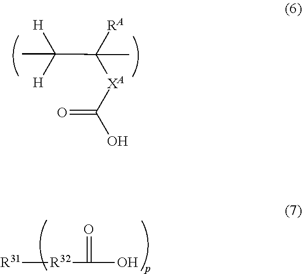
wherein R^{A} is hydrogen, halogen, methyl or trifluoromethyl,
X^{A} is a single bond, phenylene, naphthylene, or *—C(═O)—O—X^{A1}—, X^{A1} is a C₁-C₁₀ saturated hydrocarbylene group, phenylene group or naphthylene group, the saturated hydrocarbylene group may contain a hydroxy moiety, ether bond, ester bond or lactone ring, * designates a point of attachment to the carbon atom in the backbone,
p is 1, 2, 3 or 4,
R³¹ is a C₁-C₄₀ p-valent hydrocarbon group or C₂-C₄₀ p-valent heterocyclic group; when p=2, R³¹ may also be an ether bond, carbonyl group, azo group, thioether bond, carbonate bond, carbamate bond, sulfinyl group or sulfonyl group; some or all of the hydrogen atoms in the p-valent hydrocarbon group or p-valent heterocyclic group may be substituted by a heteroatom-containing moiety, some —CH₂— in the p-valent hydrocarbon group may be replaced by a heteroatom-containing moiety,
R³² is a single bond or C₁-C₁₀ hydrocarbylene group, some or all of the hydrogen atoms in the hydrocarbylene group may be substituted by a heteroatom-containing moiety, some —CH₂— in the hydrocarbylene group may be replaced by a heteroatom-containing moiety; when p is 2, 3 or 4, a plurality of R³² may be identical or different.

12. A pattern forming process comprising the steps of exposing the resist film in the laminate of claim 1 to i-line, KrF excimer laser, ArF excimer laser, EB or EUV, and developing the exposed resist film in a developer.

13. The pattern forming process of claim 12 wherein the developer is an organic solvent.
